(19) United States
(12) Patent Application Publication
(10) Pub. No.: US 2024/0268232 A1
(43) Pub. Date: Aug. 8, 2024

(54) TOP EMISSION TYPE ORGANIC ELECTROLUMINESCENT DEVICE, AND METHOD FOR DESIGNING SAME

(71) Applicant: KYULUX, INC., Fukuoka-shi, Fukuoka (JP)

(72) Inventor: Hayato KAKIZOE, Fukuoka-shi, Fukuoka (JP)

(21) Appl. No.: 18/564,449

(22) PCT Filed: Mar. 30, 2022
(86) PCT No.: PCT/JP2022/015887

§ 371 Date: Nov. 27, 2023

(30) Foreign Application Priority Data
May 28, 2021 (JP) 2021-090607
Aug. 17, 2021 (JP) 2021-132672

(51) Int. Cl. H10K 85/60; C09K 11/06; H10K 50/11; H10K 101/20; H10K 101/40; H10K 102/00; H10K 102/10

(52) U.S. Cl. CPC H10K 85/658; C09K 11/06; H10K 50/11; H10K 85/654; H10K 85/6572; H10K 2101/20; H10K 2101/40; H10K 2102/10; H10K 2102/3026

(57) ABSTRACT

A top emission type organic electroluminescent device including a light emitting layer containing first to third organic compounds, in which the second organic compound is a delayed fluorescent material having lower E_{S1} than the first organic compound, and the third organic compound has the lowest E_{S1} and higher E_{LUMO} and E_{HOMO} than the second organic compound and has a S value of −0.38 or less and a full width at half maximum of 31 nm or less, has a high light emission efficiency.

### TECHNICAL FIELD

The present invention relates to a top emission type organic electroluminescent device. The present invention also relates to a method for evaluating the light emission capability of a film and a method for determining a condition that is suitable for film formation. The present invention further relates to a method for designing an organic electroluminescent device, a program, and a database.

### BACKGROUND ART

Organic electroluminescent devices (organic EL devices) are expected to be used as a light source and a display device since the organic electroluminescent devices are self-luminous with no backlight required, resulting in light weight and flexibility, and also have advantages of fast response and good visibility.

On the other hand, the organic electroluminescent devices have room for improvement in light emission efficiency, and various material species and device structures have been proposed for the further enhancement of the light emission efficiency (see, for example, PTLs 1 to 6).

### CITATION LIST

### Patent Literatures

PTL 1: JP 2002-231459 A
PTL 2: U.S. Patent No. 9,099,674
PTL 3: U.S. Patent No. 8,686,420
PTL 4: JP 2004-013991 A
PTL 5: JP 2012-160632 A
PTL 6: WO 2012/111462

### SUMMARY OF INVENTION

### Technical Problem

However, most of the proposals for organic electroluminescent devices to date relate to either the material species or the device structure, and among these, no study has been made on the combination of the material species and the device structure. Therefore, it is unclear what type of device characteristics can be obtained with combinations other than the particular material species and device structures used in the proposals. For example, even though a material species is proposed as an excellent one, the use of the material in a device structure other than used in the proposal cannot substantially provide the function of a light emitting device in some cases, and on the other hand, an excellent device structure proposed cannot provide a good light emission capability in some cases depending on the material species used therein. In other words, the light emission efficiency obtained by combining specific material species and device structure cannot be predicted unless the device is actually produced. Therefore, it is not easy at present to find out a combination of the material species and device structure that results in a high light emission efficiency from the proposals for organic electroluminescent devices to date.

For solving the problem, the present inventors have made earnest investigations for providing an organic electroluminescent device having a high light emission efficiency by appropriately combining a material species and a device structure.

### Solution to Problem

As a result of the earnest investigations, the present inventors have found that the light emission efficiency of the device can be improved by incorporating a light emitting layer constituted by a material satisfying a particular condition into a top emission type organic electroluminescent device.

The present invention is proposed based on the knowledge, and specifically includes the following configurations.
[1] A top emission type organic electroluminescent device including a lamination structure including a substrate, a first electrode, a light emitting layer, and a transparent second electrode in this order,
the light emitting layer containing a first organic compound, a second organic compound, and a third organic compound that satisfy the following expressions (a) to (c),
the second organic compound being a delayed fluorescent material,
the third organic compound having an S value of −0.38 or less in the light emitting layer,
the third organic compound having a FWHM (full width at half maximum) of a light emission spectrum of 31 nm or less:

$${E}_{S 1} ( 1 ) > {E}_{S 1} ( 2 ) > {E}_{S 1} ( 3 ) \qquad ( a )$$

$${E}_{LUMO} ( 2 ) \leq {E}_{LUMO} ( 3 ) \qquad ( b )$$

$${E}_{HOMO} ( 2 ) \leq {E}_{HOMO} ( 3 ) \qquad ( c )$$

wherein
E_{S1}(1) represents lowest excited singlet energy of the first organic compound,
E_{S1}(2) represents lowest excited singlet energy of the second organic compound,
E_{S1}(3) represents lowest excited singlet energy of the third organic compound,
E_{LUMO}(2) represents energy of a LUMO of the second organic compound,
E_{LUMO}(3) represents energy of a LUMO of the third organic compound,
E_{HOMO}(2) represents energy of a HOMO of the second organic compound, and
E_{HOMO}(3) represents energy of a HOMO of the third organic compound.
[2] The organic electroluminescent device according to the item [1], wherein recombination of a hole and an electron occurs in the light emitting layer.
[3] The organic electroluminescent device according to the item [1] or [2], wherein the second organic compound includes a structure including a benzene ring having bonded thereto one or two cyano groups and at least one donor group.
[4] The organic electroluminescent device according to the item [3], wherein the donor group is a substituted or unsubstituted carbazol-9-yl group.
[5] The organic electroluminescent device according to the item [3], wherein the benzene ring has bonded thereto 3 or more substituted or unsubstituted carbazol-9-yl groups.
[6] The organic electroluminescent device according to any one of the items [1] to [5], wherein the third organic compound is a compound having a multiple resonance effect of a boron atom and a nitrogen atom, or a compound including a condensed aromatic cyclic structure.
[7] A method for evaluating a light emission capability of a film containing the first organic compound, the second organic compound, and the third organic compound that satisfy the expressions (a) to (c),
the method including evaluating the light emission capability of the film with an S value of the third organic compound and a full width at half maximum of a light emission spectrum of the third organic compound as indices.
[8] The method according to the item [7], wherein the method includes evaluating based on the full width at half maximum of 31 nm or less and the S value of −0.38 or less.
[9] The method according to the item [7] or [8], wherein the method includes evaluating usefulness as a light emitting layer of a top emission type organic electroluminescent device.
[10] The method according to the item [9], wherein the method includes predicting a light emission efficiency of the device.
[11] The method according to any one of the items [7] to [10], wherein the method includes evaluating capabilities of multiple films.
[12] A method for determining a condition suitable for film formation, including
forming a film containing the first organic compound, the second organic compound, and the third organic compound that satisfy the expressions (a) to (c) under one condition,
measuring an S value and a full width at half maximum of a light emission spectrum of the third organic compound in the formed film,
repeating once or more an operation including forming a film containing the first organic compound, the second organic compound, and the third organic compound under a condition different from the previous condition, and measuring an S value and a full width at half maximum of a light emission spectrum of the third organic compound in the formed film, and
evaluating the S value and the full width at half maximum as indices.
[13] The method according to the item [12], wherein the method further includes newly designing a condition suitable for film formation based on the evaluation, and then determining.
[14] A method for designing an organic electroluminescent device, including forming a light emitting layer under a condition determined by the method according to the item [12] or [13].
[15] A program including instructions for performing the method according to the item [12] or[13] or the method for designing according to the item [14].
[16] A database including data of the conditions, the S values, and the full widths at half maximum in the item [12].

### Advantageous Effects of Invention

The top emission type organic electroluminescent device of the present invention has a high light emission efficiency. According to the methods of the present invention, the light emission capability of the film can be easily evaluated, the formation condition of the light emitting layer having a good light emission capability can be found with high accuracy, and an excellent organic electroluminescent device can be designed. Furthermore, the use of the program and the database of the present invention enables the evaluation and the designing with high efficiency.

### BRIEF DESCRIPTION OF DRAWINGS

FIG. 1 is a schematic cross sectional view showing a layer configuration of an organic electroluminescent device according to the first embodiment.

FIG. 2 is a schematic cross sectional view showing a layer configuration of an organic electroluminescent device according to the second embodiment.

FIG. 3 is a graph showing the relationship between the external quantum efficiency (EQE) and the full width at half maximum (FWHM) of the third organic compound of the organic electroluminescent devices TE1 to TE6.

FIG. 4 is a graph showing the relationship between the light emission peak intensity (PI) and the full width at half maximum (FWHM) of the third organic compound of the organic electroluminescent devices TE1 to TE6.

FIG. 5 is a graph showing the relationship between the external quantum efficiency (EQE) and the S value of the third organic compound in the light emitting layer of the organic electroluminescent devices TE1 to TE6.

FIG. 6 is a graph showing the relationship between the light emission peak intensity (PI) and the S value of the third organic compound in the light emitting layer of the organic electroluminescent devices TE1 to TE6.

FIG. 7 is a graph showing the relationship between the evanescent mode and the full width at half maximum (FWHM) of the third organic compound of the top emission type devices TE1 to TE6.

FIG. 8 is a graph showing the relationship between the evanescent mode and the S value of the third organic compound in the light emitting layer of the top emission type devices TE1 to TE6.

FIG. 9 is a flow chart describing the method for determining a condition suitable for film formation of the present invention.

### DESCRIPTION OF EMBODIMENTS

The contents of the present invention will be described in detail below. The description of the constitutional elements described below may be made with reference to representative embodiments or specific examples of the present invention in some cases, but the present invention is not limited to the embodiments and the examples. In the description herein, the numeral range expressed by using “to” means a range that encompasses the numerals described before and after “to” as the lower limit value and the upper limit value. In the description herein, the expression “consisting of” means that only the items described before “consisting of” are contained, but no other item is contained. A part or the whole of the hydrogen atoms existing in the molecule of the compound used in the present invention may be replaced by a deuterium atom (²H or D). In the chemical structural formulae in the description herein, a hydrogen atom is shown by H, or the presence thereof is omitted. For example, the position of a benzene ring where the presence of an atom bonded to the ring skeleton-forming carbon atom thereof is omitted means that H is bonded to the ring skeleton-forming carbon atom. In the description herein, the term “substituent” means an atom or an atomic group other than a hydrogen atom and a deuterium atom. The expression “substituted or unsubstituted” and “which may be substituted” means that a hydrogen atom may be replaced by a deuterium atom or a substituent. The expression “transparent” in the description herein means that the transmittance of visible light is 50% or more, preferably 80% or more, more preferably 90% or more, and further preferably 99% or more. The transmittance of visible light can be measured with an ultraviolet-visible spectrophotometer.

The organic electroluminescent device of the present invention is a top emission type organic electroluminescent device having a lamination structure including a substrate, a first electrode, a light emitting layer, and a transparent second electrode in this order. A layer may intervene or may not intervene between each of the substrate and the first electrode, the first electrode and the light emitting layer, and the light emitting layer and the second electrode. The first electrode and the light emitting layer may be laminated so as to be brought into direct contact with each other, or a structure including the light emitting layer that is laminated above the first electrode so as not to be brought into direct contact with each other may be employed. The light emitting layer and the second electrode may be laminated so as to be brought into direct contact with each other, or a structure including the second electrode that is laminated above the light emitting layer so as not to be brought into direct contact with each other may be employed. The light emitting layer is positioned between the first electrode and the second electrode, and is preferably disposed in the region between the first electrode and the second electrode in such a manner that the light emitting layer does not protrude from the region.

The organic electroluminescent device of the present invention is a top emission type device. Therefore, light emitted from the light emitting layer is emitted at least from the second electrode side. The amount of the light that is emitted from the second electrode side is 60% or more, and preferably 90% or more, for example, may be 99% or more, and may be 100%, of the amount of light emitted from the device. The specific configuration of the top emission type device will be described later.

In the organic electroluminescent device of the present invention, the light emitting layer contains a first organic compound, a second organic compound, and a third organic compound.

In the organic electroluminescent device of the present invention, the third organic compound has an S value of −0.38 or less in the light emitting layer. The S value of the third organic compound is more preferably −0.40 or less, further preferably −0.41 or less, and still further preferably −0.42 or less. The S value may also referred to as an orientation value, and is an index showing the extent of orientation of the third organic compound in the light emitting layer. A larger negative value (i.e., a smaller value) thereof means a higher orientation of the compound. The S value can be determined by the method described in Scientific Reports, 2017, 7, 8405.

In the organic electroluminescent device of the present invention, the third organic compound has a FWHM (full width at half maximum) of the light emission spectrum of 31 nm or less. The full width at half maximum is preferably 26 nm or less, more preferably 23 nm or less, and further preferably 20 nm or less. The full width at half maximum of the light emission spectrum herein means the full width at half maximum of the light emission peak that is intended to be used as light emission. In general, the full width at half maximum is the full width at half maximum of the light emission peak having the maximum light emission intensity, and is preferably the full width at half maximum of the light emission peak having the maximum light emission intensity within the visible region.

In a preferred embodiment of the present invention, the third organic compound has an S value of −0.41 or less and a full width at half maximum of 23 nm or less. In a more preferred embodiment of the present invention, the third organic compound has an S value of −0.42 or less and a full width at half maximum of 23 nm or less. In a further preferred embodiment of the present invention, the third organic compound has an S value of −0.42 or less and a full width at half maximum of 20 nm or less.

The first organic compound, the second organic compound, and the third organic compound contained in the light emitting layer satisfy the following expressions (a) to (c).

$${E}_{S 1} ( 1 ) > {E}_{S 1} ( 2 ) > {E}_{S 1} ( 3 ) \qquad ( a )$$

$${E}_{LUMO} ( 2 ) \leq {E}_{LUMO} ( 3 ) \qquad ( b )$$

$${E}_{HOMO} ( 2 ) \leq {E}_{HOMO} ( 3 ) \qquad ( c )$$

In the expression (a), E_{S1}(1) represents the lowest excited singlet energy of the first organic compound, E_{S1}(2) represents the lowest excited singlet energy of the second organic compound, and E_{S1}(3) represents the lowest excited singlet energy of the third organic compound. The present invention uses eV as the unit therefor. The lowest excited singlet energy can be obtained by preparing a thin film or a toluene solution (concentration: 10⁻⁵ mol/L) of the target compound to be measured, and measuring the fluorescent spectrum thereof at ordinary temperature (300 K) (in more detail, reference may be made to the measurement method of the lowest excited singlet energy in the description of the second organic compound).

The present invention satisfies the relationship of the expression (a), and therefore among the first organic compound, the second organic compound, and the third organic compound contained in the light emitting layer, the lowest excited singlet energy of the first organic compound is the largest, that of the second organic compound is the next largest, and that of the third organic compound is the smallest. For example, the value of E_{S1}(1)-E_{S1}(2) may be in a range of 0.20 eV or more, may be in a range of 0.40 eV or more, or may be in a range of 0.60 eV or more, and may be in a range of 1.50 eV or less, may be in a range of 1.20 eV or less, or may be in a range of 0.80 eV or less. For example, the value of E_{S1}(2)-E_{S1}(3) may be in a range of 0.05 eV or more, may be in a range of 0.10 eV or more, or may be in a range of 0.15 eV or more, and may be in a range of 0.50 eV or less, may be in a range of 0.30 eV or less, or may be in a range of 0.20 eV or less. For example, the value of E_{S1}(1)-E_{S1}(3) may be in a range of 0.25 eV or more, may be in a range of 0.45 eV or more, or may be in a range of 0.65 eV or more, and may be in a range of 2.00 eV or less, may be in a range of 1.70 eV or less, or may be in a range of 1.30 eV or less.

In the expression (b), E_{LUMO}(2) represents energy of the LUMO of the second organic compound, and E_{LUMO}(3) represents energy of the LUMO of the third organic compound. The LUMO is an abbreviation of the lowest unoccupied molecular orbital, and can be obtained by the atmospheric photoelectron spectroscopy (for example, AC-3, available from Riken Keiki Co., Ltd.).

The present invention satisfies the relationship of the expression (b), and therefore the energy of the LUMO of the second organic compound contained in the light emitting layer is the energy of the LUMO of the third organic compound contained therein or less. For example, the difference in energy of the LUMO (E_{LUMO}(3)-E_{LUMO}(2)) may be in a range of 0.05 eV or more, may be in a range of 0.10 eV or more, or may be in a range of 0.13 eV or more, and may be in a range of 0.40 eV or less, may be in a range of 0.30 eV or less, or may be in a range of 0.20 eV or less. In one embodiment of the present invention, a compound having energy of the LUMO in a range of −2.0 to −5.0 eV or a compound having energy of the LUMO in a range of −2.5 to −4.0 eV may be used as the second organic compound. In one embodiment of the present invention, a compound having energy of the LUMO in a range of −2.0 to −5.0 eV or a compound having energy of the LUMO in a range of −2.5 to −4.0 eV may be used as the third organic compound.

In the expression (c), E_{HOMO}(2) represents energy of the HOMO of the second organic compound, and E_{HOMO}(3) represents energy of the HOMO of the third organic compound. The HOMO is an abbreviation of the highest occupied molecular orbital, and can be obtained by the atmospheric photoelectron spectroscopy (for example, AC-3, available from Riken Keiki Co., Ltd.).

The present invention satisfies the relationship of the expression (c), and therefore the energy of the HOMO of the second organic compound contained in the light emitting layer is the energy of the HOMO of the third organic compound contained therein or less. For example, the difference in energy of the HOMO (E_{HOMO}(3)-E_{HOMO}(2)) may be in a range of 0.05 eV or more, may be in a range of 0.10 eV or more, or may be in a range of 0.13 eV or more, and may be in a range of 0.40 eV or less, may be in a range of 0.30 eV or less, or may be in a range of 0.20 eV or less. In one embodiment of the present invention, a compound having energy of the HOMO in a range of −4.0 to −6.5 eV or a compound having energy of the LUMO in a range of −5.5 to −6.2 eV may be used as the second organic compound. In one embodiment of the present invention, a compound having energy of the HOMO in a range of −4.0 to −6.5 eV or a compound having energy of the HOMO in a range of −5.0 to −6.0 eV may be used as the third organic compound.

In the light emitting layer of the organic electroluminescent device of the present invention, the content of the first organic compound Conc(1), the content of the second organic compound Conc(2), and the content of the third organic compound Conc(3) preferably satisfy the relationship of the following expression (d).

$$Conc ( 1 ) > Conc ( 2 ) > Conc ( 3 ) \qquad ( d )$$

Conc(1) is preferably 30% by weight of more, may be in a range of 50% by weight or more, or may be in a range of 60% by weight or more, and may be in a range of 99% by weight or less, may be in a range of 85% by weight or less, or may be in a range of 70% by weight or less.
Conc(2) is preferably 5% by weight of more, may be in a range of 15% by weight or more, or may be in a range of 30% by weight or more, and may be in a range of 45% by weight or less, may be in a range of 40% by weight or less, or may be in a range of 35% by weight or less.
Conc(3) is preferably 5% by weight of less, and more preferably 3% by weight or less. Conc(3) may be in a range of 0.01% by weight or more, may be in a range of 0.1% by weight or more, or may be in a range of 0.3% by weight or more, and may be in a range of 2% by weight or less, or may be in a range of 1% by weight or less.

The value of Conc(1)/Conc(3) may be in a range of 10 or more, may be in a range of 50 or more, or may be in a range of 90 or more, and may be in a range of 10,000 or less, may be in a range of 1,000 or less, or may be in a range of 200 or less.

The value of Conc(2)/Conc(3) may be in a range of 5 or more, may be in a range of 10 or more, may be in a range of 20 or more, or may be in a range of 30 or more, and may be in a range of 500 or less, may be in a range of 300 or less, or may be in a range of 100 or less.

The light emitting layer of the organic electroluminescent device of the present invention preferably contains no other metal element than boron. A light emitting layer that does not contain metal elements including boron may also be used. For example, the light emitting layer may be constituted only by one or more compounds consisting of atoms selected from the group consisting of a carbon atom, a hydrogen atom, a nitrogen atom, an oxygen atom, a sulfur atom, a fluorine atom, and a boron atom. For example, the light emitting layer may be constituted only by one or more compounds consisting of atoms selected from the group consisting of a carbon atom, a hydrogen atom, a nitrogen atom, an oxygen atom, a sulfur atom, a fluorine atom, and a boron atom. For example, the light emitting layer may be constituted only by one or more compounds consisting of atoms selected from the group consisting of a carbon atom, a hydrogen atom, a nitrogen atom, an oxygen atom, and a sulfur atom. For example, the light emitting layer may be constituted only by one or more compounds consisting of atoms selected from the group consisting of a carbon atom, a hydrogen atom, a nitrogen atom, and an oxygen atom.

### First Organic Compound

The first organic compound used in the light emitting layer of the organic electroluminescent device of the present invention is selected from compounds that have lowest excited singlet energy that is larger than the second organic compound and the third organic compound. The first organic compound preferably has a function of a host material assuming transportation of a carrier. The first organic compound preferably has a function confining the energy of the third organic compound within the compound. According to the configuration, the third organic compound can convert the energy generated through recombination of a hole and an electron within the molecule and the energy received from the first organic compound and the second organic compound to light emission with high efficiency.

The first organic compound is preferably an organic compound that has a hole transporting function and an electron transporting function, prevents the light emission from becoming a longer wavelength, and has a high glass transition temperature. In one preferred embodiment of the present invention, the first organic compound is selected from a compound that does not emit delayed fluorescent light. The light emission from the first organic compound is preferably less than 1%, and more preferably less than 0.1%, for example, may be less than 0.01%, of the light emission from the organic electroluminescent device of the present invention, and may be the detection limit or less.

The first organic compound preferably contains no metal atom. For example, a compound containing atoms selected from the group consisting of a carbon atom, a hydrogen atom, a nitrogen atom, an oxygen atom, and a sulfur atom may be selected as the first organic compound. For example, a compound containing atoms selected from the group consisting of a carbon atom, a hydrogen atom, a nitrogen atom, and an oxygen atom may be selected as the first organic compound. For example, a compound containing atoms selected from the group consisting of a carbon atom, a hydrogen atom, and a nitrogen atom may be selected as the first organic compound.

Preferred compounds that can be used as the first organic compound are shown below.

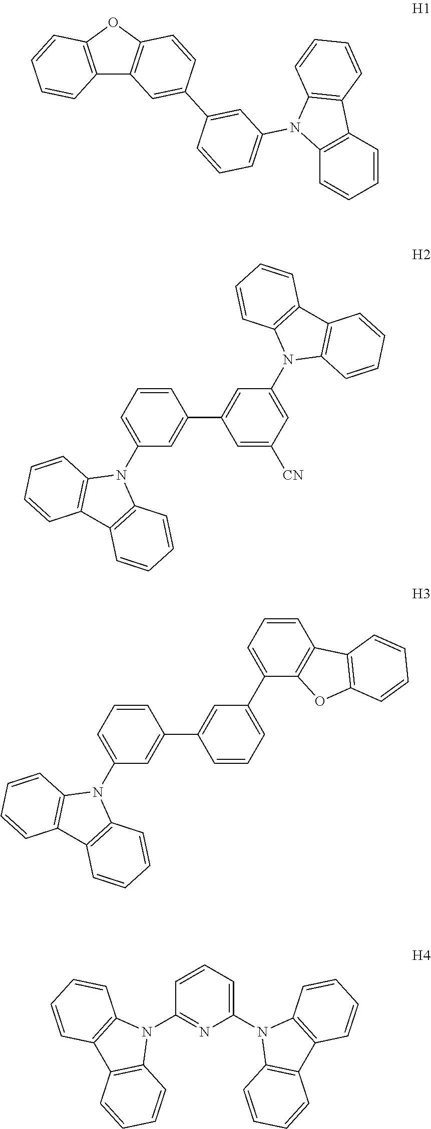 [SMILES: c1cc(-c2ccc3oc4ccccc4c3c2)cc(-n2c3ccccc3c3ccccc32)c1 ; N#Cc1cc(-c2cccc(-n3c4ccccc4c4ccccc43)c2)cc(-n2c3ccccc3c3ccccc32)c1 ; c1cc(-c2cccc(-n3c4ccccc4c4ccccc43)c2)cc(-c2cccc3c2oc2ccccc23)c1 ; c1cc(-n2c3ccccc3c3ccccc32)nc(-n2c3ccccc3c3ccccc32)c1]

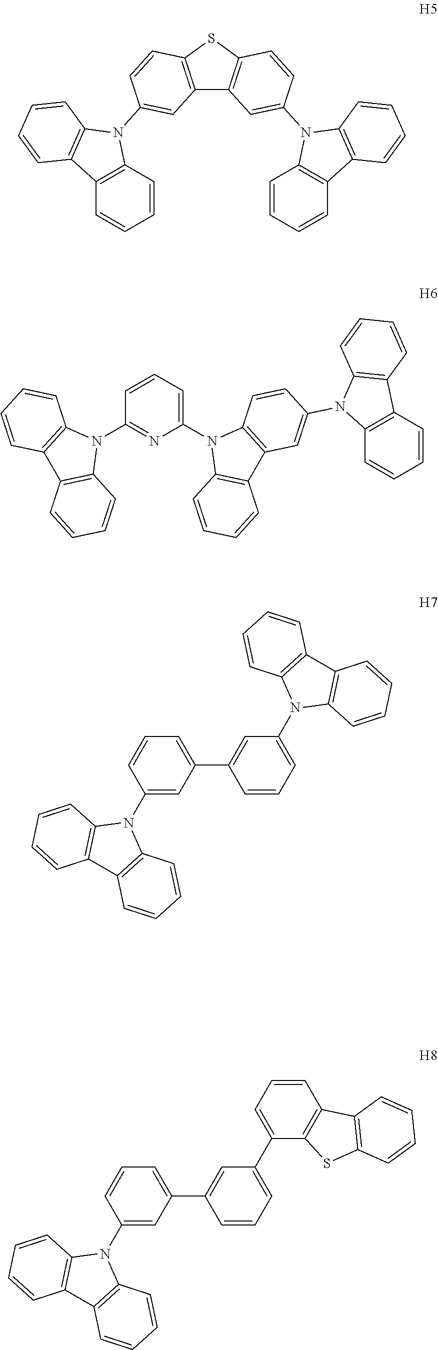 [SMILES: c1ccc2c(c1)c1ccccc1n2-c1ccc2sc3ccc(-n4c5ccccc5c5ccccc54)cc3c2c1 ; c1cc(-n2c3ccccc3c3ccccc32)nc(-n2c3ccccc3c3cc(-n4c5ccccc5c5ccccc54)ccc32)c1 ; c1cc(-c2cccc(-n3c4ccccc4c4ccccc43)c2)cc(-n2c3ccccc3c3ccccc32)c1 ; c1cc(-c2cccc(-n3c4ccccc4c4ccccc43)c2)cc(-c2cccc3c2sc2ccccc23)c1]

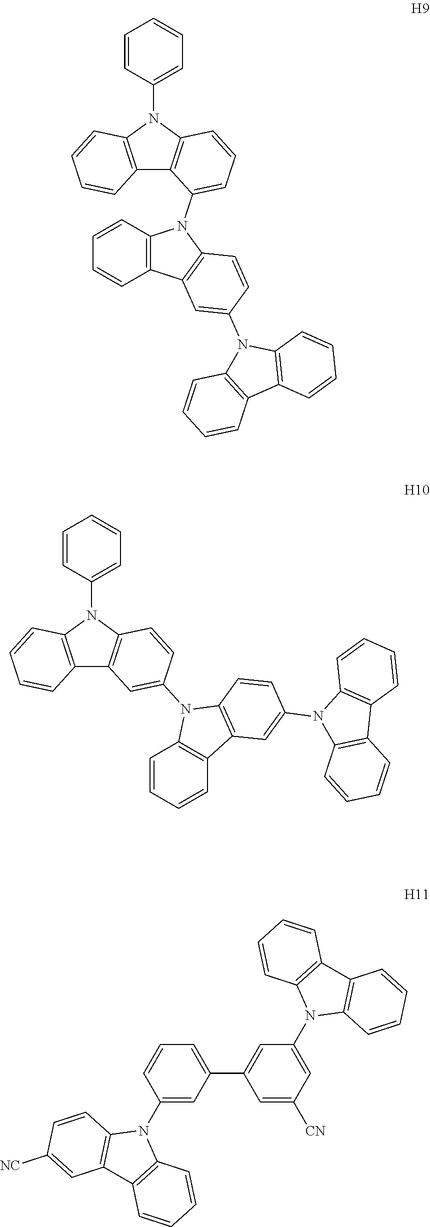 [SMILES: c1ccc(-n2c3ccccc3c3c(-n4c5ccccc5c5cc(-n6c7ccccc7c7ccccc76)ccc54)cccc32)cc1 ; c1ccc(-n2c3ccccc3c3cc(-n4c5ccccc5c5cc(-n6c7ccccc7c7ccccc76)ccc54)ccc32)cc1 ; N#Cc1cc(-c2cccc(-n3c4ccccc4c4cc(C#N)ccc43)c2)cc(-n2c3ccccc3c3ccccc32)c1]

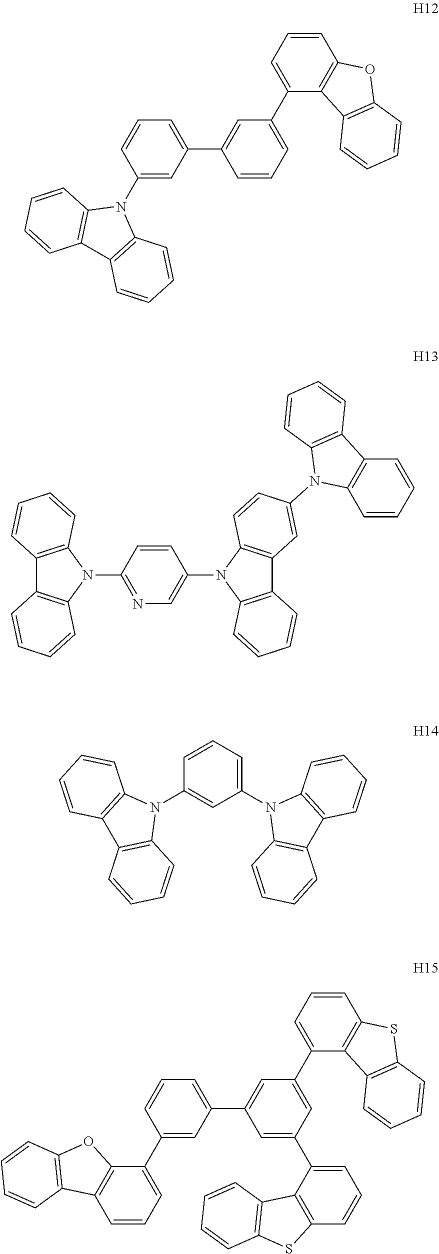 [SMILES: c1cc(-c2cccc(-n3c4ccccc4c4ccccc43)c2)cc(-c2cccc3oc4ccccc4c23)c1 ; c1ccc2c(c1)c1ccccc1n2-c1ccc2c(c1)c1ccccc1n2-c1ccc(-n2c3ccccc3c3ccccc32)nc1 ; c1cc(-n2c3ccccc3c3ccccc32)cc(-n2c3ccccc3c3ccccc32)c1 ; c1cc(-c2cc(-c3cccc4sc5ccccc5c34)cc(-c3cccc4sc5ccccc5c34)c2)cc(-c2cccc3c2oc2ccccc23)c1]

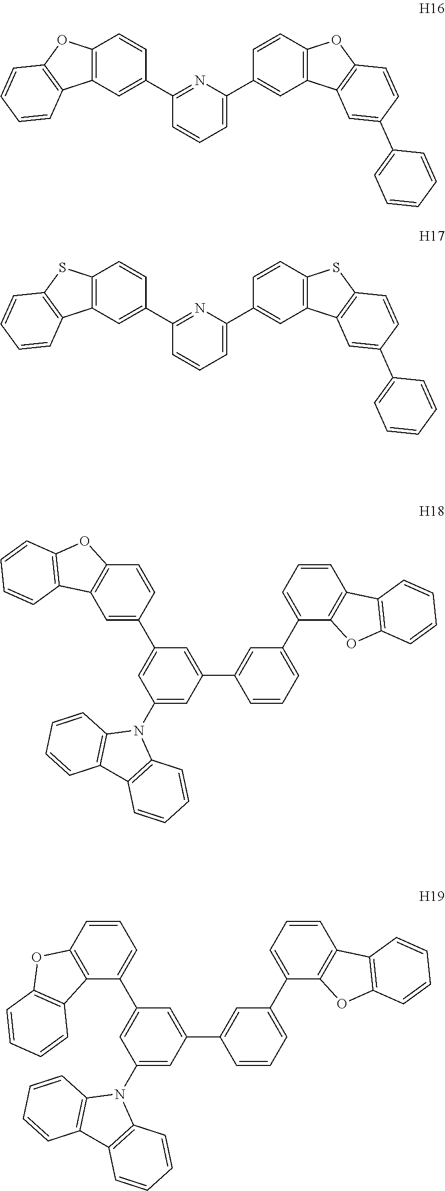 [SMILES: c1ccc(-c2ccc3oc4ccc(-c5cccc(-c6ccc7oc8ccccc8c7c6)n5)cc4c3c2)cc1 ; c1ccc(-c2ccc3sc4ccc(-c5cccc(-c6ccc7sc8ccccc8c7c6)n5)cc4c3c2)cc1 ; c1cc(-c2cc(-c3ccc4oc5ccccc5c4c3)cc(-n3c4ccccc4c4ccccc43)c2)cc(-c2cccc3c2oc2ccccc23)c1 ; c1cc(-c2cc(-c3cccc4oc5ccccc5c34)cc(-n3c4ccccc4c4ccccc43)c2)cc(-c2cccc3c2oc2ccccc23)c1]

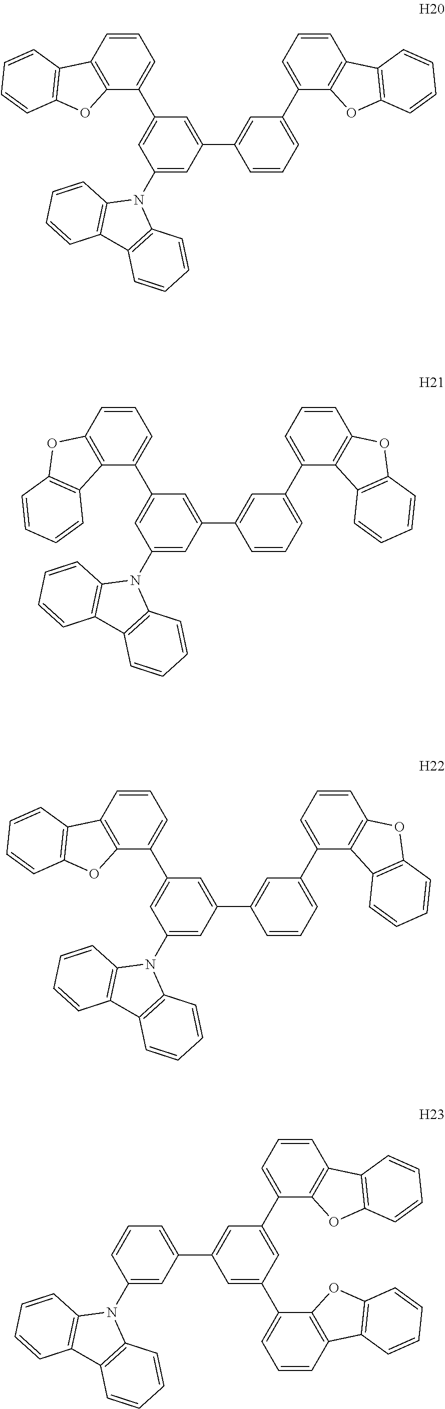 [SMILES: c1cc(-c2cc(-c3cccc4c3oc3ccccc34)cc(-n3c4ccccc4c4ccccc43)c2)cc(-c2cccc3c2oc2ccccc23)c1 ; c1cc(-c2cc(-c3cccc4oc5ccccc5c34)cc(-n3c4ccccc4c4ccccc43)c2)cc(-c2cccc3oc4ccccc4c23)c1 ; c1cc(-c2cc(-c3cccc4c3oc3ccccc34)cc(-n3c4ccccc4c4ccccc43)c2)cc(-c2cccc3oc4ccccc4c23)c1 ; c1cc(-c2cc(-c3cccc4c3oc3ccccc34)cc(-c3cccc4c3oc3ccccc34)c2)cc(-n2c3ccccc3c3ccccc32)c1]

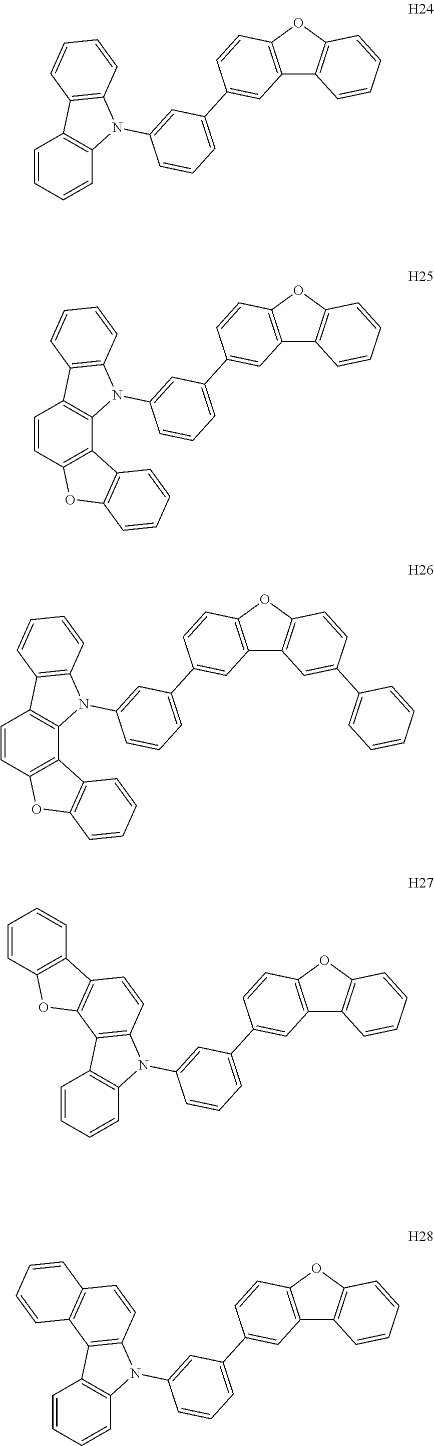 [SMILES: c1cc(-c2ccc3oc4ccccc4c3c2)cc(-n2c3ccccc3c3ccccc32)c1 ; c1cc(-c2ccc3oc4ccccc4c3c2)cc(-n2c3ccccc3c3ccc4oc5ccccc5c4c32)c1 ; c1ccc(-c2ccc3oc4ccc(-c5cccc(-n6c7ccccc7c7ccc8oc9ccccc9c8c76)c5)cc4c3c2)cc1 ; c1cc(-c2ccc3oc4ccccc4c3c2)cc(-n2c3ccccc3c3c4oc5ccccc5c4ccc32)c1 ; c1cc(-c2ccc3oc4ccccc4c3c2)cc(-n2c3ccccc3c3c4ccccc4ccc32)c1]

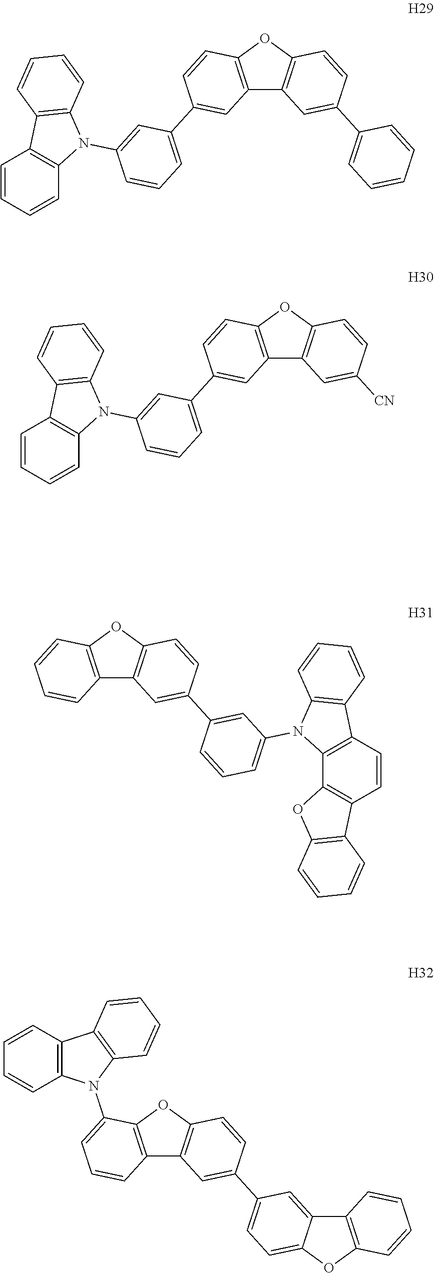 [SMILES: c1ccc(-c2ccc3oc4ccc(-c5cccc(-n6c7ccccc7c7ccccc76)c5)cc4c3c2)cc1 ; N#Cc1ccc2oc3ccc(-c4cccc(-n5c6ccccc6c6ccccc65)c4)cc3c2c1 ; c1cc(-c2ccc3oc4ccccc4c3c2)cc(-n2c3ccccc3c3ccc4c5ccccc5oc4c32)c1 ; c1ccc2c(c1)oc1ccc(-c3ccc4oc5c(-n6c7ccccc7c7ccccc76)cccc5c4c3)cc12]

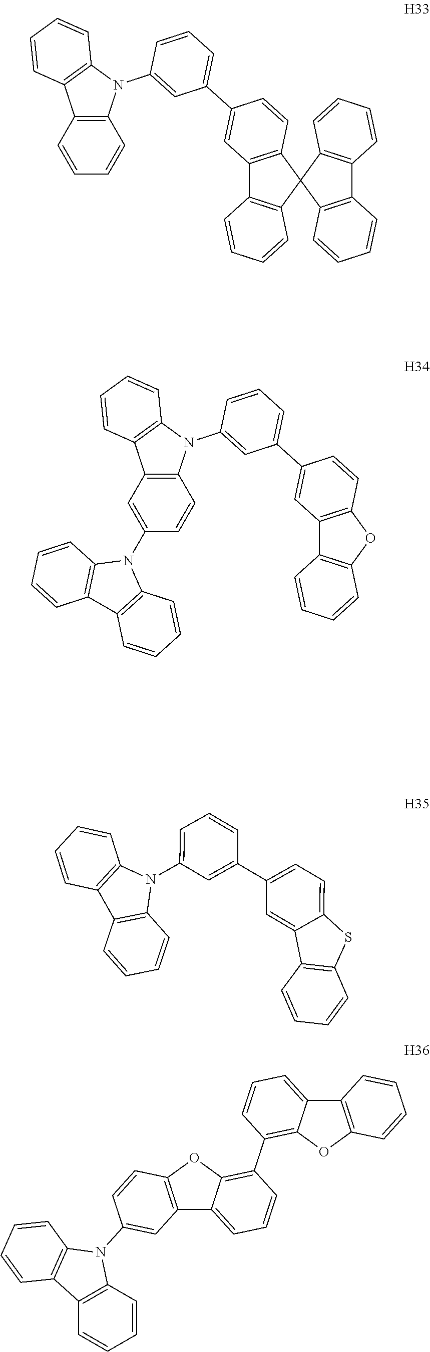 [SMILES: c1cc(-c2ccc3c(c2)-c2ccccc2C32c3ccccc3-c3ccccc32)cc(-n2c3ccccc3c3ccccc32)c1 ; c1cc(-c2ccc3oc4ccccc4c3c2)cc(-n2c3ccccc3c3cc(-n4c5ccccc5c5ccccc54)ccc32)c1 ; c1cc(-c2ccc3sc4ccccc4c3c2)cc(-n2c3ccccc3c3ccccc32)c1 ; c1ccc2c(c1)oc1c(-c3cccc4c3oc3ccc(-n5c6ccccc6c6ccccc65)cc34)cccc12]

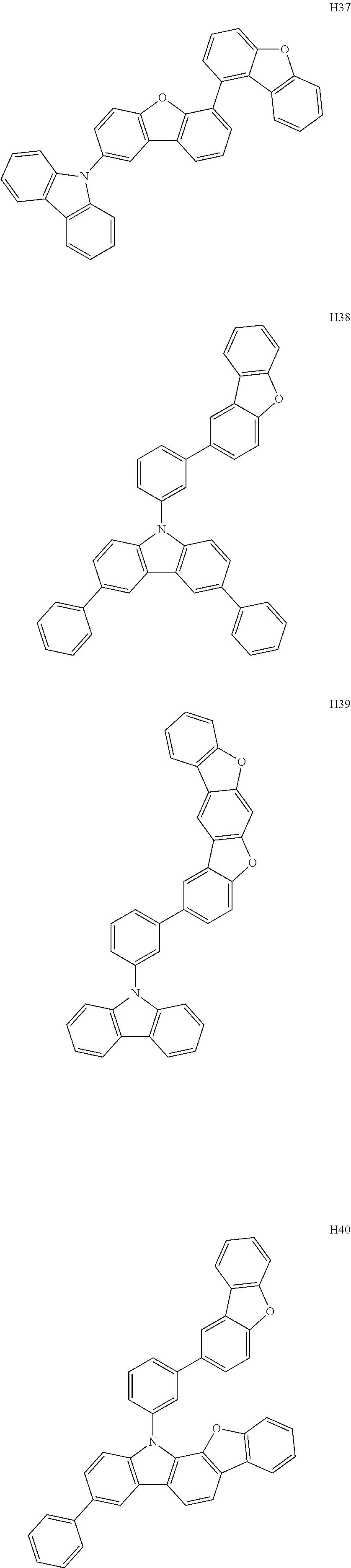 [SMILES: c1ccc2c(c1)oc1cccc(-c3cccc4c3oc3ccc(-n5c6ccccc6c6ccccc65)cc34)c12 ; c1ccc(-c2ccc3c(c2)c2cc(-c4ccccc4)ccc2n3-c2cccc(-c3ccc4oc5ccccc5c4c3)c2)cc1 ; c1cc(-c2ccc3oc4cc5oc6ccccc6c5cc4c3c2)cc(-n2c3ccccc3c3ccccc32)c1 ; c1ccc(-c2ccc3c(c2)c2ccc4c5ccccc5oc4c2n3-c2cccc(-c3ccc4oc5ccccc5c4c3)c2)cc1]

### Second Organic Compound

The second organic compound used in the light emitting layer of the organic electroluminescent device of the present invention is a delayed fluorescent material that has lowest excited singlet energy that is smaller than the first organic compound and is larger than the third organic compound, and has energy of the HOMO and LUMO that is smaller than the third organic compound. The “delayed fluorescent material” in the present invention is an organic compound that causes reverse intersystem crossing from the excited triplet state to the excited singlet state in the excited state, and emits fluorescent light (delayed fluorescent light) in returning the excited singlet state to the ground state. In the present invention, a compound emitting fluorescent light having a light emission lifetime of 100 ns (nanosecond) or more observed when measured by a fluorescent lifetime measurement system (such as a streak camera system available from Hamamatsu Photonics K.K.) is referred to as the delayed fluorescent material. The second organic compound is a material capable of emitting delayed fluorescent light, but it is not essential to emit delayed fluorescent light derived from the second organic compound used in the organic electroluminescent device of the present invention. The light emission from the second organic compound is preferably less than 10%, for example, may be less than 1%, may be less than 0.1%, or may be less than 0.01%, of the light emission from the organic electroluminescent device of the present invention, and may be the detection limit or less.

In the organic electroluminescent device of the present invention, the second organic compound transitions to the excited singlet state through reception of energy from the first organic compound in the excited singlet state. The second organic compound may transition to the excited triplet state through reception of energy from the first organic compound in the excited triplet state. The second organic compound has a small difference (ΔE_{ST}) between the excited singlet energy and the excited triplet energy, and therefore the second organic compound in the excited triplet state is likely to cause reverse intersystem crossing to the second organic compound in the excited singlet state. The second organic compound in the excited singlet state formed via these routes donates energy to the third organic compound, so as to allow the third organic compound to transition to the excited singlet state.

The second organic compound preferably has a difference ΔE_{ST} between the lowest excited singlet energy and the lowest excited triplet energy at 77 K of 0.3 eV or less, more preferably 0.25 eV or less, further preferably 0.2 eV or less, still further preferably 0.15 eV or less, still more further preferably 0.1 eV or less, even further preferably 0.07 eV or less, even still further preferably 0.05 eV or less, even still more further preferably 0.03 eV or less, and particularly preferably 0.01 eV or less.

With smaller ΔE_{ST}, the reverse intersystem crossing is likely to occur from the excited singlet state to the excited triplet state through reception of heat energy, and therefore the second organic compound functions as a heat activation type delayed fluorescent material. The heat activation type delayed fluorescent material relatively easily causes reverse intersystem crossing from the excited triplet state to the excited singlet state through reception of heat generated by the device, and can allow the excited triplet energy to contribute to the light emission efficiently.

In the present invention, the lowest excited singlet energy (E_{S}) and the lowest excited triplet energy (E_{T1}) of the compound are values that are obtained in the following procedure. ΔE_{ST} is a value that is obtained by calculating E_{S1}-E_{T1}.

### (1) Lowest Excited Singlet Energy (E_{S1})

A thin film or a toluene solution (concentration: 10⁻⁵ mol/L) of the target compound to be measured is prepared and designated as a specimen. The specimen was measured for the fluorescent spectrum at ordinary temperature (300 K). The fluorescent spectrum has an ordinate as the light emission and an abscissa as the wavelength. A tangent line is drawn to the rise on the short wavelength side of the light emission spectrum, and the wavelength value λ_{edge} (nm) at the intersection point of the tangent line and the abscissa is obtained. The wavelength value is converted to the energy value according to the following conversion expression, and is designated as E_{S1}.

E_{S1}(eV)=1239.85/λ_{edge} Conversion expression:

The measurement of the light emission spectrum in the examples described later is performed by using an LED light source (M300L4, available from Thorlabs, Inc.) as the excitation light source and a detector (PMA-12 Multichannel Spectroscope C10027-01, available from Hamamatsu Photonics K.K.).

### (2) Lowest Excited Triplet Energy (E_{T1})

The same specimen as used in the measurement of the lowest excited singlet energy (E_{S1}) is cooled to 77 (K) with liquid nitrogen, the specimen for measuring phosphorescent light is irradiated with excitation light (300 nm), and the phosphorescent light is measured with a detector. The light emission after 100 ms or later from the irradiation of excitation light is designated as a phosphorescent light spectrum. A tangent line is drawn to the rise on the short wavelength side of the phosphorescent light spectrum, and the wavelength value λ_{edge} (nm) at the intersection point of the tangent line and the abscissa is obtained. The wavelength value is converted to the energy value according to the following conversion expression, and is designated as E_{T1}.

E_{T1}(eV)=1239.85/λ_{edge} Conversion expression:

The tangent line to the rise on the short wavelength side of the phosphorescent light spectrum is drawn in the following manner. In moving on the spectrum curve to the maximum value on the shortest wavelength side among the maximum values of the spectrum from the short wavelength side of the phosphorescent light spectrum, tangent lines to points on the curve are considered toward the long wavelength side. The tangent lines increase the gradient as the curve rises (i.e., as the ordinate increases). The tangent line that is drawn on the point where the gradient value becomes maximum is designated as the tangent line to the rise on the short wavelength side of the phosphorescent light spectrum.

A maximum value having a peak intensity of 10% or less of the maximum peak intensity of the spectrum is not included in the aforementioned maximum value on the shortest wavelength side, and the tangent line drawn on the point where the gradient value becomes maximum that is closest to the maximum value on the shortest wavelength side is designated as the tangent line to the rise on the short wavelength side of the phosphorescent light spectrum.

The second organic compound preferably contains no metal atom. For example, a compound containing atoms selected from the group consisting of a carbon atom, a hydrogen atom, a nitrogen atom, an oxygen atom, and a sulfur atom may be selected as the second organic compound. For example, a compound containing atoms selected from the group consisting of a carbon atom, a hydrogen atom, a nitrogen atom, and an oxygen atom may be selected as the second organic compound. For example, a compound containing atoms selected from the group consisting of a carbon atom, a hydrogen atom, and a nitrogen atom may be selected as the second organic compound.

Typical examples of the second organic compound include a compound including a structure including a benzene ring having bonded thereto one or two cyano groups and at least one donor group. Preferred examples of the donor group include a substituted or unsubstituted carbazol-9-yl group. Examples of the compound include a compound including a benzene ring having bonded thereto 3 or more substituted or unsubstituted carbazol-9-yl groups, and a compound including a carbazol-9-yl group, at least one of the two benzene ring of which is condensed with a 5-membered ring of any of a substituted or unsubstituted benzofuran ring, a substituted or unsubstituted benzothiophene ring, a substituted or unsubstituted indole ring, a substituted or unsubstituted indene ring, and a substituted or unsubstituted silaindene ring.

The second organic compound used is preferably a compound represented by the following general formula (1) emitting delayed fluorescent light.

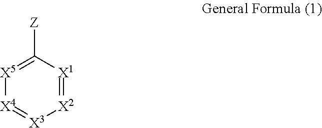

In the general formula (1), X¹ to X⁵ each represent N or C—R, in which R represents a hydrogen atom, a deuterium atom, or a substituent. In the case where two or more of X¹ to X⁵ represent C—R, the groups represented by C—R may be the same as or different from each other. At least one of X¹ to X⁵ represents C-D (wherein D represents a donor group). In the case where all X¹ to X⁵ represent C—R, Z represents an acceptor group.

The compound represented by the general formula (1) is particularly preferably a compound represented by the following general formula (2).

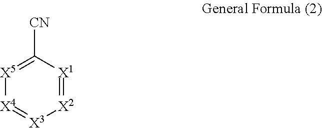

In the general formula (2), X¹ to X⁵ each represent N or C—R, in which R represents a hydrogen atom, a deuterium atom, or a substituent. In the case where two or more of X¹ to X⁵ represent C—R, the groups represented by C—R may be the same as or different from each other. At least one of X¹ to X⁵ represents C-D (wherein D represents a donor group).

In one preferred embodiment of the present invention, all X¹ to X⁵ do not represent C—CN, which accordingly provides a compound including a structure including a benzene ring having bonded thereto one or two cyano groups and at least one donor group. In another preferred embodiment of the present invention, only X² represents C—CN, and X¹ and X³ to X⁵ do not represent C—CN, which accordingly provides a compound including a structure including a benzene ring of isophthalonitrile having bonded thereto at least one donor group. In still another embodiment of the present invention, only X³ represents C—CN, and X¹, X², X⁴, and X⁵ do not represent C—CN, which accordingly provides a compound including a structure including a benzene ring of terephthalonitrile having bonded thereto at least one donor group.

The acceptor group that Z in the general formula (1) represents is a group that donates an electron to the ring to which Z bonds, and for example, can be selected from groups having a positive Hammett's σₚ value. The donor group that D in the general formula (1) and the general formula (2) represents is a group that attracts an electron from the ring to which D bonds, and for example, can be selected from groups having a negative Hammett's σₚ value. Hereinafter the acceptor group can be referred to as A.

Here, “Hammett's σₚ value” is one propounded by L. P. Hammett, and is one to quantify the influence of a substituent on the reaction rate or the equilibrium of a para-substituted benzene derivative. Specifically, the value is a constant (σₚ) peculiar to the substituent in the following equation that is established between a substituent and a reaction rate constant or an equilibrium constant in a para-substituted benzene derivative:

$$log ( k / {k}_{0} ) = ρ {σ}_{p} \\ or \\ log ( K / {K}_{0} ) = ρ {σ}_{p}$$

In the above equations, k represents a rate constant of a benzene derivative not having a substituent; k₀ represents a rate constant of a benzene derivative substituted with a substituent; K represents an equilibrium constant of a benzene derivative not having a substituent; K₀ represents an equilibrium constant of a benzene derivative substituted with a substituent; ρ represents a reaction constant to be determined by the kind and the condition of reaction. Regarding the description relating to the “Hammett's σₚ value” and the numerical value of each substituent, reference may be made to the description relating to σₚ value in Hansch, C. et. al., Chem. Rev., 91, 165-195 (1991).

Specific examples of the acceptor group include a cyano group and the acceptor groups preferred as A in the general formulae (12) to (14) described later. Specific examples of the donor group include the donor groups preferred as D in the general formulae (12) to (14) described later.

In the general formulae (1) and (2), X¹ to X⁵ each represent N or C—R, and at least one of which represents C-D. The number of N in X¹ to X⁵ is 0 to 4, and examples thereof include cases where X¹, X³, and X⁵ are N, X¹ and X³ are N, X¹ and X⁴ are N, X² and X³ are N, X¹ and X⁵ are N, X² and X⁴ are N, only X¹ is N, only X² is N, and only X³ is N. The number of C-D in X¹ to X⁵ is 1 to 5, and more preferably 2 to 5, and examples thereof include cases where X¹, X², X³, X⁴, and X⁵ are C-D, X¹, X², X⁴, and X⁵ are C-D, X¹, X², X³, and X⁴ are C-D, X¹, X³, X⁴, and X⁵ are C-D, X¹, X³, and X⁵ are C-D, X¹, X², and X⁵ are C-D, X¹, X², and X⁴ are C-D, X¹, X³, and X⁴ are C-D, XI and X³ are C-D, X¹ and X⁴ are C-D, X² and X³ are C-D, X¹ and X⁵ are C-D, X² and X⁴ are C-D, only X¹ is C-D, only X² is C-D, and only X³ is C-D. At least one of X¹ to X⁵ may be C-A, in which A represents an acceptor group. The number of C-A in X¹ to X⁵ is preferably 0 to 2, and more preferably 0 or 1. Preferred examples of A in C-A include a cyano group and a heterocyclic aromatic group having an unsaturated nitrogen atom. X¹ to X⁵ each independently may represent C-D or C-A.

In the case where adjacent two of X¹ to X⁵ represent C—R, two groups of R may be bonded to each other to form a cyclic structure. The cyclic structure formed by bonding to each other may be an aromatic ring or an aliphatic ring, and may contain a hetero atom, and the cyclic structure may also be a condensed ring of two or more rings. The hetero atom herein is preferably selected from the group consisting of a nitrogen atom, an oxygen atom, and a sulfur atom. Examples of the cyclic structure formed include a benzene ring, a naphthalene ring, a pyridine ring, a pyridazine ring, a pyrimidine ring, a pyrazine ring, a pyrrole ring, an imidazole ring, a pyrazole ring, an imidazoline ring, an oxazole ring, an isoxazole ring, a thiazole ring, an isothiazole ring, a cyclohexadiene ring, a cyclohexene ring, a cyclopentaene ring, a cycloheptatriene ring, a cycloheptadiene ring, a cycloheptaene ring, a furan ring, a thiophene ring, a naphthyridine ring, a quinoxaline ring, and a quinoline ring. For example, a ring including multiple rings condensed each other, such as a phenanthrene ring and a triphenylene ring, may also be formed.

The donor group D in the general formula (1) and the general formula (2) is preferably a group represented by, for example, the following general formula (3).

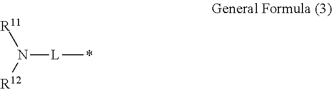

In the general formula (3), R¹¹ and R¹² each independently represent a substituted or unsubstituted alkyl group, a substituted or unsubstituted alkenyl group, a substituted or unsubstituted aryl group, or a substituted or unsubstituted heteroaryl group. R¹¹ and R¹² can bond to each other to form a cyclic structure. L represents a single bond, a substituted or unsubstituted arylene group, or a substituted or unsubstituted heteroarylene group. The substituent that can be introduced into the arylene group or the heteroarylene group of L can be the group represented by the general formula (1) or the general formula (2), or cab be a group represented by the general formulae (3) to (6) to be mentioned hereinunder. The groups represented by these (1) to (6) can be introduced in an amount up to the maximum number of the groups capable of being introduced into L. In the case where plural groups of the general formulae (1) to (6) are introduced, these substituents can be the same as or different from each other. * indicates the bonding position to the carbon atom (C) that constitutes the ring skeleton of the ring in the general formula (1) or the general formula (2).

Here, “alkyl group” can be linear, branched or cyclic. Two or more of a linear moiety, a cyclic moiety and a branched moiety can be in the group as mixed. The carbon number of the alkyl group can be, for example, 1 or more, 2 or more, or 4 or more. The carbon number can also be 30 or less, 20 or less, 10 or less, 6 or less, or 4 or less. Specific examples of the alkyl group include a methyl group, an ethyl group, an n-propyl group, an isopropyl group, an n-butyl group, an isobutyl group, a tert-butyl group, an n-pentyl group, an isopentyl group, an n-hexyl group, an isohexyl group, a 2-ethylhexyl group, an n-heptyl group, an isoheptyl group, an n-octyl group, an isooctyl group, an n-nonyl group, an isononyl group, an n-decanyl group, an isodecanyl group, a cyclopentyl group, a cyclohexyl group, and a cycloheptyl group. The alkyl group of a substituent can be further substituted with an aryl group.

“Alkenyl group” can be linear, branched or cyclic. Two or more of a linear moiety, a cyclic moiety and a branched moiety can be in the group as mixed. The carbon number of the alkyl group can be, for example, 2 or more, or 4 or more. The carbon number can also be 30 or less, 20 or less, 10 or less, 6 or less, or 4 or less. Specific examples of the alkenyl group include an ethenyl group, an n-propenyl group, an isopropenyl group, an n-butenyl group, an isobutenyl group, an n-pentenyl group, an isopentenyl group, an n-hexenyl group, an isohexenyl group, and a 2-ethylhexenyl group. The alkenyl group to be a substituent can be further substituted.

The “aryl group” and the “heteroaryl group” each may be a monocyclic ring or a condensed ring including two or more rings condensed. The number of rings condensed to form the condensed ring is preferably 2 to 6, and may be selected, for example, from 2 to 4. Specific examples of the ring include a benzene ring, a pyridine ring, a pyrimidine ring, a triazine ring, a napthalene ring, an anthracene ring, a phenanthrene ring, a triphenylene ring, a quinoline ring, a pyrazine ring, a quinoxaline ring, and a naphthyridine ring. Specific examples of the aryl group and the heteroaryl group include a phenyl group, a 1-naphtyl group, a 2-naphthyl group, a 1-anthracenyl group, a 2-anthracenyl group, a 9-anthracenyl group, a 2-pyridyl group, a 3-pyridyl group, and a 4-pyridyl group. The “arylene group” and the “heteroarylene group” may be groups obtained by changing the valence of the groups described for the aryl group and the heteroaryl group from 1 to 2.

The substituent means a monovalent group that can substitute a hydrogen atom, and is not a concept involving a condensed moiety. For the description and the preferred ranges of the substituent, reference may be made to the description and the preferred ranges for the substituent in the general formula (7) described later.

The compound represented by the general formula (3) is preferably a compound represented by any of the following general formulae (4) to (6).

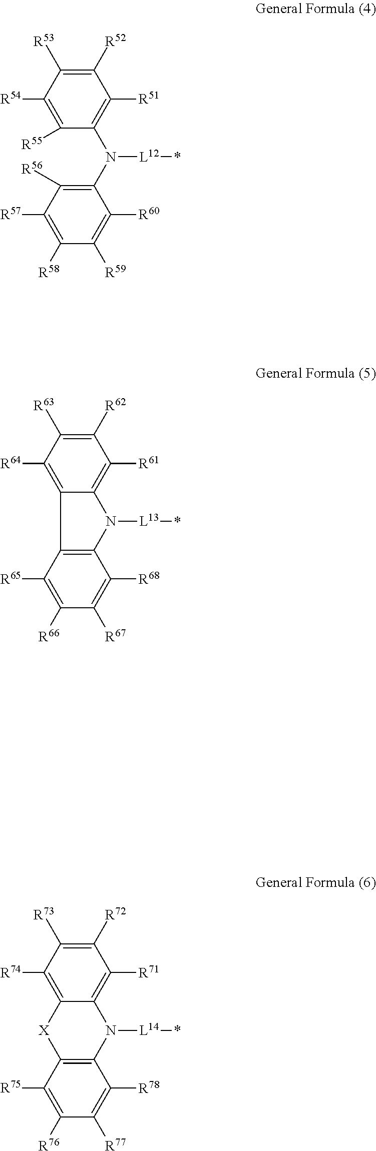

In the general formulae (4) to (6), R⁵¹ to R⁶⁰, R⁶¹ to R⁶⁸, and R⁷¹ to R⁷⁸ each independently represent a hydrogen atom, a deuterium atom, or a substituent. For the description and the preferred ranges of the substituent herein, reference may be made to the description and the preferred ranges for the substituent in the general formula (7) described later. R⁵¹ to R⁶⁰, R⁶¹ to R⁶⁸, and R⁷¹ to R⁷⁸ each independently preferably represent a group represented by any of the general formulae (4) to (6). The number of the substituent in the general formulae (4) to (6) is not limited. The case completely unsubstituted (i.e., all are hydrogen atoms or deuterium atoms) is also preferred. In the case where two or more substituents exist in the general formulae (4) to (6), the substituents may be the same as or different from each other. In the case where a substituent exists in the general formulae (4) to (6), the substituent is preferably any of R⁵² to R⁵⁹ for the general formula (4), any of R⁶² to R⁶⁷ for the general formula (5), and any of R⁷² to R⁷⁷ for the general formula (6).

In the general formula (6), X represents an oxygen atom, a sulfur atom, a substituted or unsubstituted nitrogen atom, a substituted or unsubstituted carbon atom, a substituted or unsubstituted silicon atom or a carbonyl group that is divalent and has a linking chain length of one atom, or represents a substituted or unsubstituted ethylene group, a substituted or unsubstituted vinylene group, a substituted or unsubstituted o-arylene group or a substituted or unsubstituted o-heteroarylene group that is divalent and has a linking chain length of two atoms. Regarding the specific examples and the preferred range of the substituents, reference can be made to the description of the substituents in the general formula (1) and the general formula (2).

In the general formulae (4) to (6), L¹² to L¹⁴ each represent a single bond, a substituted or unsubstituted arylene group or a substituted or unsubstituted heteroarylene group. Regarding the description and the preferred range of the arylene group and the heteroarylene group that L¹² to L¹⁴ represent, reference can be made to the description and the preferred range of the arylene group and the heteroarylene group that L represents. L¹² to L¹⁴ each are preferably a single bond, or a substituted or unsubstituted arylene group. Here the substituent for the arylene group and the heteroarylene group can be the group represented by the general formulae (1) to (6). The group represented by the general formulae (1) to (6) can be introduced into L¹² to L¹⁴ in an amount up to the maximum number of the substituents that can be introduced thereinto. In the case where plural groups of the general formulae (1) to (6) are introduced, these substituents can be the same as or different from each other. * indicates the bonding position to the carbon atom (C) that constitutes the ring skeleton of the ring in the general formula (1) or the general formula (2).

In the general formulae (4) to (6), R⁵¹ and R⁵², R⁵² and R⁵³, R⁵³ and R⁵⁴, R⁵⁴ and R⁵⁵, R⁵⁵ and R⁵⁶, R⁵⁶ and R⁵⁷, R⁵⁷ and R⁵⁸, R⁵⁸ and R⁵⁹, R⁵⁹ and R⁶⁰, R⁶¹ and R⁶², R⁶² and R⁶³, R⁶³ and R⁶⁴, R⁶⁵ and R⁶⁶, R⁶⁶ and R⁶⁷, R⁶⁷ and R⁶⁸, R⁷¹ and R⁷², R⁷² and R⁷³, R⁷³ and R⁷⁴, R⁷⁵ and R⁷⁶, R⁷⁶ and R⁷⁷, and R⁷⁷ and R⁷⁸ each may be bonded to each other to form a cyclic structure. For the description and the preferred ranges of the cyclic structure, reference may be made to the description and the preferred ranges for the cyclic structure of X¹ to X⁵ in the general formulae (1) and (2).

Preferred examples of the cyclic structure include a structure including a substituted or unsubstituted benzofuran ring, a substituted or unsubstituted benzothiophene ring, a substituted or unsubstituted indole ring, a substituted or unsubstituted indene ring, or a substituted or unsubstituted silaindene ring that is condensed to at least one benzene rings of the general formulae (4) to (6). More preferred examples thereof include a group represented by any of the following general formulae (5a) to (5f) obtained by condensing to the general formula (5).

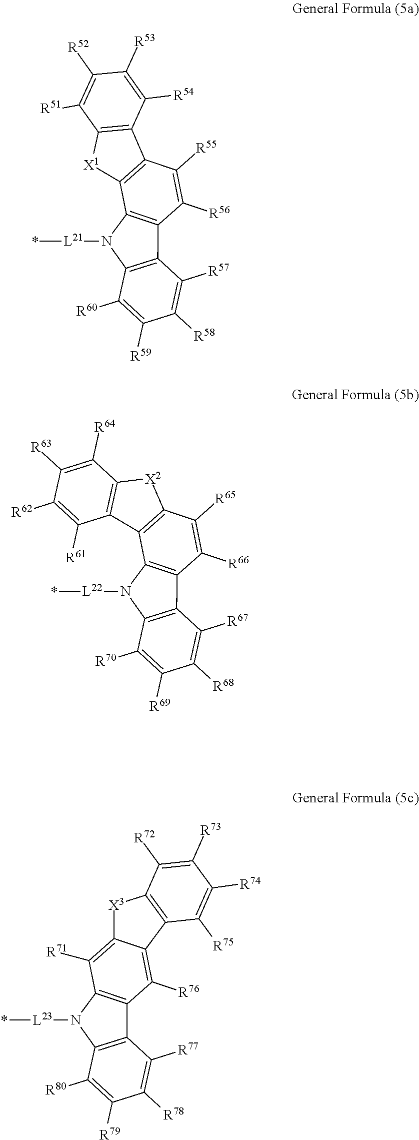

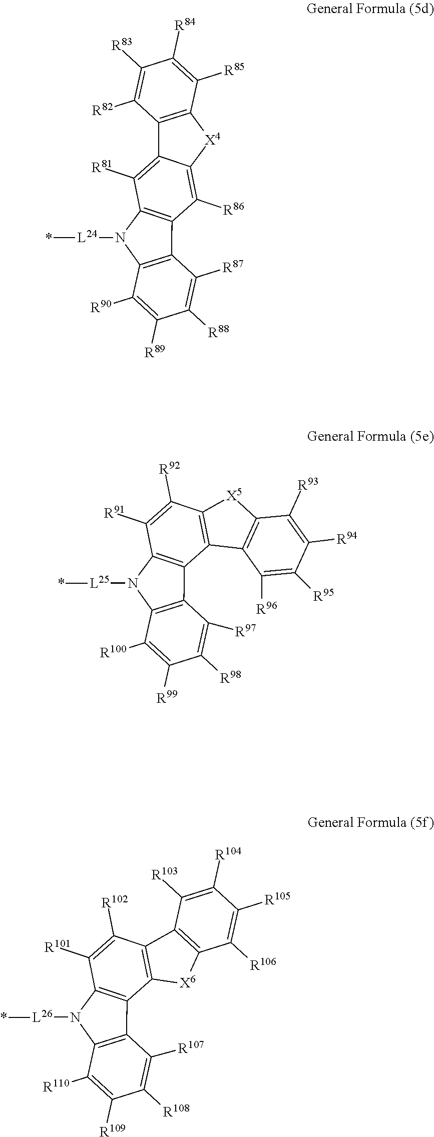

In the general formulae (5a) to (5f), L¹¹ and L²¹ to L²⁶ each represent a single bond or a divalent linking group. For the description and the preferred ranges of L¹³ and L²¹ to L²⁶, reference may be made to the description and the preferred ranges for L² described above.

In the general formulae (5a) to (5f), R⁴¹ to R¹¹⁰ each independently represent a hydrogen atom or a substituent. R⁴¹ and R⁴², R⁴² and R⁴³, R⁴³ and R⁴⁴, R⁴⁴ and R⁴⁵, R⁴⁵ and R⁴⁶, R⁴⁶ and R⁴⁷, R⁴⁷ and R⁴⁸, R⁵¹ and R⁵², R⁵² and R⁵³, R⁵³ and R⁵⁴, R⁵⁴ and R⁵⁵, R⁵⁵ and R⁵⁶, R⁵⁶ and R⁵⁷, R⁵⁷ and R⁵⁸, R⁵⁸ and R⁵⁹, R⁵⁹ and R⁶⁰, R⁶¹ and R⁶², R⁶² and R⁶³, R⁶³ and R⁶⁴, R⁶⁵ and R⁶⁶, R⁶⁶ and R⁶⁷, R⁶⁷ and R⁶⁸, R⁶⁸ and R⁶⁹, R⁶⁹ and R⁷⁰, R⁷² and R⁷³, R⁷³ and R⁷⁴, R⁷⁴ and R⁷⁵, R⁷⁵ and R⁷⁶, R⁷⁶ and R⁷⁷, R⁷⁷ and R⁷⁸, R⁷⁸ and R⁷⁹, R⁷⁹ and R⁸⁰, R⁸¹ and R⁸², R⁸² and R⁸³, R⁸³ and R⁸⁴, R⁸⁴ and R⁸⁵, R⁸⁶ and R⁸⁷, R⁸⁷ and R⁸⁸, R⁸⁸ and R⁸⁹, R⁸⁹ and R⁹⁰, R⁹¹ and R⁹², R⁹³ and R⁹⁴, R⁹⁴ and R⁹⁵, R⁹⁵ and R⁹⁶, R⁹⁶ and R⁹⁷, R⁹⁷ and R⁹⁸, R⁹⁹ and R¹⁰⁰, R¹⁰¹ and R¹⁰², R¹⁰² and R¹⁰³, R¹⁰³ and R¹⁰⁴, R¹⁰⁴ and R¹⁰⁵, R¹⁰⁵ and R¹⁰⁶, R¹⁰⁷ and R¹⁰⁸, R¹⁰⁸ and R^{109,} and R¹⁰⁹ and R¹¹⁰ each may be bonded to each other to form a cyclic structure. The cyclic structure formed by bonding to each other may be an aromatic ring or an aliphatic ring, and may contain a hetero atom, and the cyclic structure may also be a condensed ring of two or more rings. The hetero atom herein is preferably selected from the group consisting of a nitrogen atom, an oxygen atom, and a sulfur atom. Examples of the cyclic structure formed include a benzene ring, a naphthalene ring, a pyridine ring, a pyridazine ring, a pyrimidine ring, a pyrazine ring, a pyrrole ring, an imidazole ring, a pyrazole ring, an imidazoline ring, an oxazole ring, an isoxazole ring, a thiazole ring, an isothiazole ring, a cyclohexadiene ring, a cyclohexene ring, a cyclopentaene ring, a cycloheptatriene ring, a cycloheptadiene ring, a cycloheptaene ring, a furan ring, a thiophene ring, a naphthyridine ring, a quinoxaline ring, and a quinoline ring. For example, a ring including multiple rings condensed each other, such as a phenanthrene ring and a triphenylene ring, may also be formed. The number of rings contained in the group represented by the general formula (6) may be selected from a range of 3 to 5, and may be selected from a range of 5 to 7. The number of rings contained in the group represented by the general formulae (5a) to (5f) may be selected from a range of 5 to 7, and may be 5.

Examples of the substituent that R⁴¹ to R¹¹⁰ each can represent include the groups of the substituent group B, and preferred examples thereof include an unsubstituted alkyl group having 1 to 10 carbon atoms, and an aryl group having 6 to 10 carbon atoms, which may be substituted by an unsubstituted alkyl group having 1 to 10 carbon atoms. In one preferred embodiment of the present invention, R⁴¹ to R¹¹⁰ each represent a hydrogen atom or an unsubstituted alkyl group having 1 to 10 carbon atoms. In one preferred embodiment of the present invention, R⁴¹ to R¹¹⁰ each represent a hydrogen atom or an unsubstituted aryl group having 6 to 10 carbon atoms. In one preferred embodiment of the present invention, all R⁴¹ to R¹¹⁰ represent hydrogen atoms.

In the general formulae (5a) to (5f), the carbon atoms, to which R⁴¹ to R¹¹⁰ are bonded, (i.e., ring skeleton-forming carbon atoms) each may be replaced by a nitrogen atom. Accordingly, in the general formulae (5a) to (5f), C—R⁴¹ to C—R¹¹⁰ each independently may be replaced by N. The number of a carbon atom that is replaced by a nitrogen atom is preferably 0 to 4, and more preferably 1 to 2, in the group represented by the general formulae (5a) to (5f). In one embodiment of the present invention, the number of a carbon atom that is replaced by a nitrogen atom is 0. In the case where 2 or more carbon atoms are replaced by nitrogen atoms, the number of a nitrogen atom that is substituted in one ring is preferably 1.

In the general formulae (5a) to (5f), X¹ to X⁶ each represent an oxygen atom, a sulfur atom, or N—R. In one embodiment of the present invention, X¹ to X⁶ represent oxygen atoms. In one embodiment of the present invention, X¹ to X⁶ represent sulfur atoms. In one embodiment of the present invention, X¹ to X⁶ represent N—R. R represents a hydrogen atom or a substituent, and preferably represents a substituent. Examples of the substituent include the groups of the substituent group A described later. Preferred examples thereof used include an unsubstituted phenyl group and a phenyl group substituted by one group selected from an alkyl group and an aryl group, or a group combining two or more thereof.

In the general formulae (5a) to (5f), * indicates the bonding position.

In the present invention, a compound represented by the following general formula (7) emitting delayed fluorescent light is particularly preferably used as the delayed fluorescent material. In a preferred embodiment of the present invention, a compound represented by the general formula (7) may be used as the second organic compound.

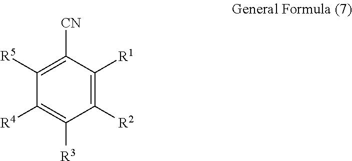

In the general formula (7), 0 to 4 of R¹ to R⁵ represent a cyano group, at least one of R¹ to R⁵ represent a substituted amino group, and the rest of R¹ to R⁵ represent a hydrogen atom, a deuterium atom, or a substituent other than a cyano group and a substituted amino group.

The substituted amino group herein is preferably a substituted or unsubstituted diarylamino group, in which two aryl groups constituting the substituted or unsubstituted diarylamino group may be bonded to each other. The aryl groups may be bonded via a single bond (resulting in a carbazole ring in this case), or may be bonded via a linking group, such as —O—, —S—, —N(R⁶)—, —C(R⁷)(R⁸)—, and Si(R⁹)(R¹⁰)—, wherein R⁶ to R¹⁰ each represent a hydrogen atom, a deuterium atom, or a substituent, and R⁷ and R⁸, and R⁹ and R¹⁰ each may be bonded to each other to form a cyclic structure.

The substituted amino group may be any of R¹ to R⁵, and for example, R¹ and R²; R¹ and R³; R¹ and R⁴; R¹ and R⁵; R² and R³; R² and R⁴; R¹ and R² and R³; R¹, R², and R⁴; R¹, R², and R⁵; R¹, R³, and R⁴; R¹, R³, and R⁵; R², R³, and R⁴; R¹, R², R³, and R⁴; R¹, R², R³, and R⁵; R¹, R², R⁴, and R⁵; or R¹, R², R³, R⁴, and R⁵ may be a substituted amino group. The cyano group may also be any of R¹ to R⁵, and for example, R¹; R²; R³; R¹ and R²; R¹ and R³; R¹ and R⁴; R¹ and R⁵; R² and R³; R² and R⁴; R¹, R², and R³; R¹, R², and R⁴; R¹, R², and R⁵; R¹, R³, and R⁴; R¹, R³, and R⁵; or R², R³, and R⁴ may be a cyano group.

R¹ to R⁵ that are not a cyano group and a substituted amino group represent a hydrogen atom, a deuterium atom, or a substituent. Examples of the substituent herein include a substituent group A consisting of a hydroxy group, a halogen atom (such as a fluorine atom, a chlorine atom, a bromine atom, and an iodine atom), an alkyl group (for example, having 1 to 40 carbon atoms), an alkoxy group (for example, having 1 to 40 carbon atoms), an alkylthio group (for example, having 1 to 40 carbon atoms), an aryl group (for example, having 6 to 30 carbon atoms), an aryloxy group (for example, having 6 to 30 carbon atoms), an arylthio group (for example, having 6 to 30 carbon atoms), a heteroaryl group (for example, having 5 to 30 ring skeleton-forming carbon atoms), a heteroaryloxy group (for example, having 5 to 30 ring skeleton-forming carbon atoms), a heteroarylthio group (for example, having 5 to 30 ring skeleton-forming carbon atoms), an acyl group (for example, having 1 to 40 carbon atoms), an alkenyl group (for example, having 1 to 40 carbon atoms), an alkynyl group (for example, having 1 to 40 carbon atoms), an alkoxycarbonyl group (for example, having 1 to 40 carbon atoms), an aryloxycarbonyl group (for example, having 1 to 40 carbon atoms), a heteroaryloxycarbonyl group (for example, having 1 to 40 carbon atoms), a silyl group (for example, a trialkylsilyl group having 1 to 40 carbon atoms), a nitro group, and one of these groups substituted by one of these groups. Preferred examples of the substituent in the case where the aryl group of the diarylamino group is substituted include the groups of the substituent group A, and also include a cyano group and a substituted amino group.

For the specific examples of the compound group and the compounds encompassed in the general formula (7), reference may be made to WO 2013/154064, paragraphs 0008 to 0048; WO 2015/080183, paragraphs 0009 to 0030; WO 2015/129715, paragraphs 0006 to 0019; JP 2017-119663 A, paragraphs 0013 to 0025; and JP 2017-119664 A, paragraphs 0013 to 0026, which are incorporated as a part of this description by reference.

A compound represented by the following general formula (8) emitting delayed fluorescent light is also particularly preferably used as the delayed fluorescent material in the present invention. In a preferred embodiment of the present invention, a compound represented by the general formula (8) may be used as the second organic compound.

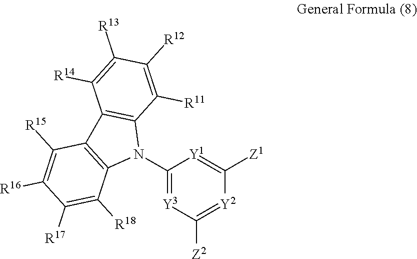

In the general formula (8), any two of Y¹, Y², and Y³ represent nitrogen atoms, and the remaining one thereof represents a methine group, or all Y¹, Y², and Y³ represent nitrogen atoms. Z¹ and Z² each independently represent a hydrogen atom, a deuterium atom, or a substituent, R¹¹ to R¹⁸ each independently represent a hydrogen atom, a deuterium atom, or a substituent, in which at least one of R¹¹ to R¹⁸ preferably represents a substituted or unsubstituted arylamino group or a substituted or unsubstituted carbazolyl group. The benzene ring constituting the arylamino group and the benzene ring constituting the carbazolyl group each may form a single bond or a linking group with R¹¹ to R¹⁸. The compound represented by the general formula (8) includes at least two carbazole structures in the molecule thereof. Examples of the substituent that Z¹ and Z² can represent include the groups of the substituent group A. Specific examples of the substituent that R¹¹ to R¹⁸, the arylamino group, and the carbazolyl group can have include the groups of the substituent group A, a cyano group, a substituted arylamino group, and a substituted alkylamino group. R¹¹ and R¹², R¹² and R¹³, R¹³ and R¹⁴, R¹⁵ and R¹⁶, R¹⁶ and R^{17,} and R¹⁷ and R¹⁸ each may be bonded to each other to form a cyclic structure.

In the compound represented by the general formula (8), a compound represented by the following general formula (9) is particularly useful.

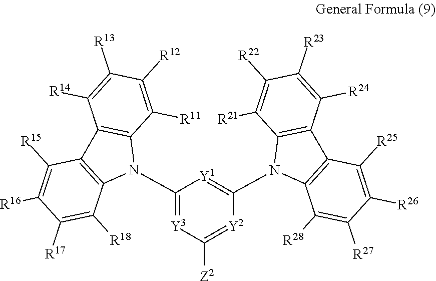

In the general formula (9), any two of Y¹, Y², and Y³ represent nitrogen atoms, and the remaining one thereof represents a methine group, or all Y¹, Y², and Y³ represent nitrogen atoms. Z² represents a hydrogen atom, a deuterium atom, or a substituent. R¹¹ to R¹⁸ and R²¹ to R²⁸ each independently represent a hydrogen atom, a deuterium atom, or a substituent, in which at least one of R¹ to R¹⁸ and/or at least one of R²¹ to R²⁸ preferably represents a substituted or unsubstituted arylamino group or a substituted or unsubstituted carbazolyl group. The benzene ring constituting the arylamino group and the benzene ring constituting the carbazolyl group each may form a single bond or a linking group with R¹¹ to R¹⁸ or R²¹ to R²⁸. Examples of the substituent that Z² can represent include the groups of the substituent group A. Specific examples of the substituent that R¹ to R¹⁸, R²¹ to R²⁸, the arylamino group, and the carbazolyl group can have include the groups of the substituent group A, a cyano group, a substituted arylamino group, and a substituted alkylamino group. R¹¹ and R¹², R¹² and R¹³, R¹³ and R¹⁴, R¹⁵ and R¹⁶, R¹⁶ and R¹⁷, R¹⁷ and R¹⁸, R²¹ and R²², R²² and R²³, R²³ and R²⁴, R²⁵ and R²⁶, R²⁶ and R²⁷, and R²⁷ and R²⁸ each may be bonded to each other to form a cyclic structure.

For the specific examples of the compound group and the compounds encompassed in the general formula (9), reference may be made to the compounds described in WO 2013/081088, paragraphs 0020 to 0062, and Appl. Phys. Let., 98, 083302 (2011), which are incorporated as a part of this description by reference.

A compound represented by the following general formula (10) emitting delayed fluorescent light is also particularly preferably used as the delayed fluorescent material in the present invention.

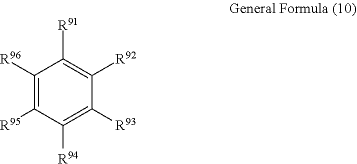

In the general formula (10), R⁹¹ to R⁹⁶ each independently represent a hydrogen atom, a deuterium atom, a donor group, or an acceptor group, in which at least one thereof is the donor group, and at least two thereof are the acceptor groups. The substitution positions of the at least two acceptor groups are not particularly limited, and it is preferred that two acceptor groups that are in meta-positions are contained. For example, in the case where R⁹¹ represents the donor group, preferred examples of the structure include a structure where at least R⁹² and R⁹⁴ represent the acceptor groups, and a structure where at least R⁹² and R⁹% represent the acceptor groups. The acceptor groups existing in the molecule may be the same as or different from each other, and a structure where all the groups are the same may be employed. The number of the acceptor groups is preferably 2 to 3, and for example, 2 may be selected therefor. Two or more donor groups may exist, and in this case, the donor groups may be the same as or different from each other. The number of donor group is preferably 1 to 3, and for example, may be 1, or may be 2. For the description and the preferred ranges of the donor group and the acceptor group, reference may be made to the description and the preferred ranges for D and Z in the general formula (1). In the general formula (10), in particular, the donor group is preferably a group represented by the general formula (3), and the acceptor group is preferably a cyano group or a group represented by the following general formula (11).

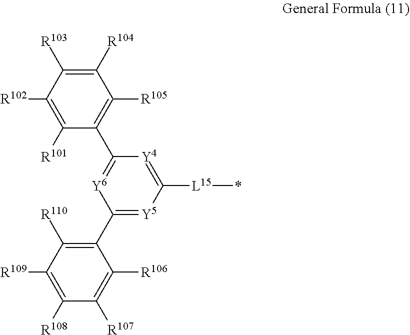

In the general formula (11), Y⁴ to Y⁶ each represent a nitrogen atom or a methine group, in which at least one thereof represents a nitrogen atom, and all thereof preferably represent nitrogen atoms. R¹⁰¹ to R¹¹ each independently represent a hydrogen atom, a deuterium atom, or a substituent, in which at least one thereof preferably represents an alkyl group. For the description and the preferred ranges of the substituent herein, reference may be made to the description and the preferred ranges for the substituent in the general formula (7). L¹⁵ represents a single bond or a linking group, and therefor, reference may be made to the description and the preferred ranges for L in the general formula (3). In one preferred embodiment of the present invention, L¹⁵ in the general formula (11) represents a single bond. * indicates the bonding position to the carbon atom (C) constituting the ring skeleton of the ring in the general formula (10).

In another preferred embodiment of the present invention, a compound represented by the following general formula (12) may be used as the second organic compound. The compound represented by the general formula (12) encompasses a compound represented by the following general formula (12a).

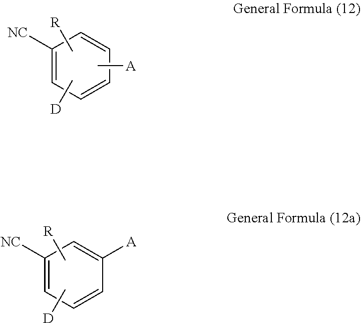

Particularly preferred examples of the compound represented by the general formula (12) include a compound represented by the following general formula (13) and a compound represented by the following general formula (14).

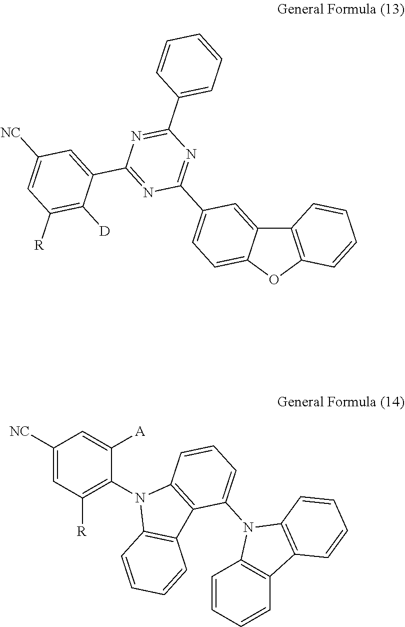

In the general formulae (12) to (14), D represents a donor group, A represents an acceptor group, and R represents a hydrogen atom, a deuterium atom, or a substituent. For the description and the preferred ranges of the donor group and the acceptor group, reference may be made to the description and the preferred ranges for the corresponding parts in the general formula (1). Examples of the substituent represented by R include an alkyl group, and an aryl group that may be substituted by one group or a group combining two or more groups selected from the group consisting of an alkyl group and an aryl group.

Specific examples of the donor group that is preferred as D in the general formulae (12) to (14) are shown below. In the following specific examples, * indicates the bonding position, and “D” represents a deuterium atom. In the following specific examples, the hydrogen atom may be substituted, for example, by an alkyl group, and a substituted or unsubstituted benzene ring may be further condensed thereto.

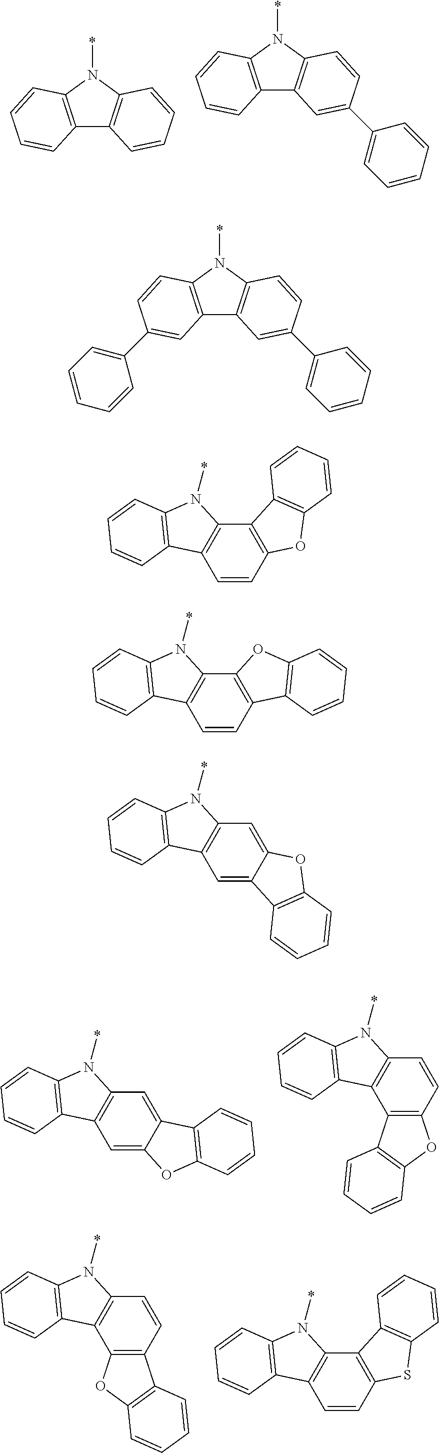

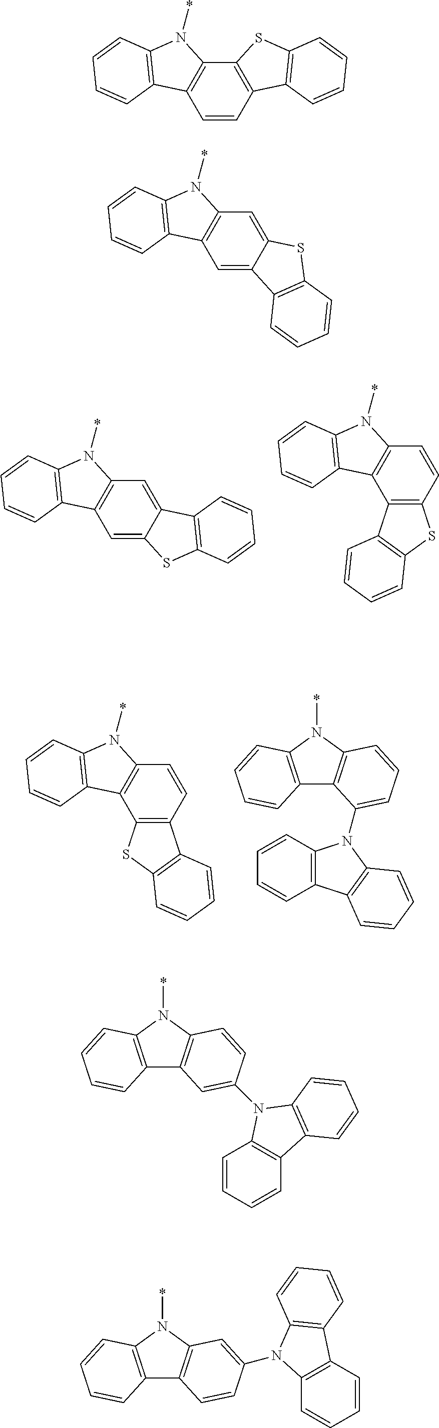

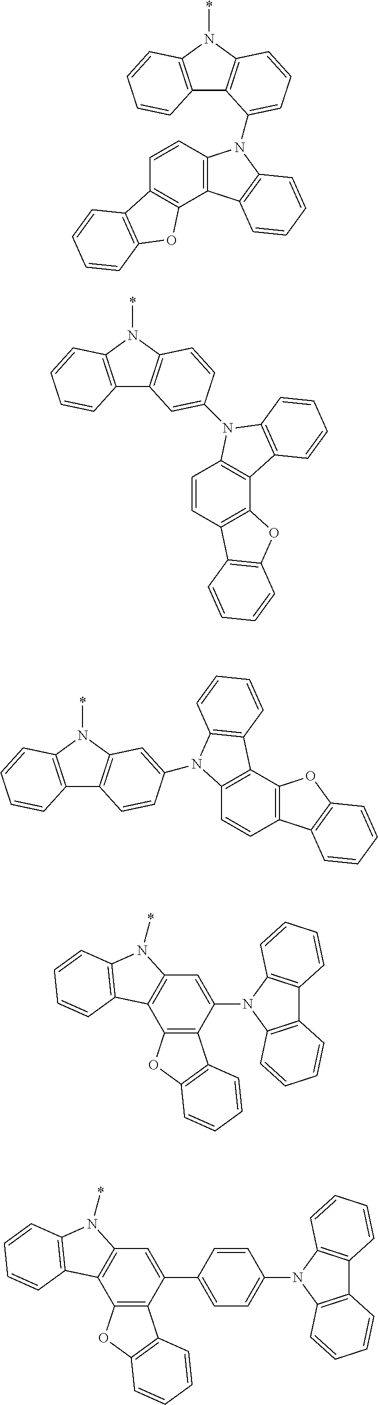

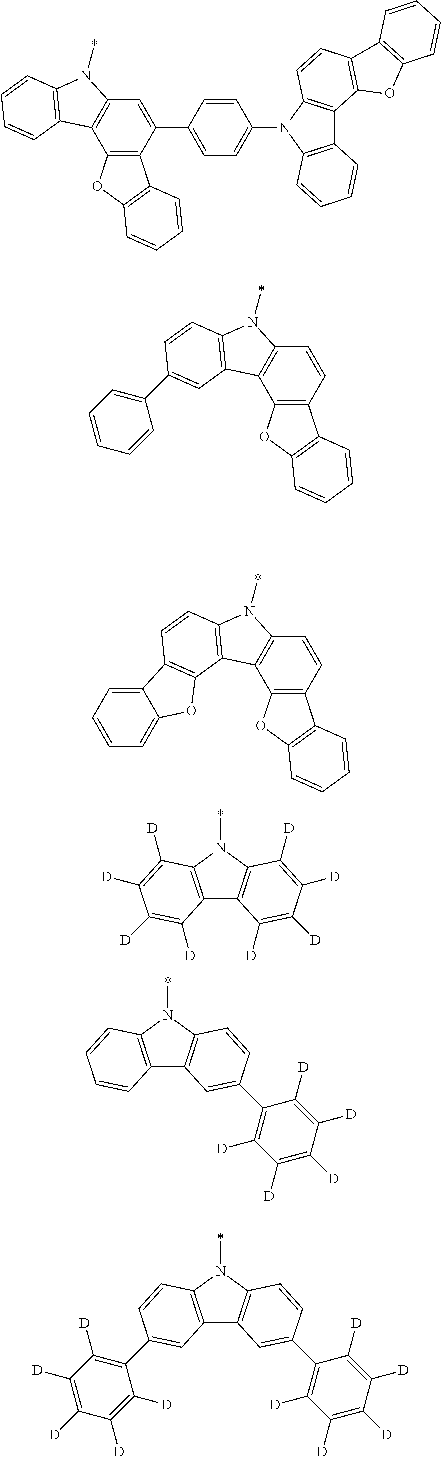

Specific examples of the acceptor group that is preferred as A in the general formulac (12) to (14) are shown below. In the following specific examples. * indicates the bonding position, and “D” represents a deuterium atom.

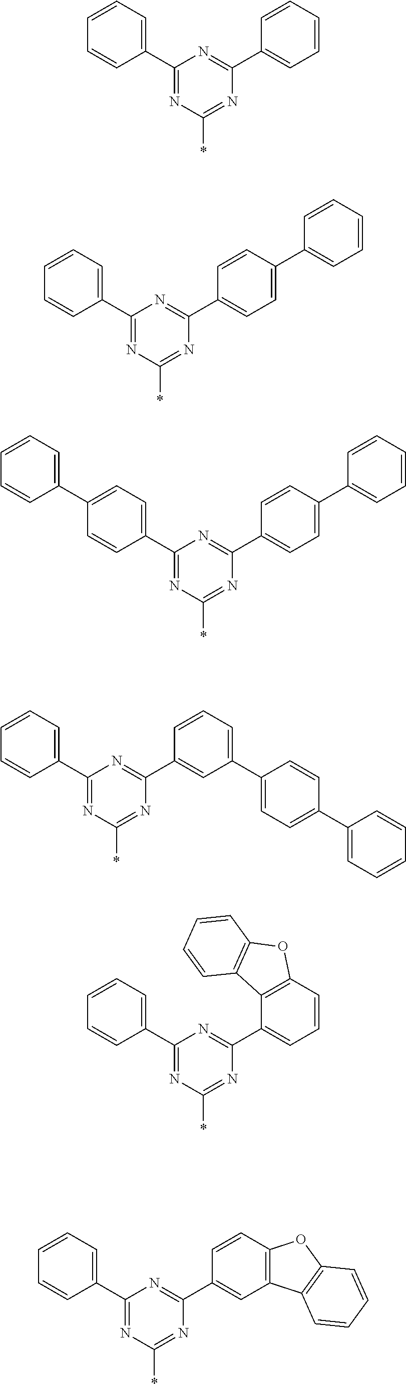

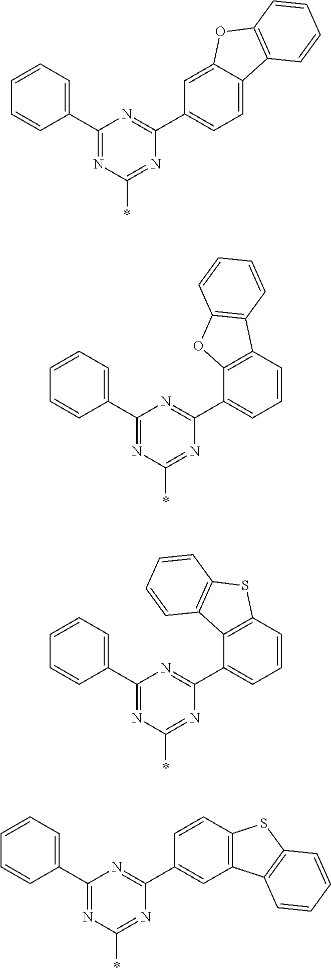

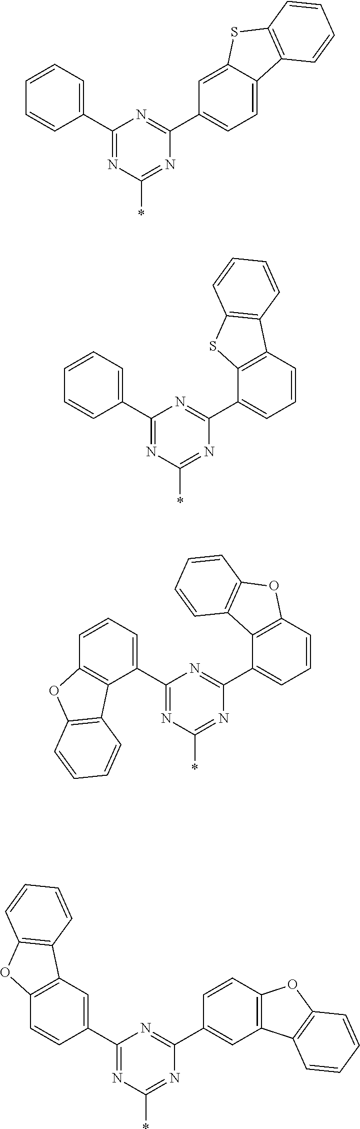

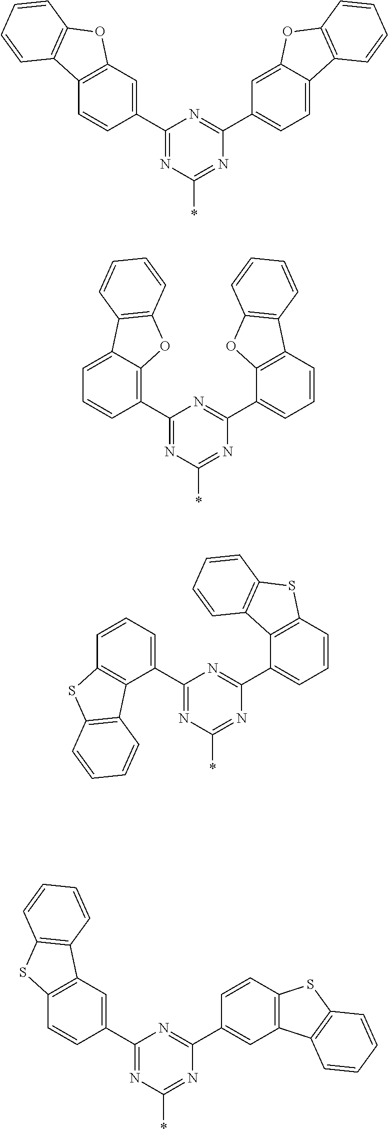

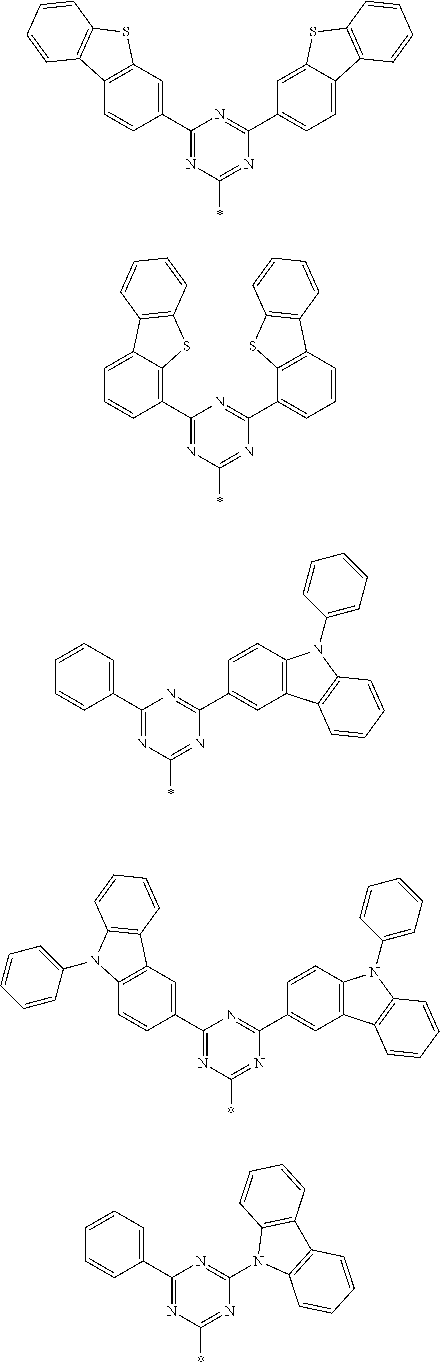

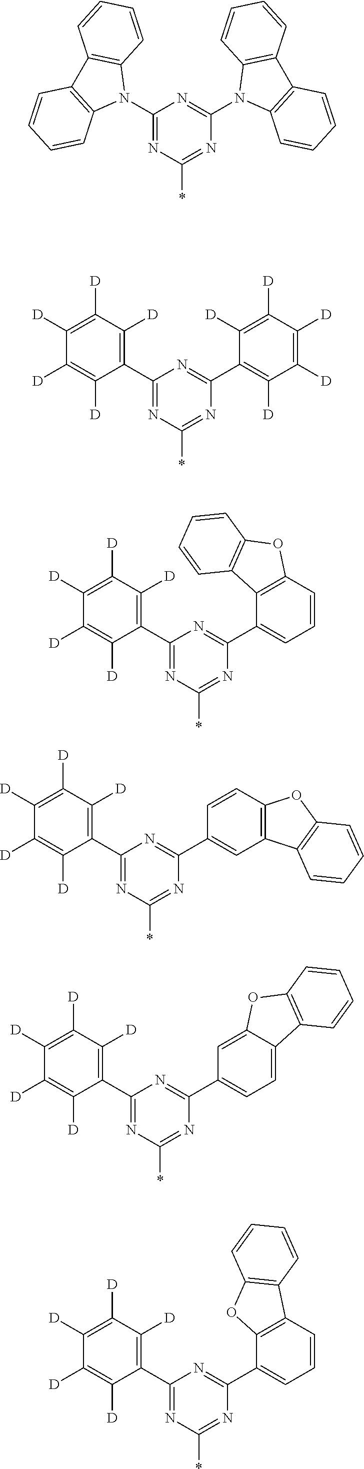

Specific examples of R in the general formulae (12) to (14) are shown below. In the following specific examples, * indicates the bonding position, and “D” represents a deuterium atom.

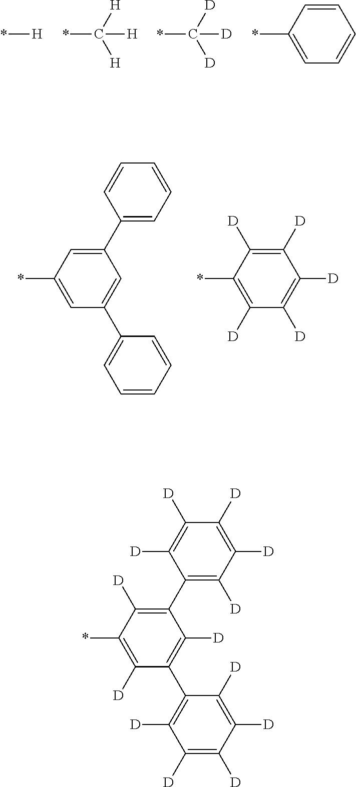

Preferred examples of the compound that can be used as the second organic compound are shown below. In the following structural formulae of the example compounds, t-Bu represents a tert-butyl group.

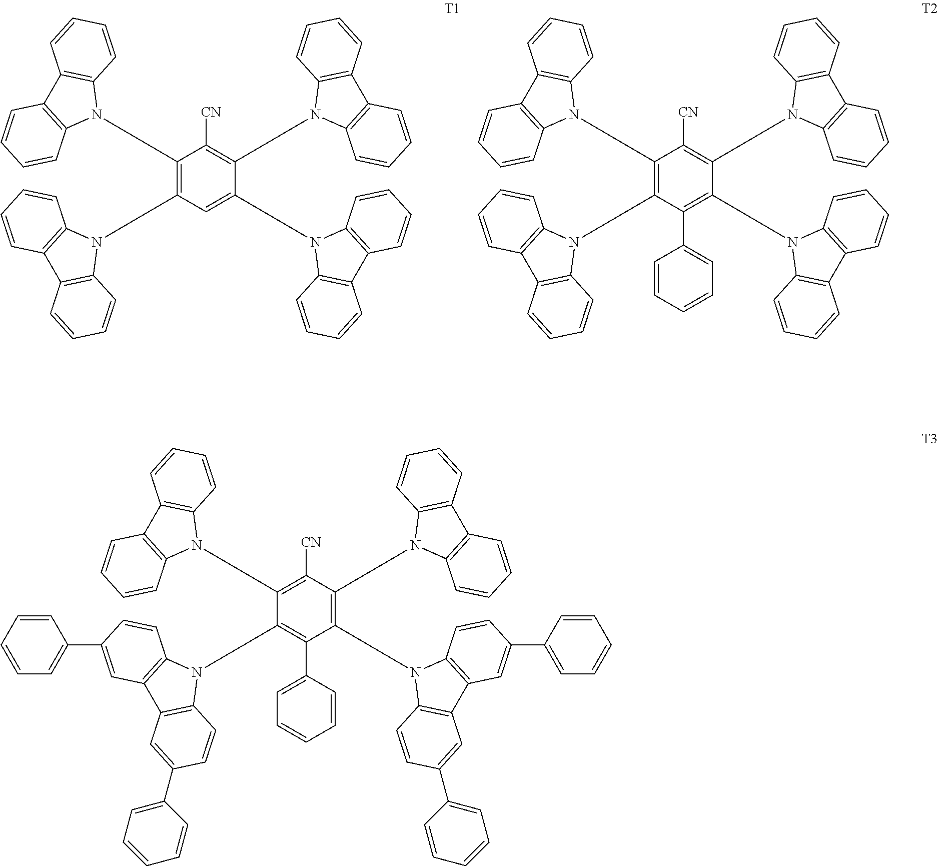 [SMILES: N#Cc1c(-n2c3ccccc3c3ccccc32)c(-n2c3ccccc3c3ccccc32)cc(-n2c3ccccc3c3ccccc32)c1-n1c2ccccc2c2ccccc21 ; N#Cc1c(-n2c3ccccc3c3ccccc32)c(-n2c3ccccc3c3ccccc32)c(-c2ccccc2)c(-n2c3ccccc3c3ccccc32)c1-n1c2ccccc2c2ccccc21 ; N#Cc1c(-n2c3ccccc3c3ccccc32)c(-n2c3ccc(-c4ccccc4)cc3c3cc(-c4ccccc4)ccc32)c(-c2ccccc2)c(-n2c3ccc(-c4ccccc4)cc3c3cc(-c4ccccc4)ccc32)c1-n1c2ccccc2c2ccccc21]

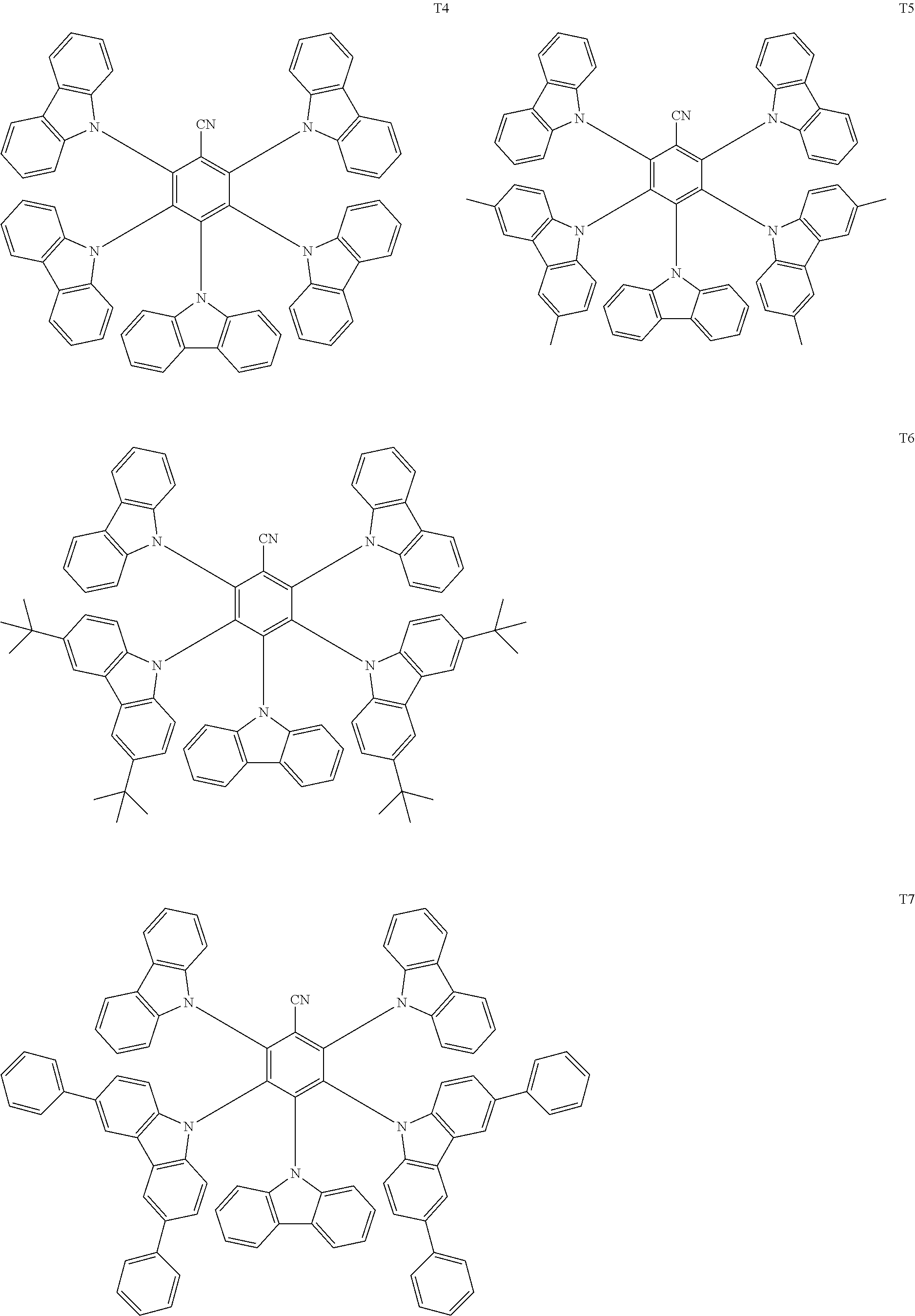

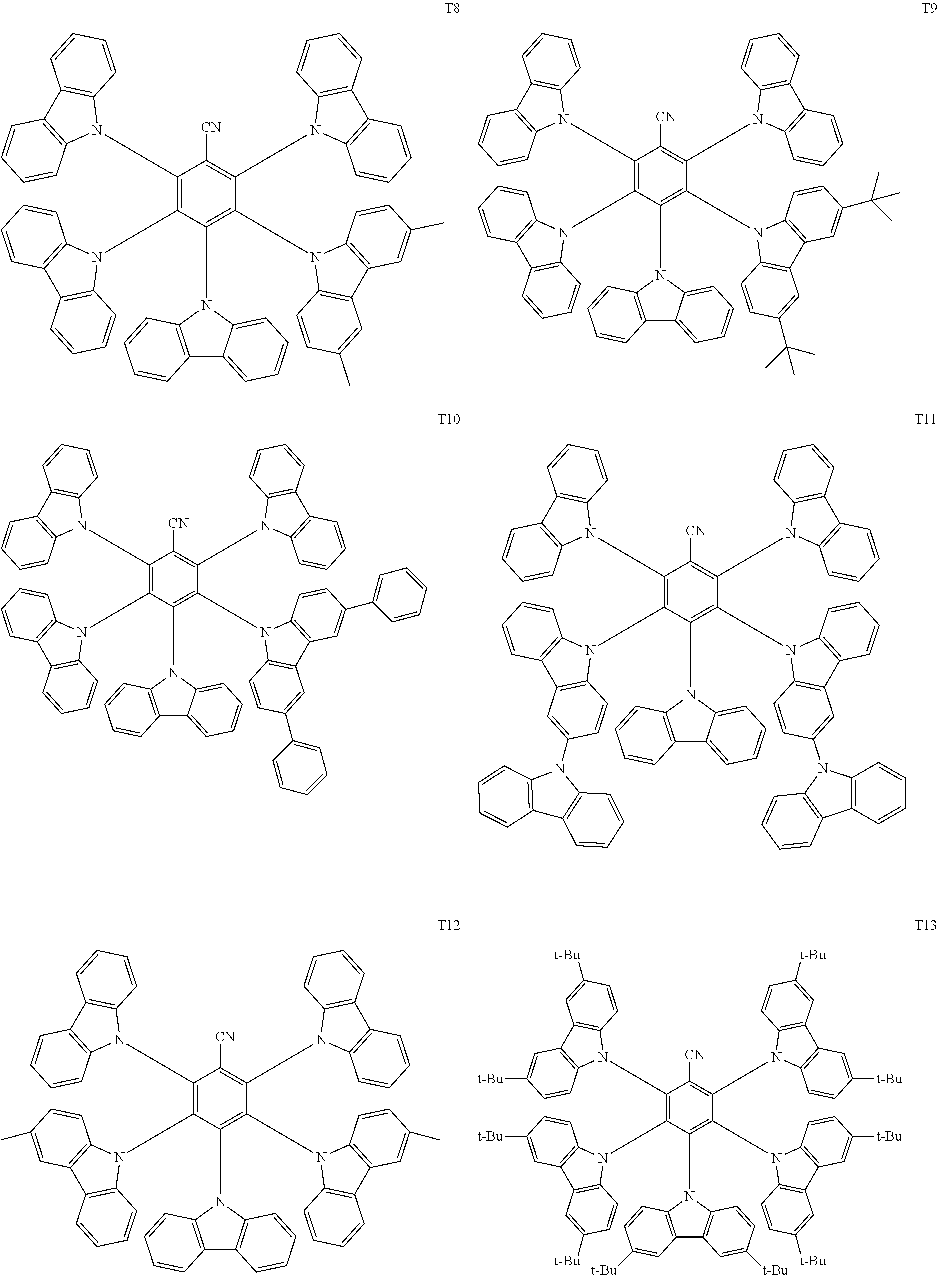

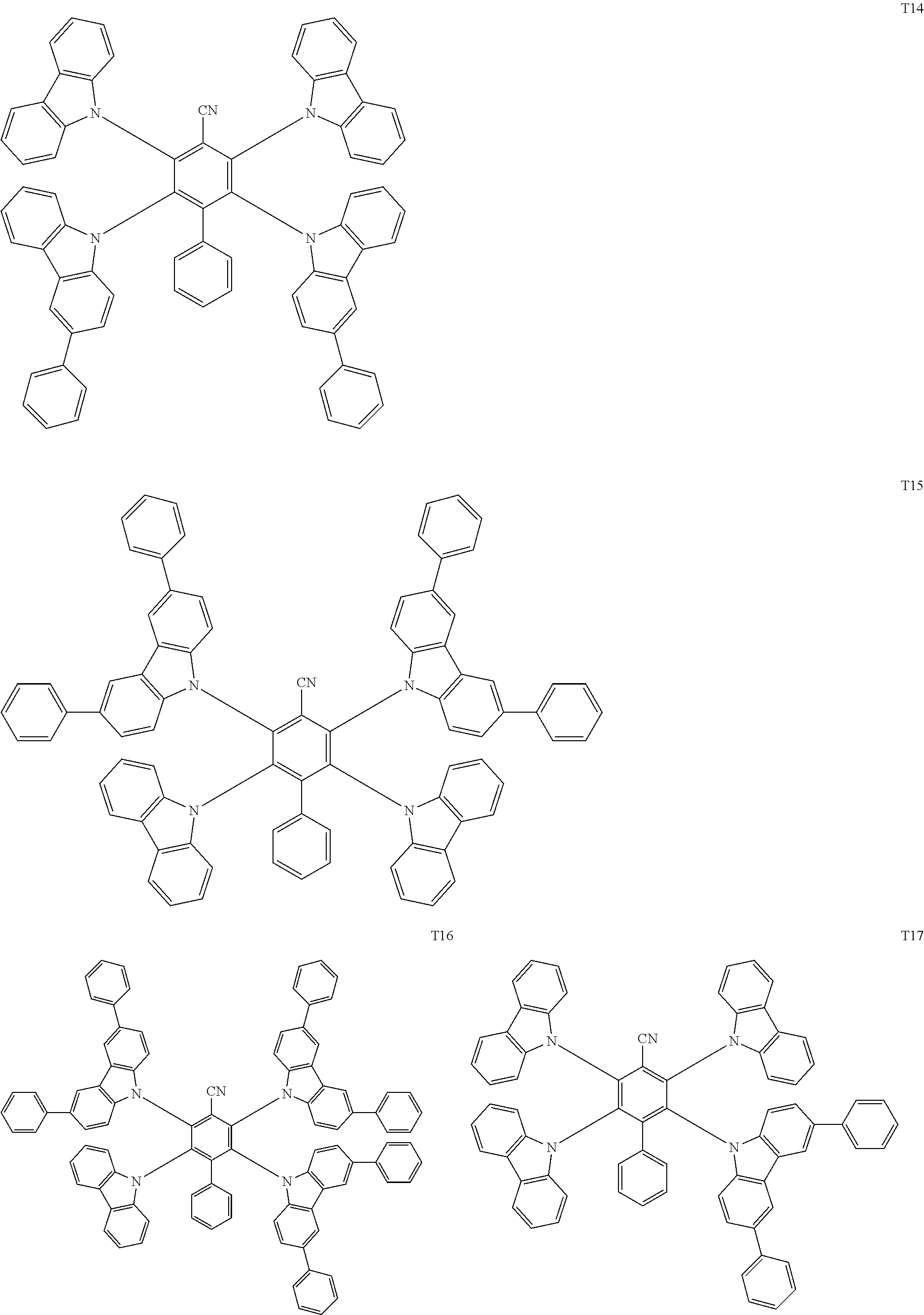

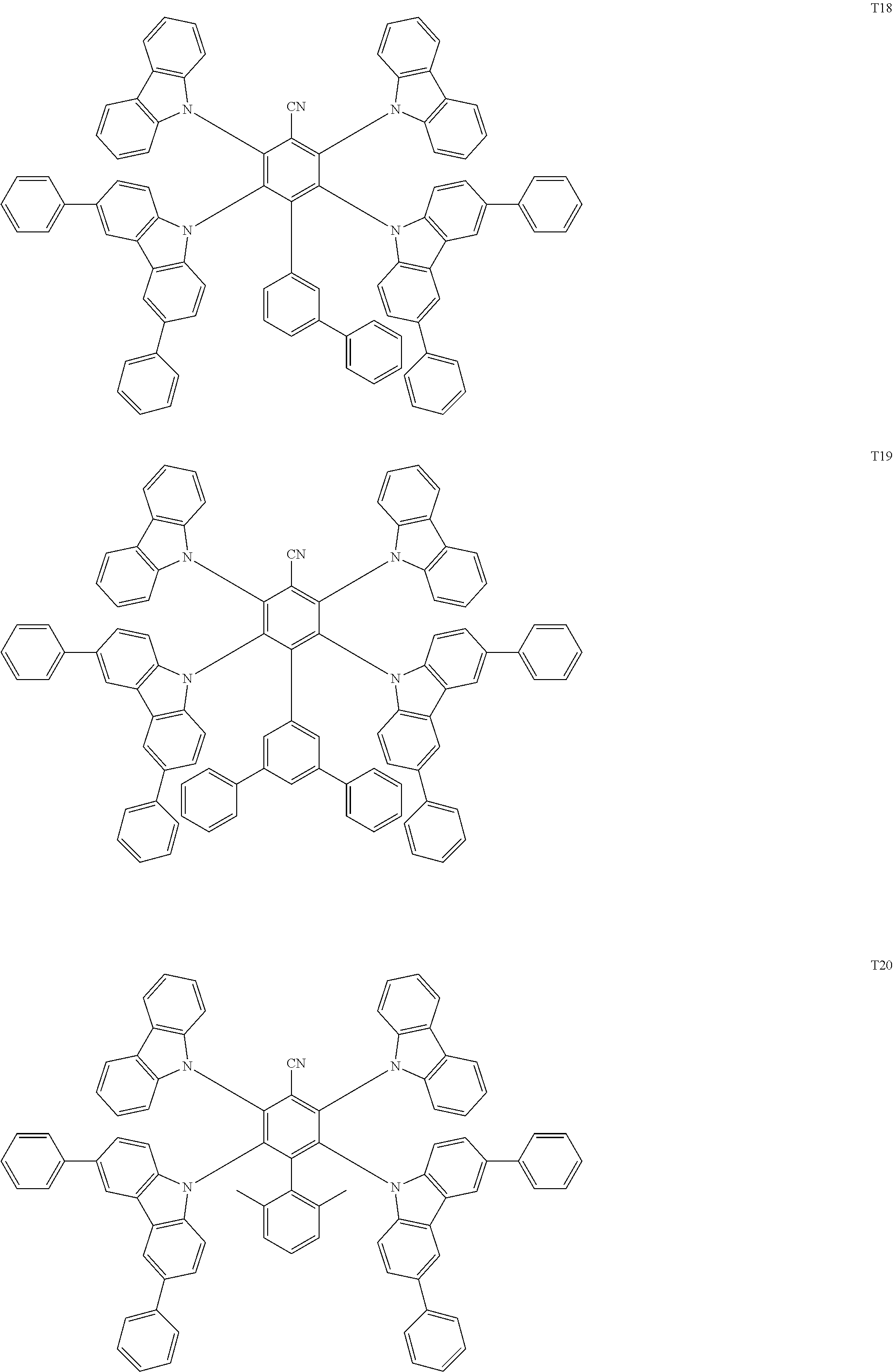 [SMILES: N#Cc1c(-n2c3ccccc3c3ccccc32)c(-n2c3ccc(-c4ccccc4)cc3c3cc(-c4ccccc4)ccc32)c(-c2cccc(-c3ccccc3)c2)c(-n2c3ccc(-c4ccccc4)cc3c3cc(-c4ccccc4)ccc32)c1-n1c2ccccc2c2ccccc21 ; N#Cc1c(-n2c3ccccc3c3ccccc32)c(-n2c3ccc(-c4ccccc4)cc3c3cc(-c4ccccc4)ccc32)c(-c2cc(-c3ccccc3)cc(-c3ccccc3)c2)c(-n2c3ccc(-c4ccccc4)cc3c3cc(-c4ccccc4)ccc32)c1-n1c2ccccc2c2ccccc21 ; Cc1cccc(C)c1-c1c(-n2c3ccc(-c4ccccc4)cc3c3cc(-c4ccccc4)ccc32)c(-n2c3ccccc3c3ccccc32)c(C#N)c(-n2c3ccccc3c3ccccc32)c1-n1c2ccc(-c3ccccc3)cc2c2cc(-c3ccccc3)ccc21]

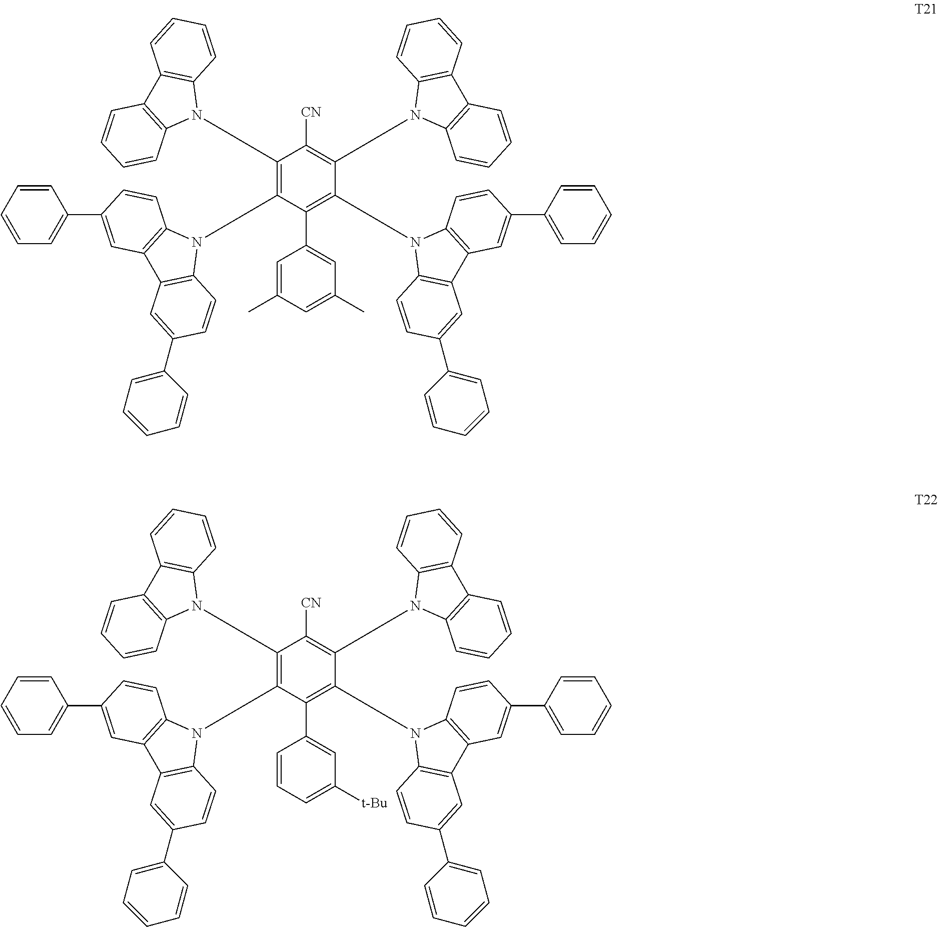 [SMILES: Cc1cc(C)cc(-c2c(-n3c4ccc(-c5ccccc5)cc4c4cc(-c5ccccc5)ccc43)c(-n3c4ccccc4c4ccccc43)c(C#N)c(-n3c4ccccc4c4ccccc43)c2-n2c3ccc(-c4ccccc4)cc3c3cc(-c4ccccc4)ccc32)c1 ; CC(C)(C)c1cccc(-c2c(-n3c4ccc(-c5ccccc5)cc4c4cc(-c5ccccc5)ccc43)c(-n3c4ccccc4c4ccccc43)c(C#N)c(-n3c4ccccc4c4ccccc43)c2-n2c3ccc(-c4ccccc4)cc3c3cc(-c4ccccc4)ccc32)c1]

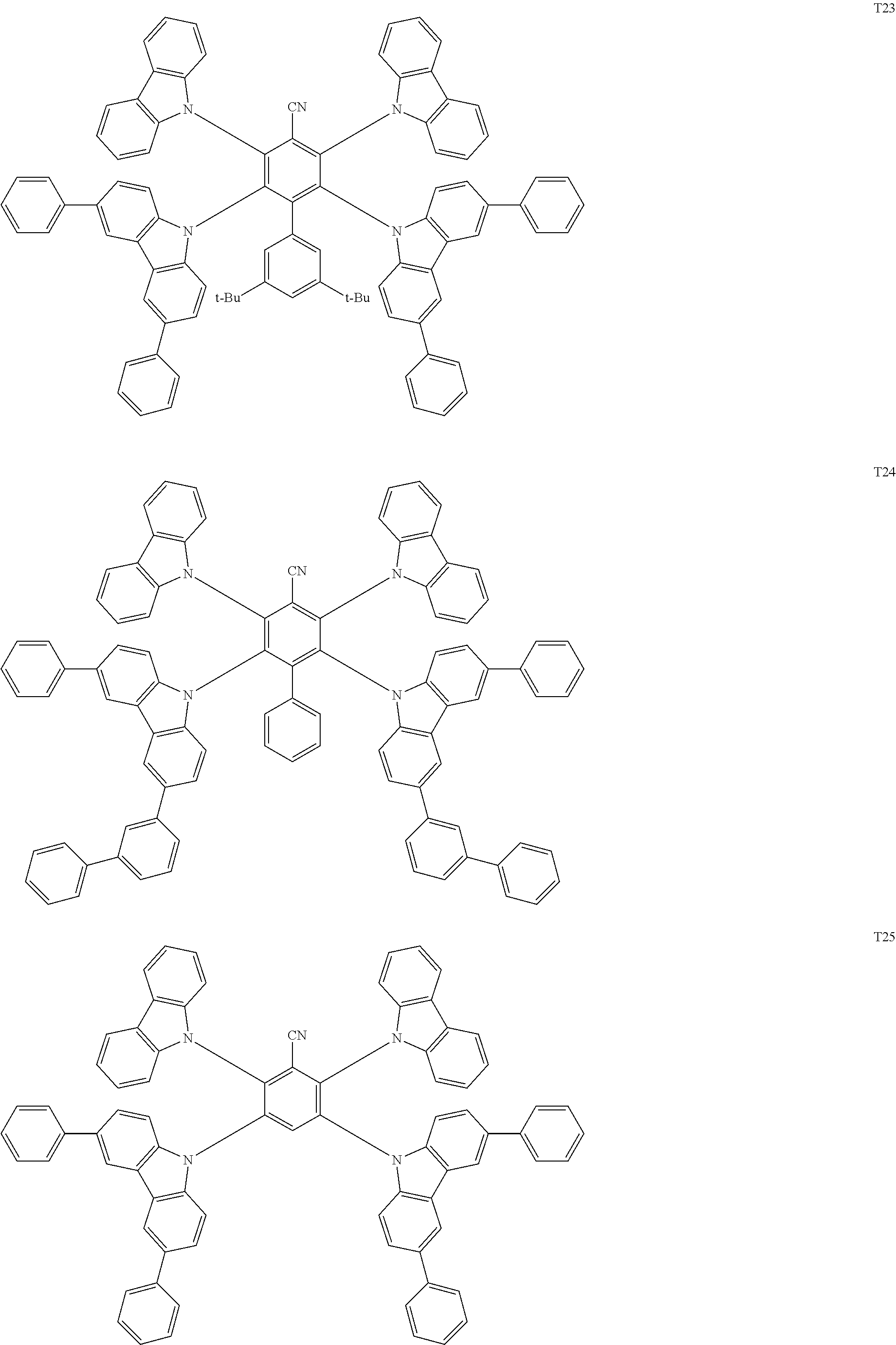 [SMILES: CC(C)(C)c1cc(-c2c(-n3c4ccc(-c5ccccc5)cc4c4cc(-c5ccccc5)ccc43)c(-n3c4ccccc4c4ccccc43)c(C#N)c(-n3c4ccccc4c4ccccc43)c2-n2c3ccc(-c4ccccc4)cc3c3cc(-c4ccccc4)ccc32)cc(C(C)(C)C)c1 ; N#Cc1c(-n2c3ccccc3c3ccccc32)c(-n2c3ccc(-c4ccccc4)cc3c3cc(-c4cccc(-c5ccccc5)c4)ccc32)c(-c2ccccc2)c(-n2c3ccc(-c4ccccc4)cc3c3cc(-c4cccc(-c5ccccc5)c4)ccc32)c1-n1c2ccccc2c2ccccc21 ; N#Cc1c(-n2c3ccccc3c3ccccc32)c(-n2c3ccc(-c4ccccc4)cc3c3cc(-c4ccccc4)ccc32)cc(-n2c3ccc(-c4ccccc4)cc3c3cc(-c4ccccc4)ccc32)c1-n1c2ccccc2c2ccccc21]

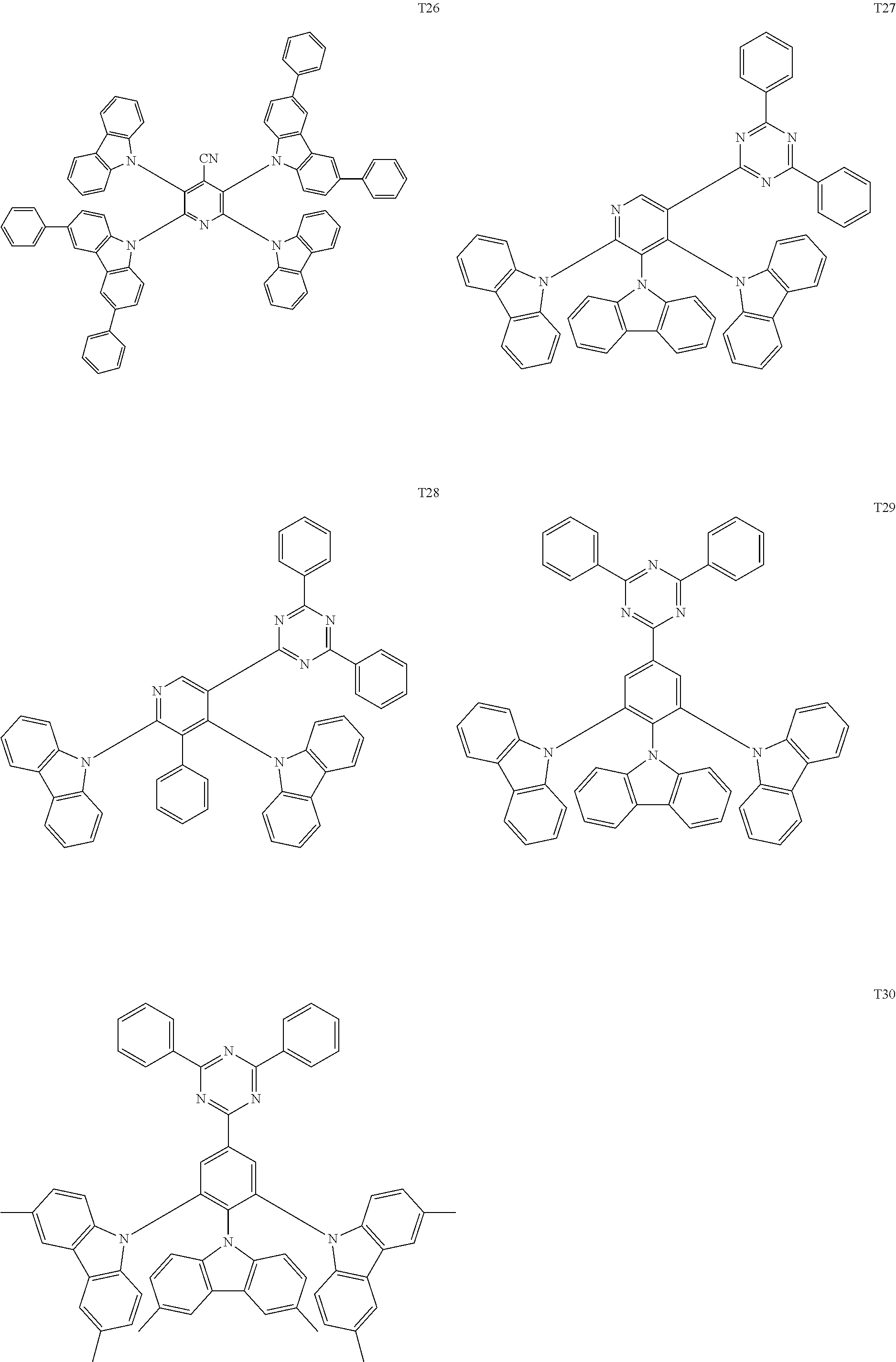

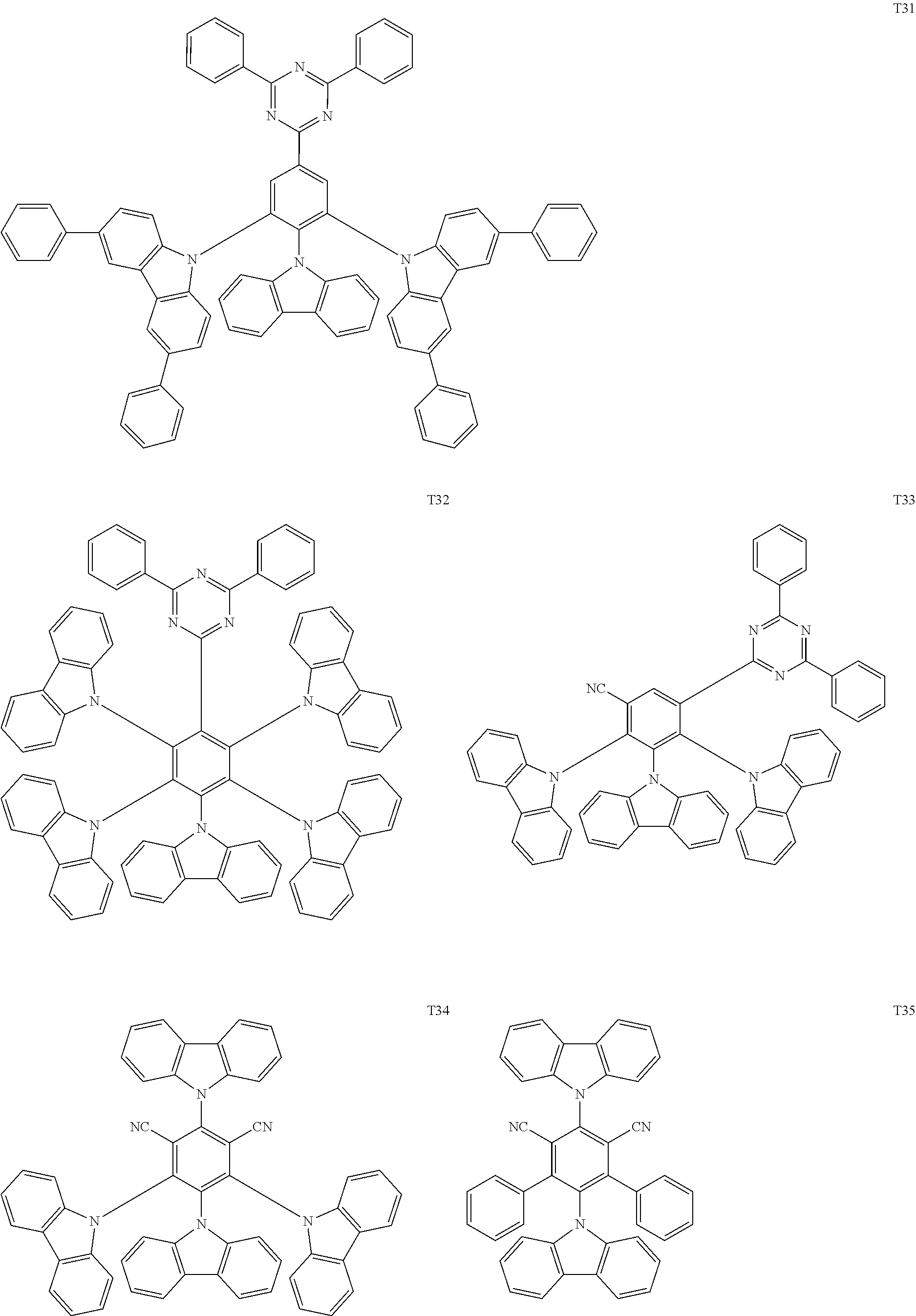

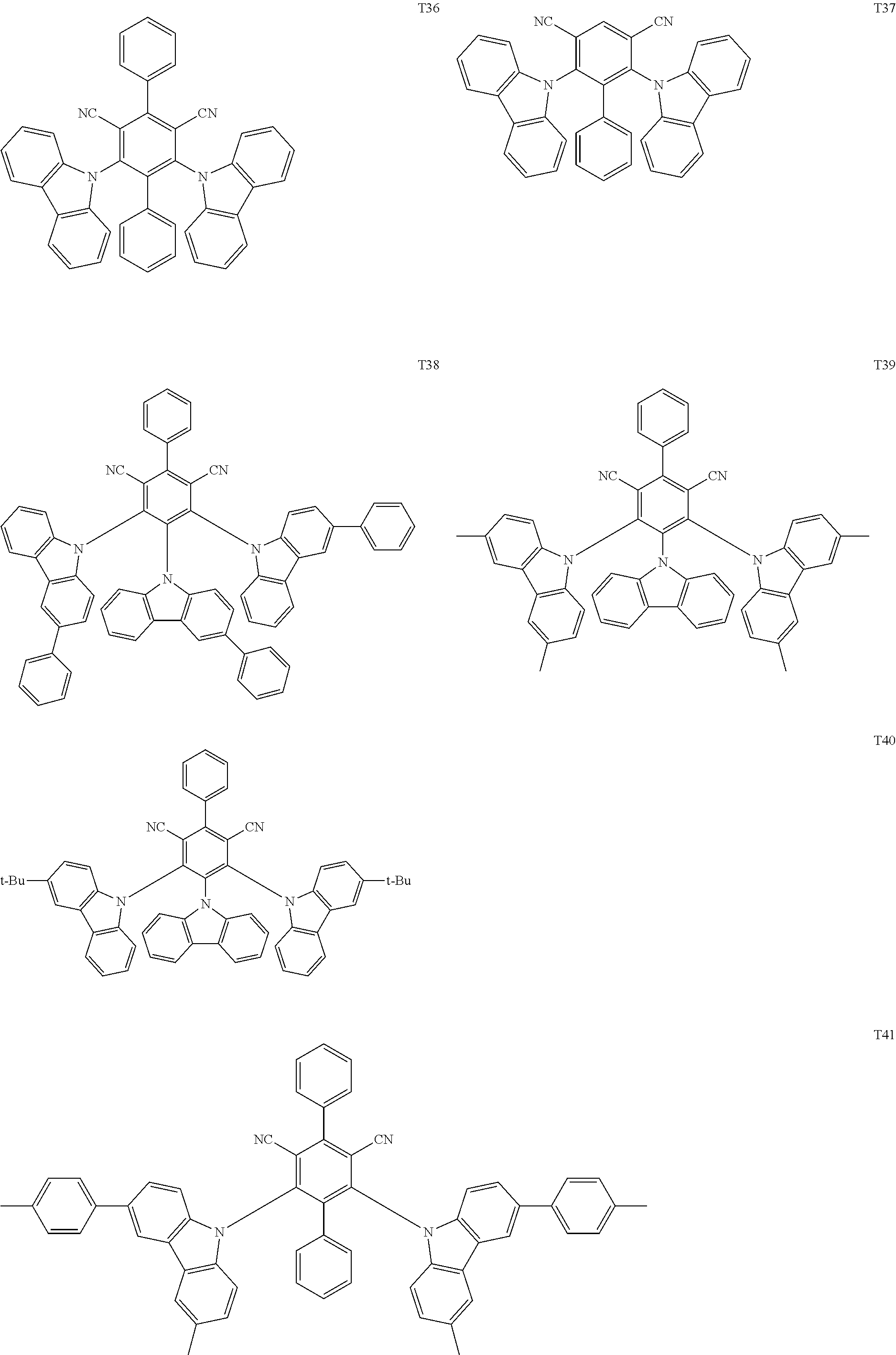

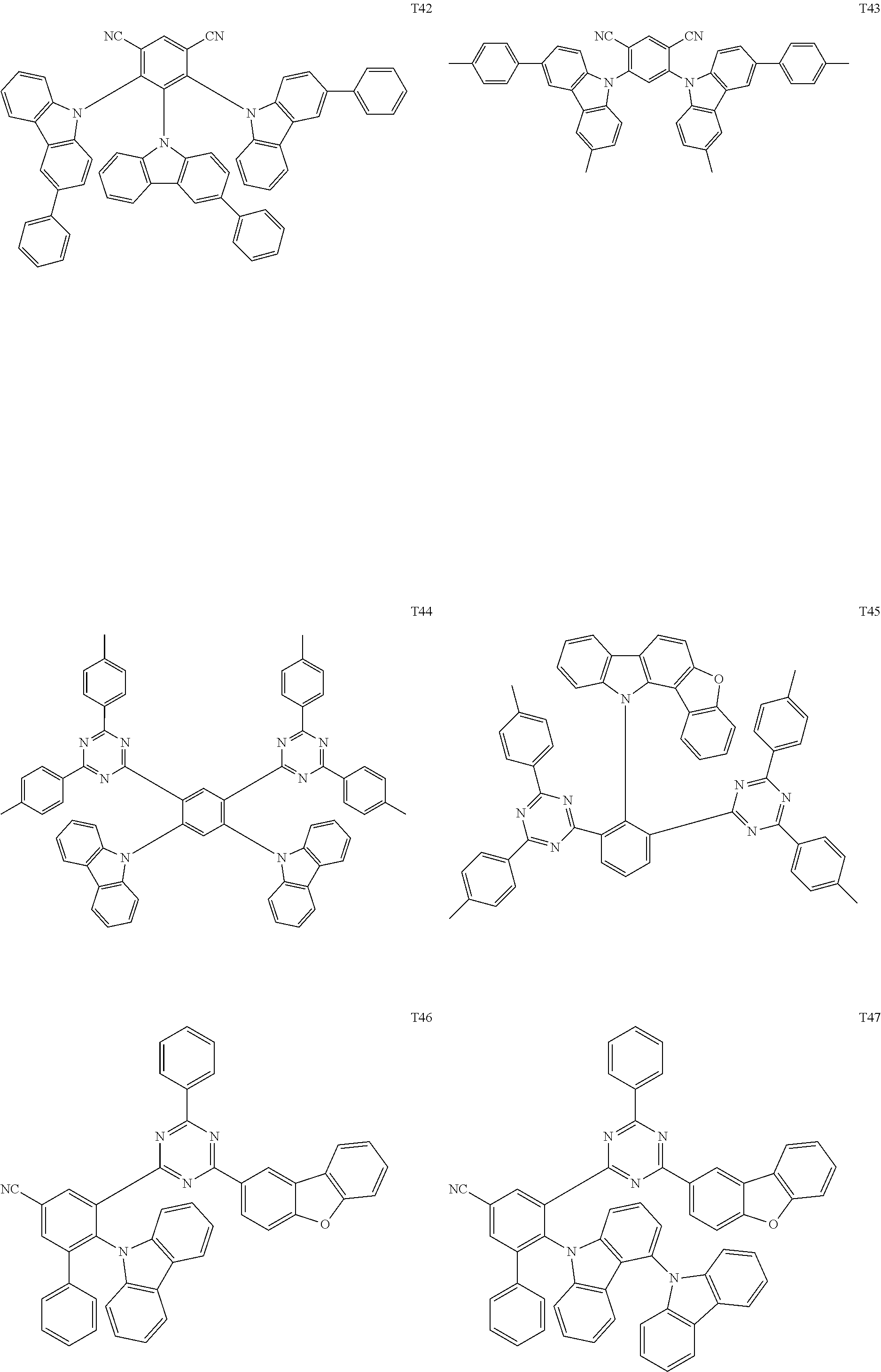

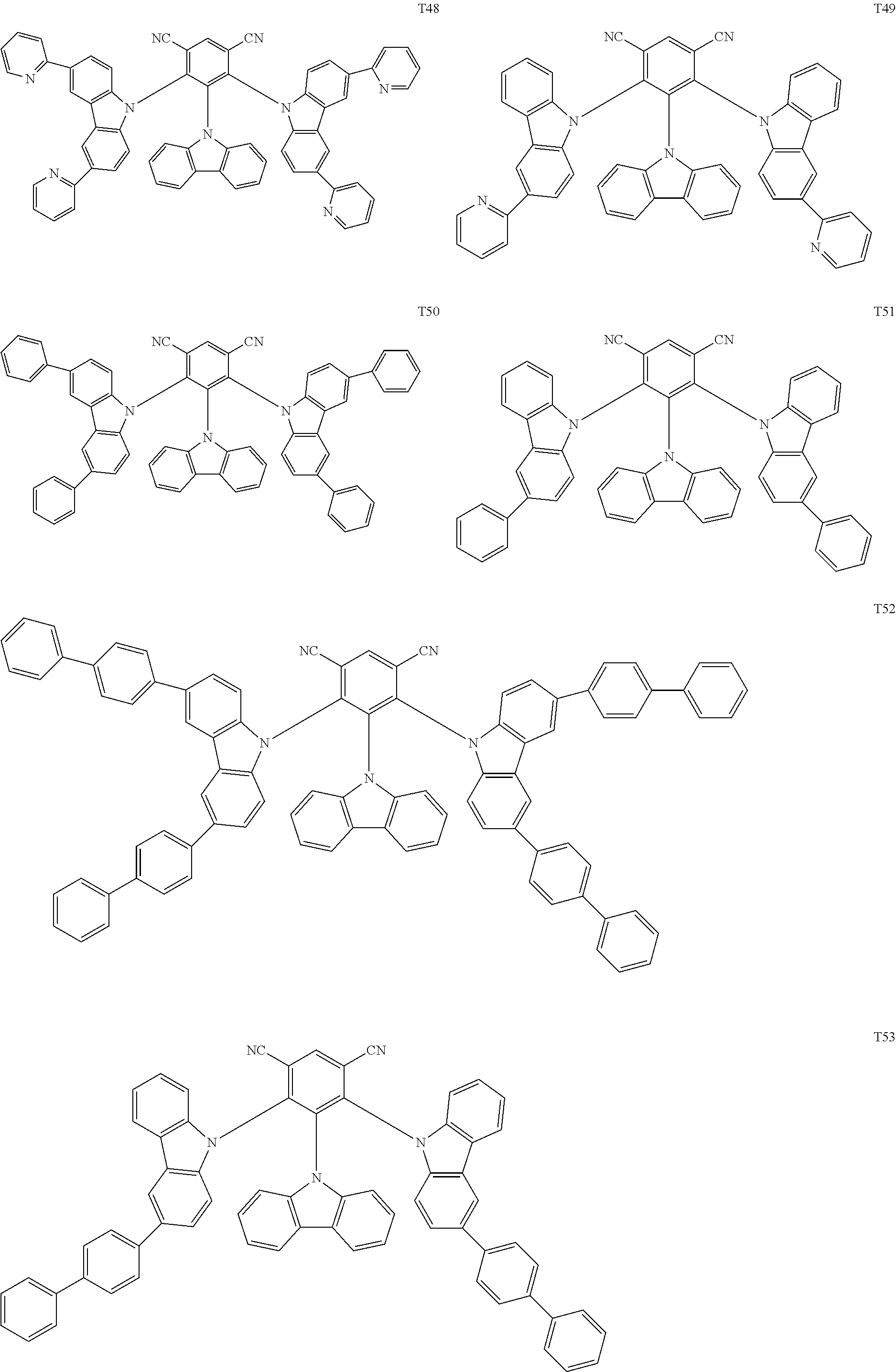

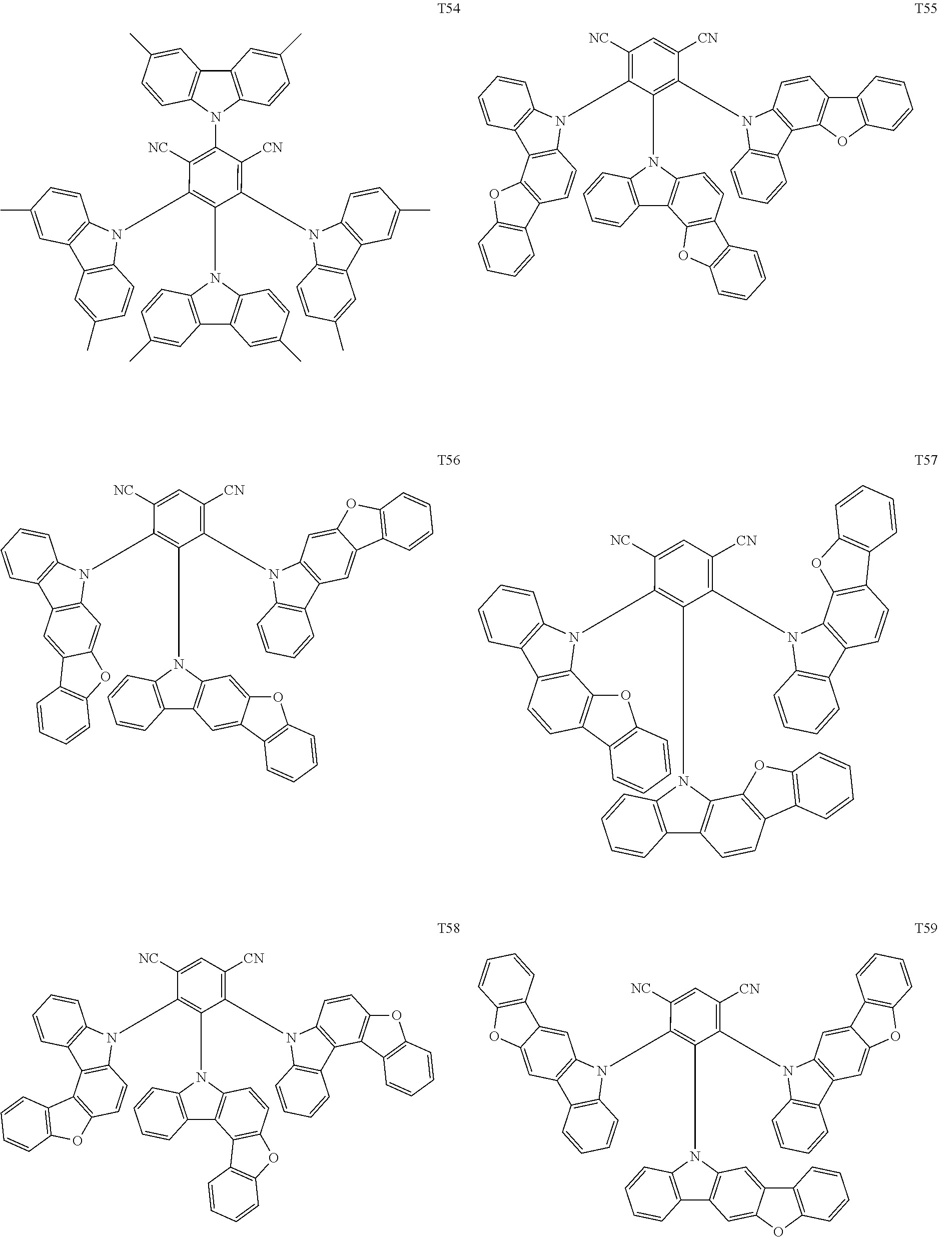

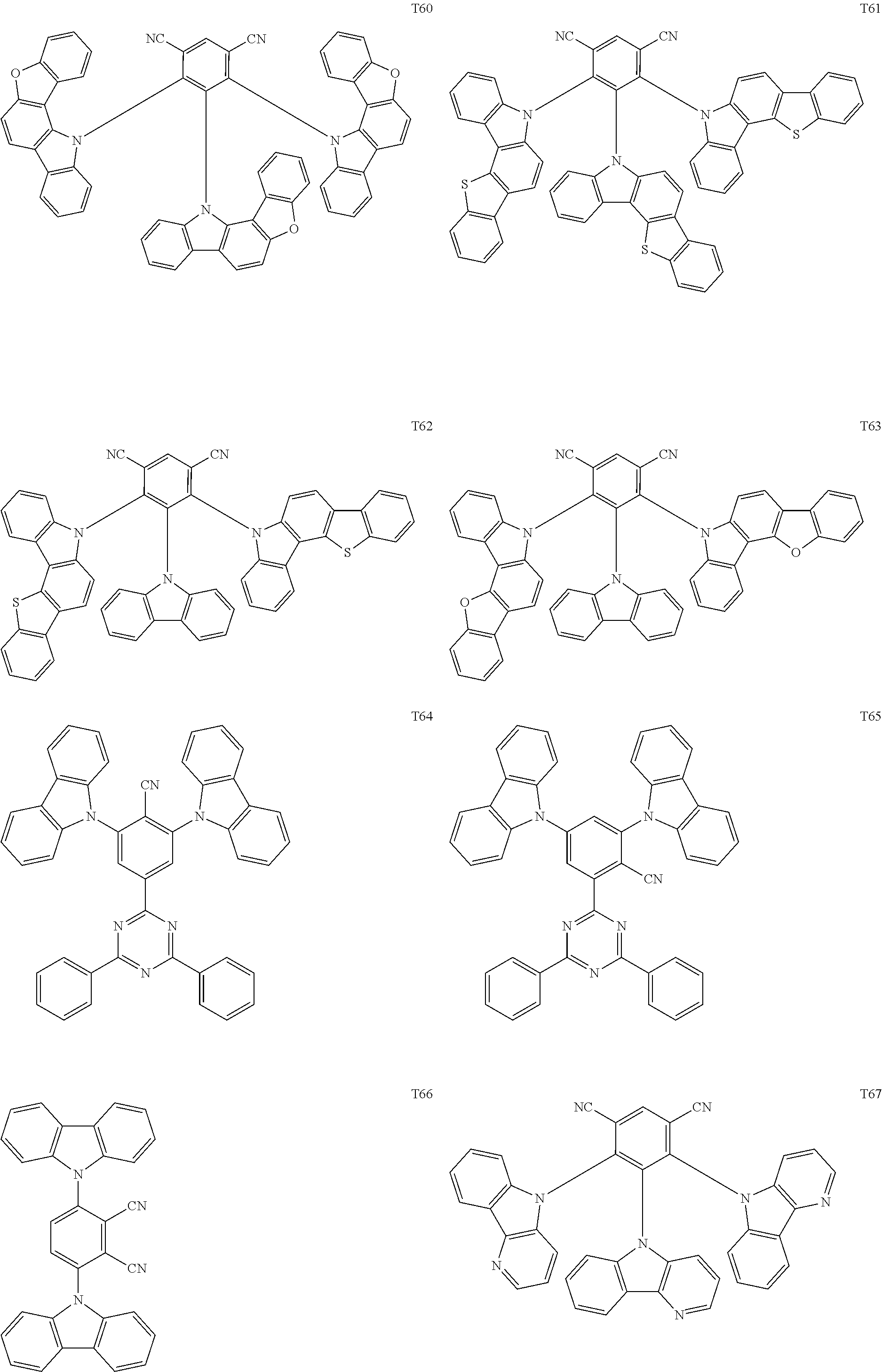

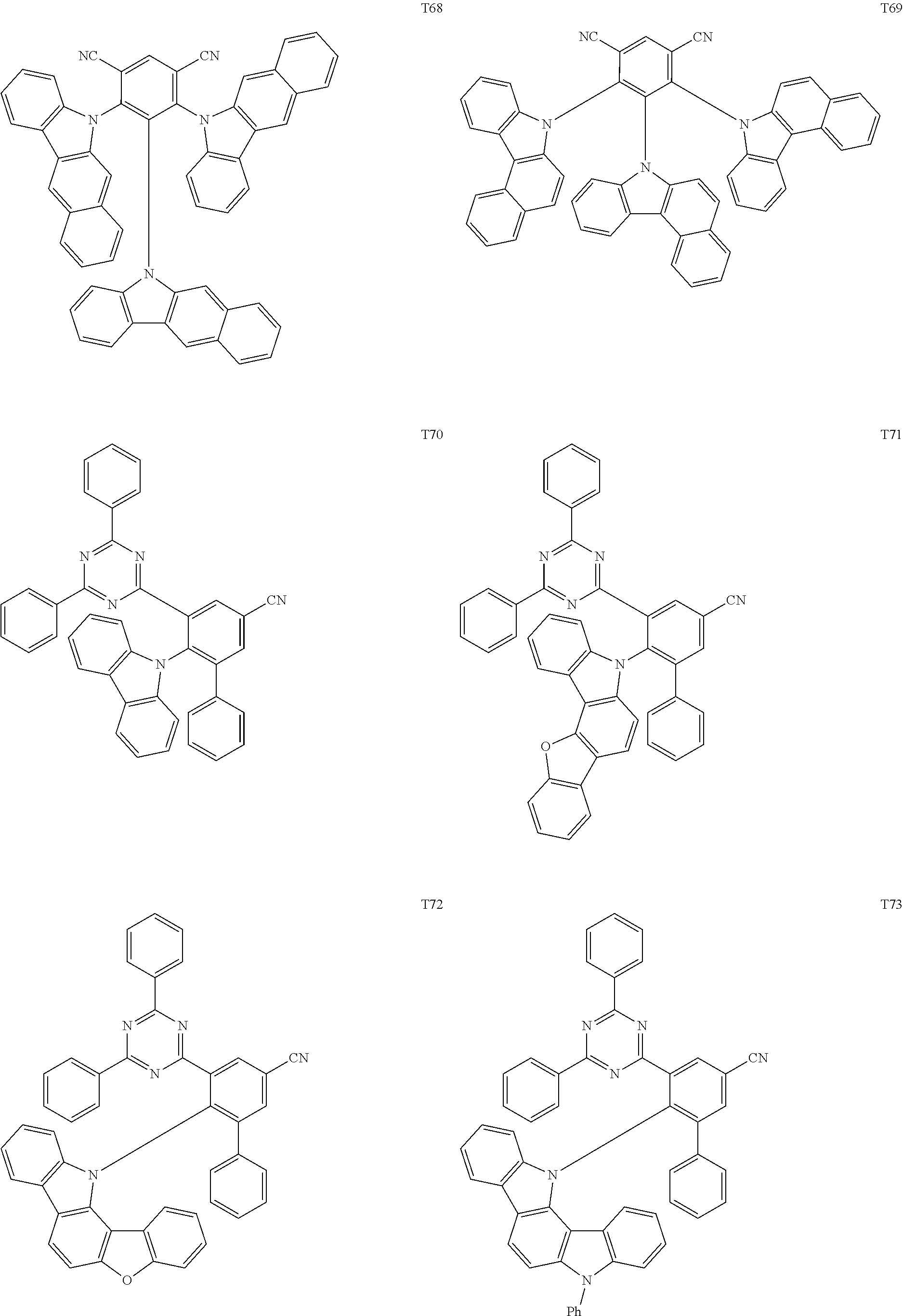

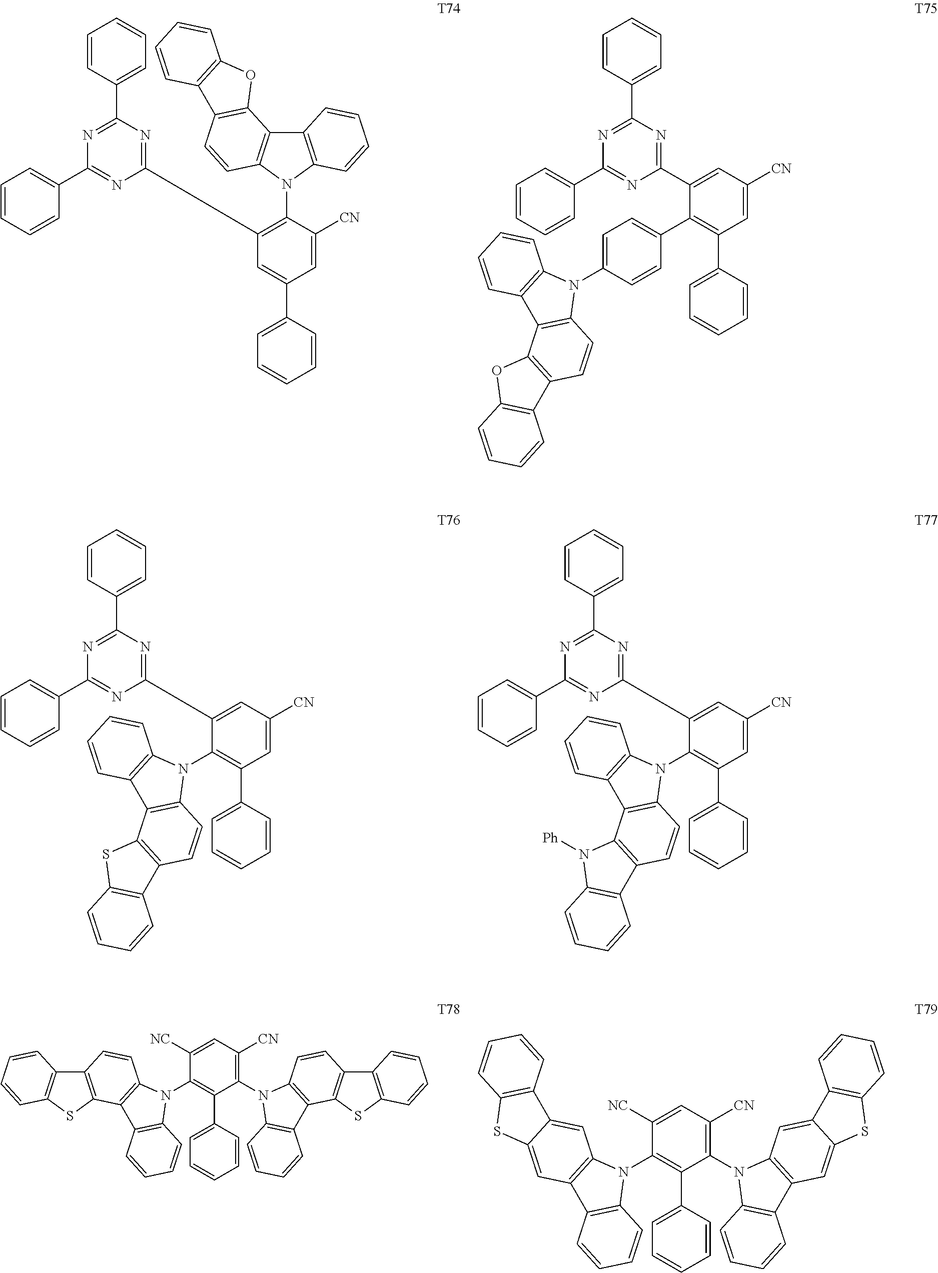

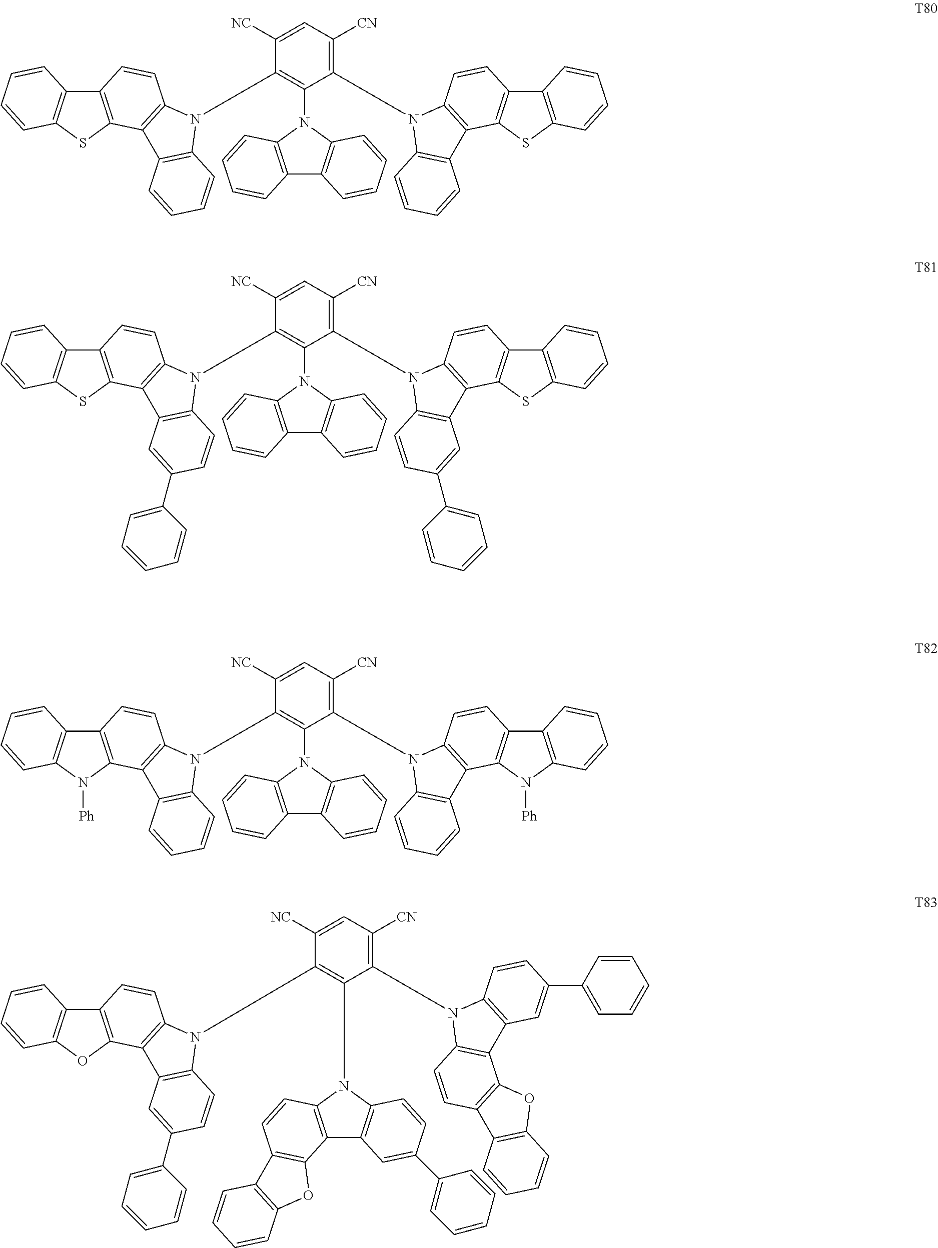

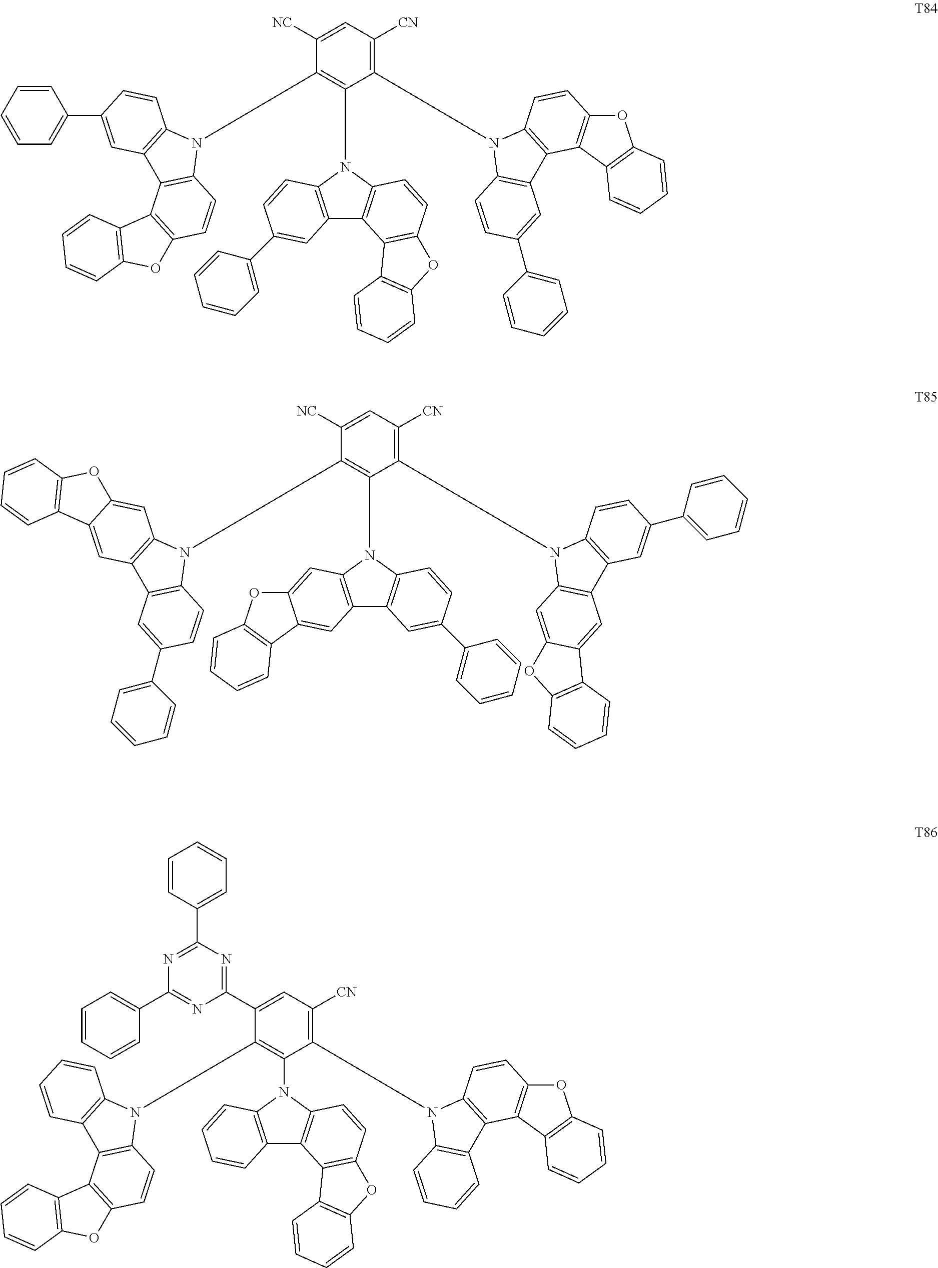 [SMILES: N#Cc1cc(C#N)c(-n2c3ccc(-c4ccccc4)cc3c3c4c(ccc32)oc2ccccc24)c(-n2c3ccc(-c4ccccc4)cc3c3c4c(ccc32)oc2ccccc24)c1-n1c2ccc(-c3ccccc3)cc2c2c3c(ccc21)oc1ccccc13 ; N#Cc1cc(C#N)c(-n2c3ccc(-c4ccccc4)cc3c3cc4c(cc32)oc2ccccc24)c(-n2c3ccc(-c4ccccc4)cc3c3cc4c(cc32)oc2ccccc24)c1-n1c2ccc(-c3ccccc3)cc2c2cc3c(cc21)oc1ccccc13 ; N#Cc1cc(-c2nc(-c3ccccc3)nc(-c3ccccc3)n2)c(-n2c3ccccc3c3c4c(ccc32)oc2ccccc24)c(-n2c3ccccc3c3c4c(ccc32)oc2ccccc24)c1-n1c2ccccc2c2c3c(ccc21)oc1ccccc13]

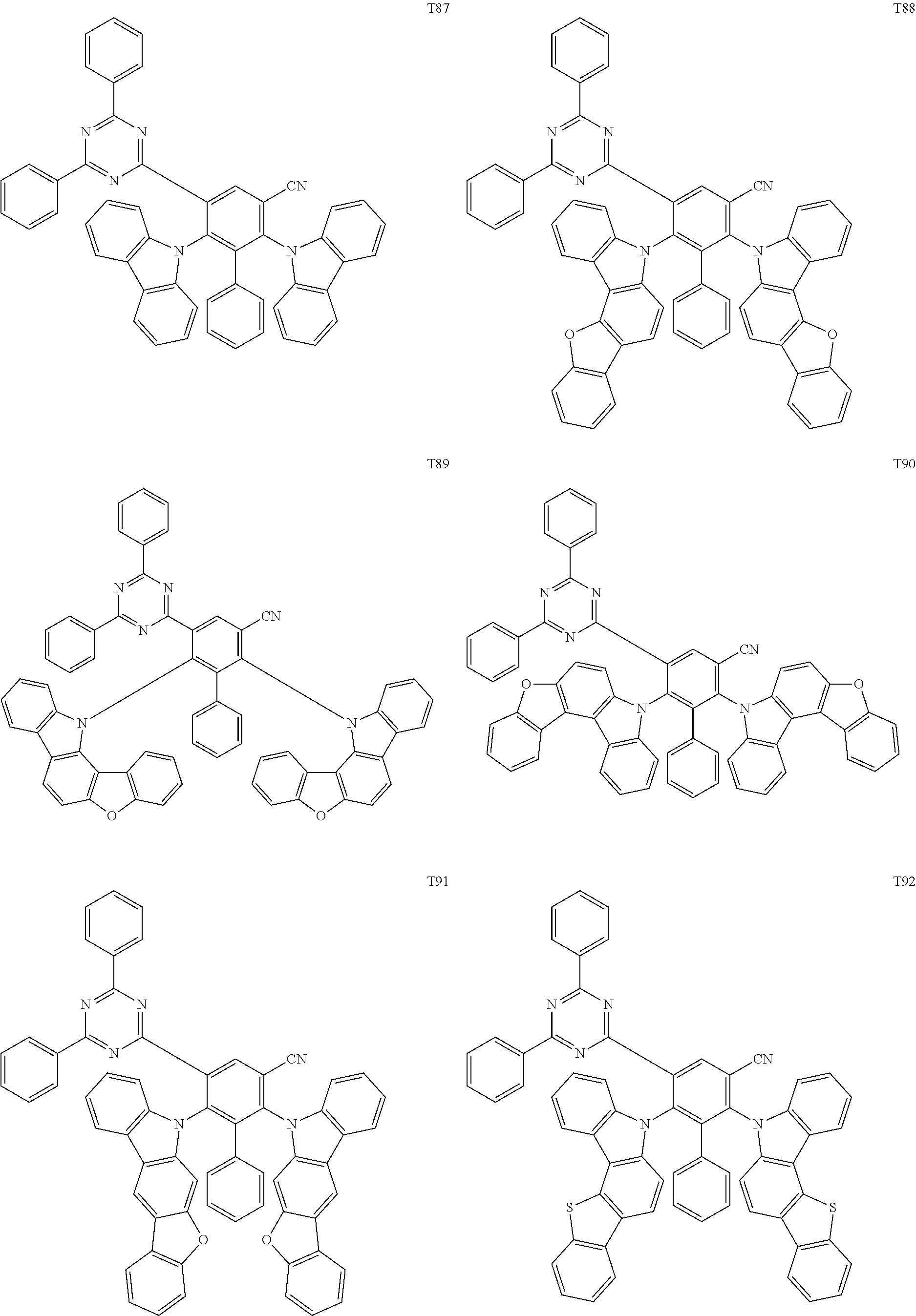

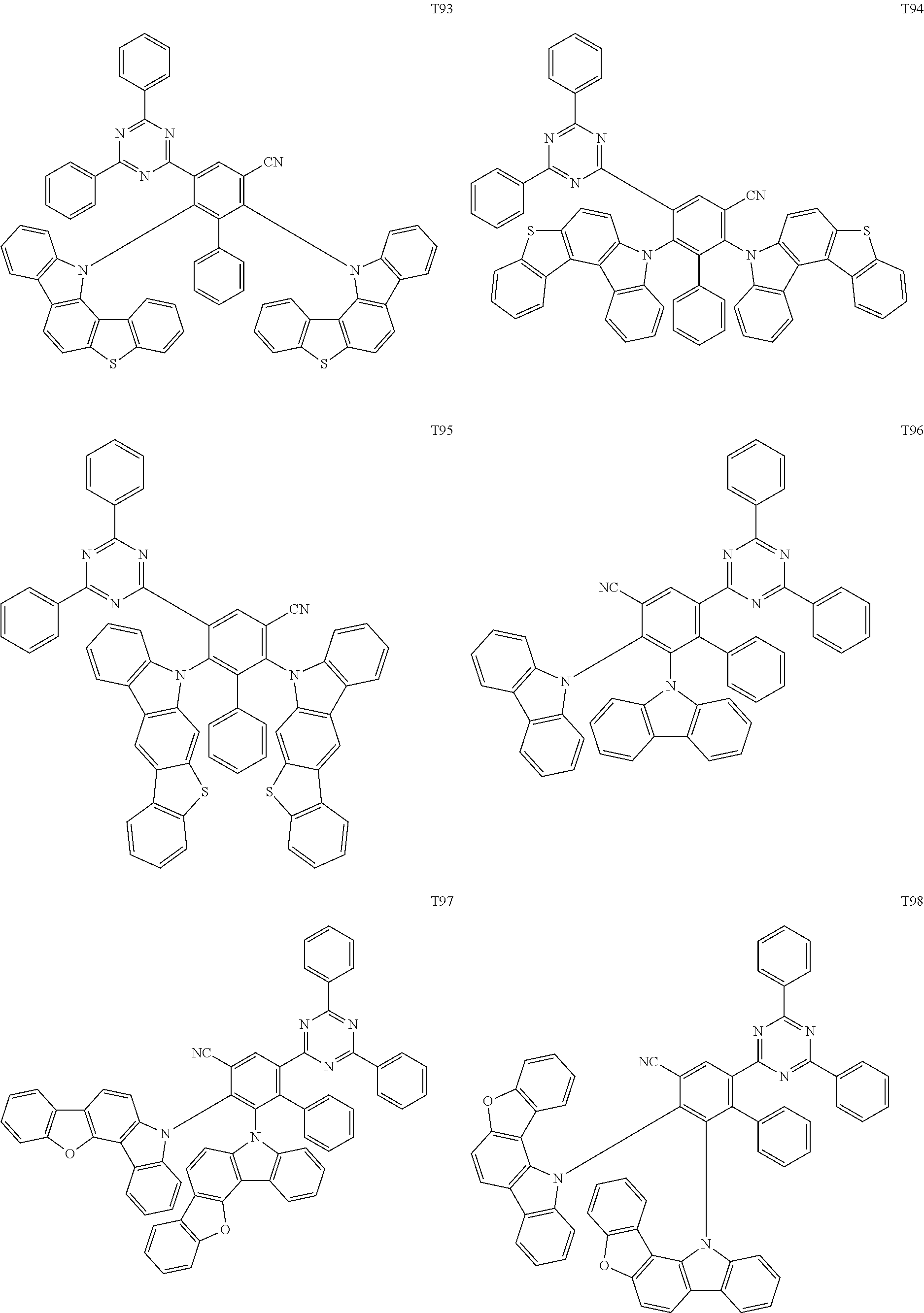

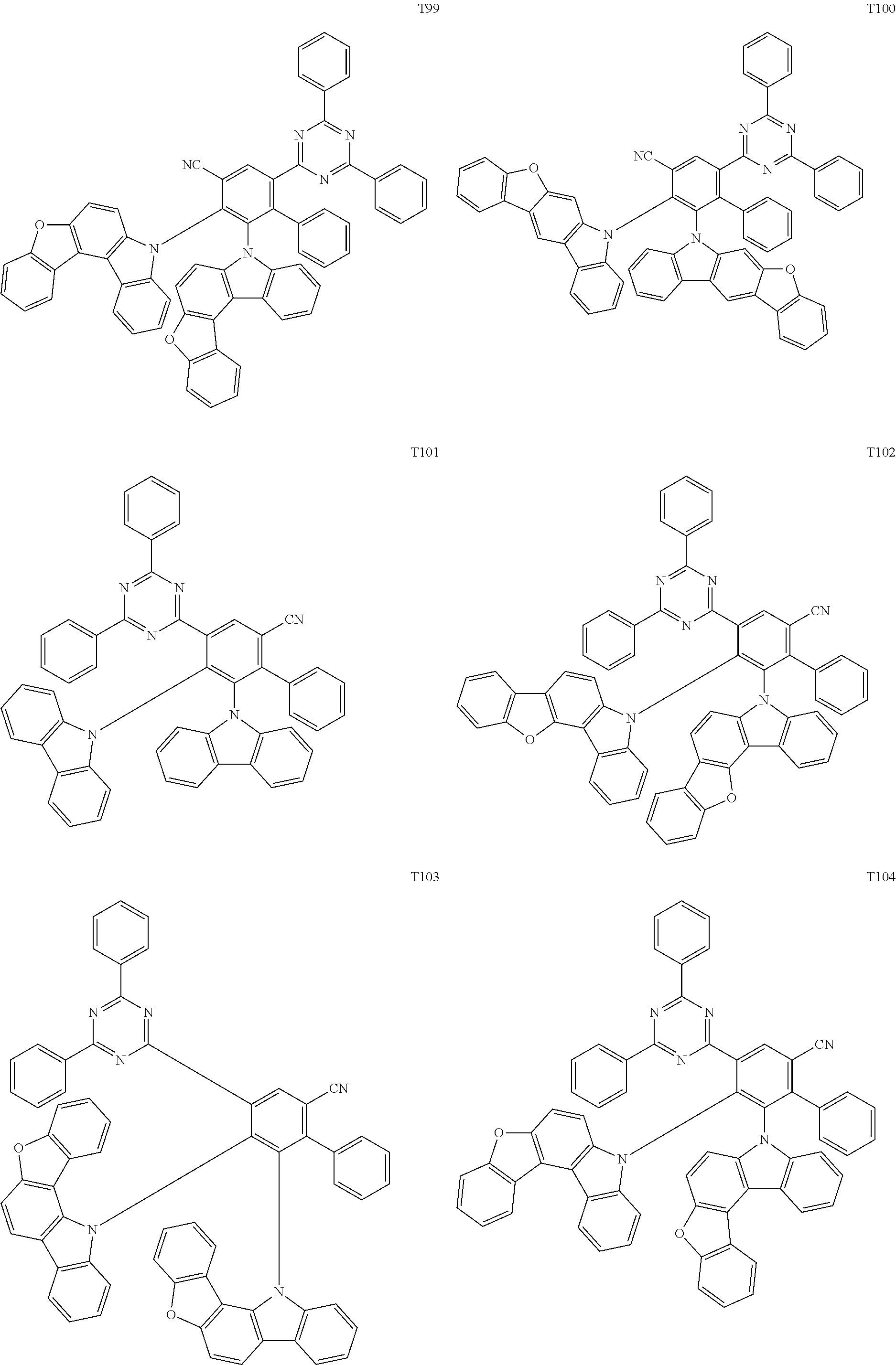

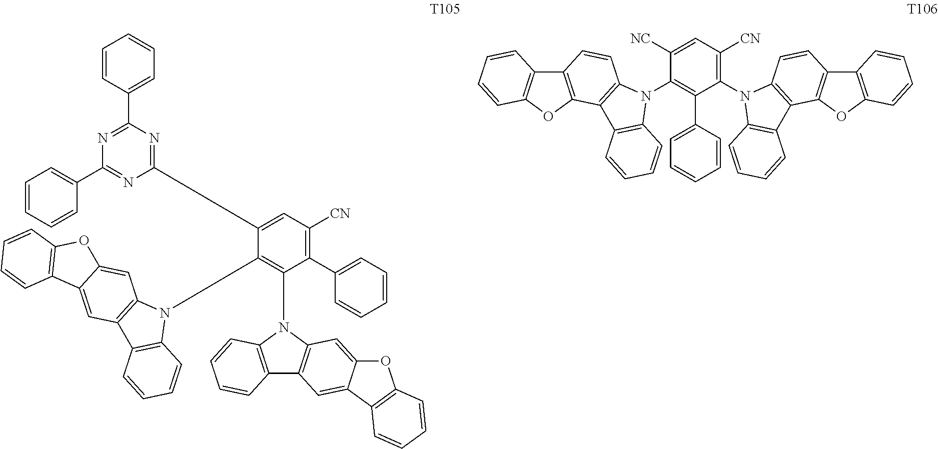 [SMILES: N#Cc1cc(-c2nc(-c3ccccc3)nc(-c3ccccc3)n2)c(-n2c3ccccc3c3cc4c(cc32)oc2ccccc24)c(-n2c3ccccc3c3cc4c(cc32)oc2ccccc24)c1-c1ccccc1 ; N#Cc1cc(C#N)c(-n2c3ccccc3c3c4oc5ccccc5c4ccc32)c(-c2ccccc2)c1-n1c2ccccc2c2c3oc4ccccc4c3ccc21]

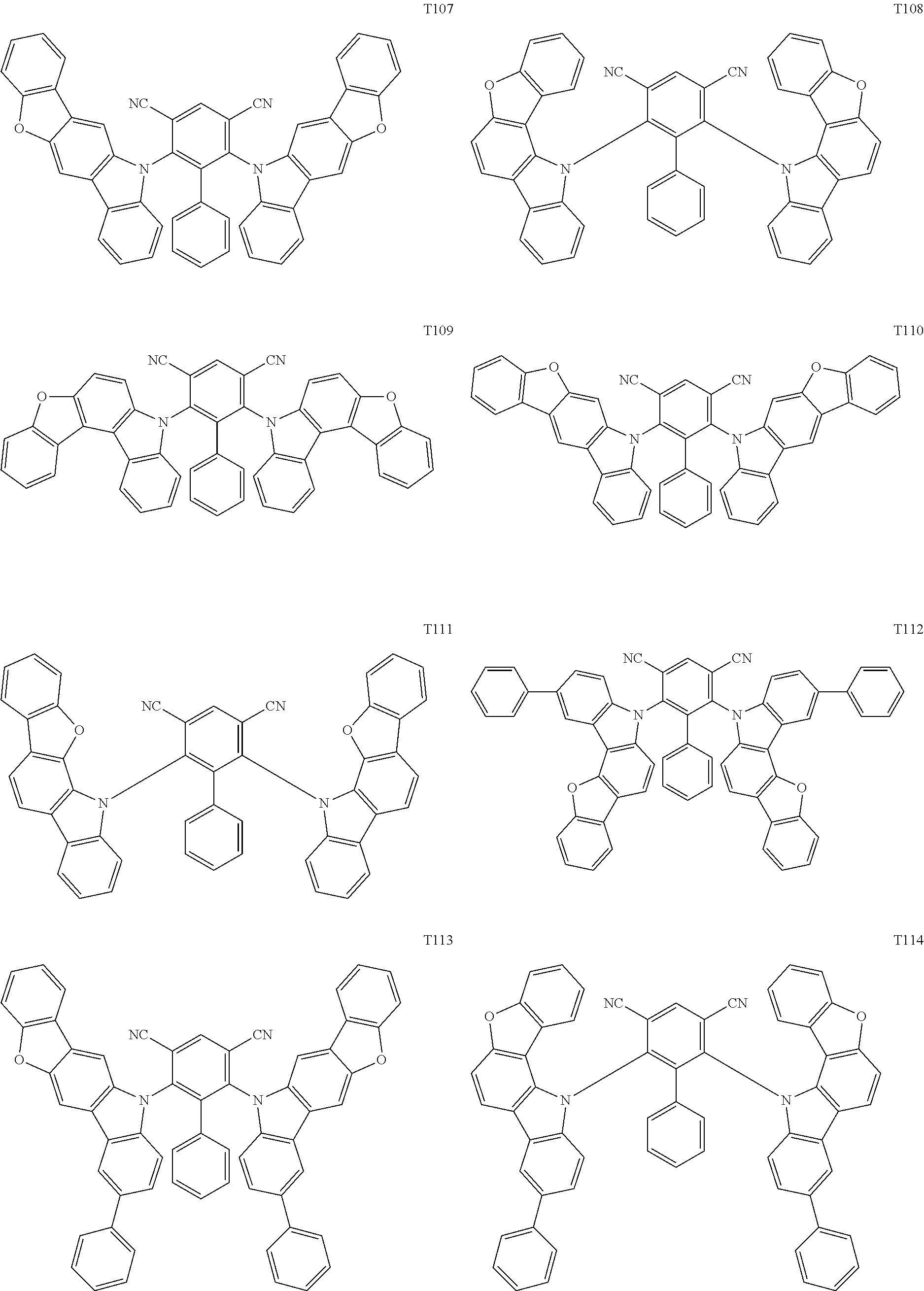

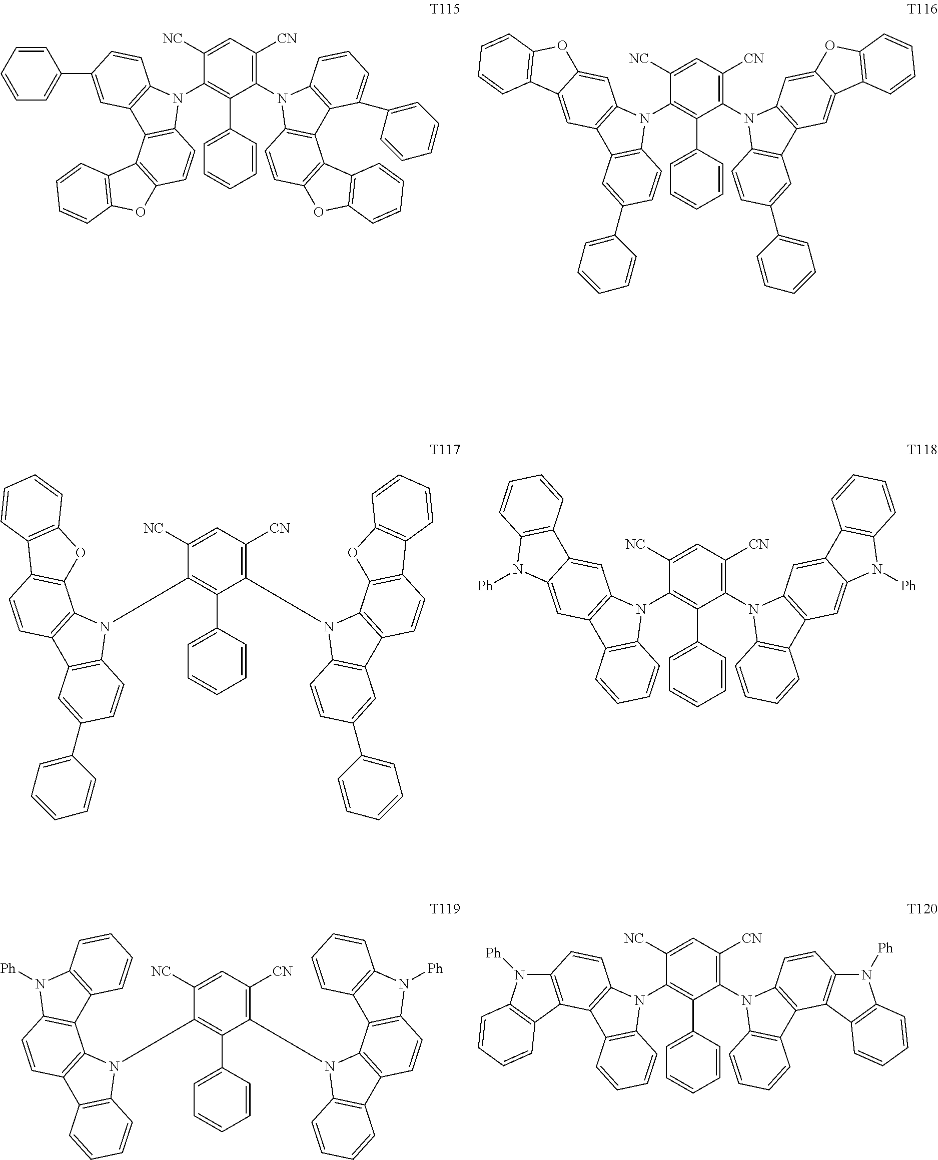

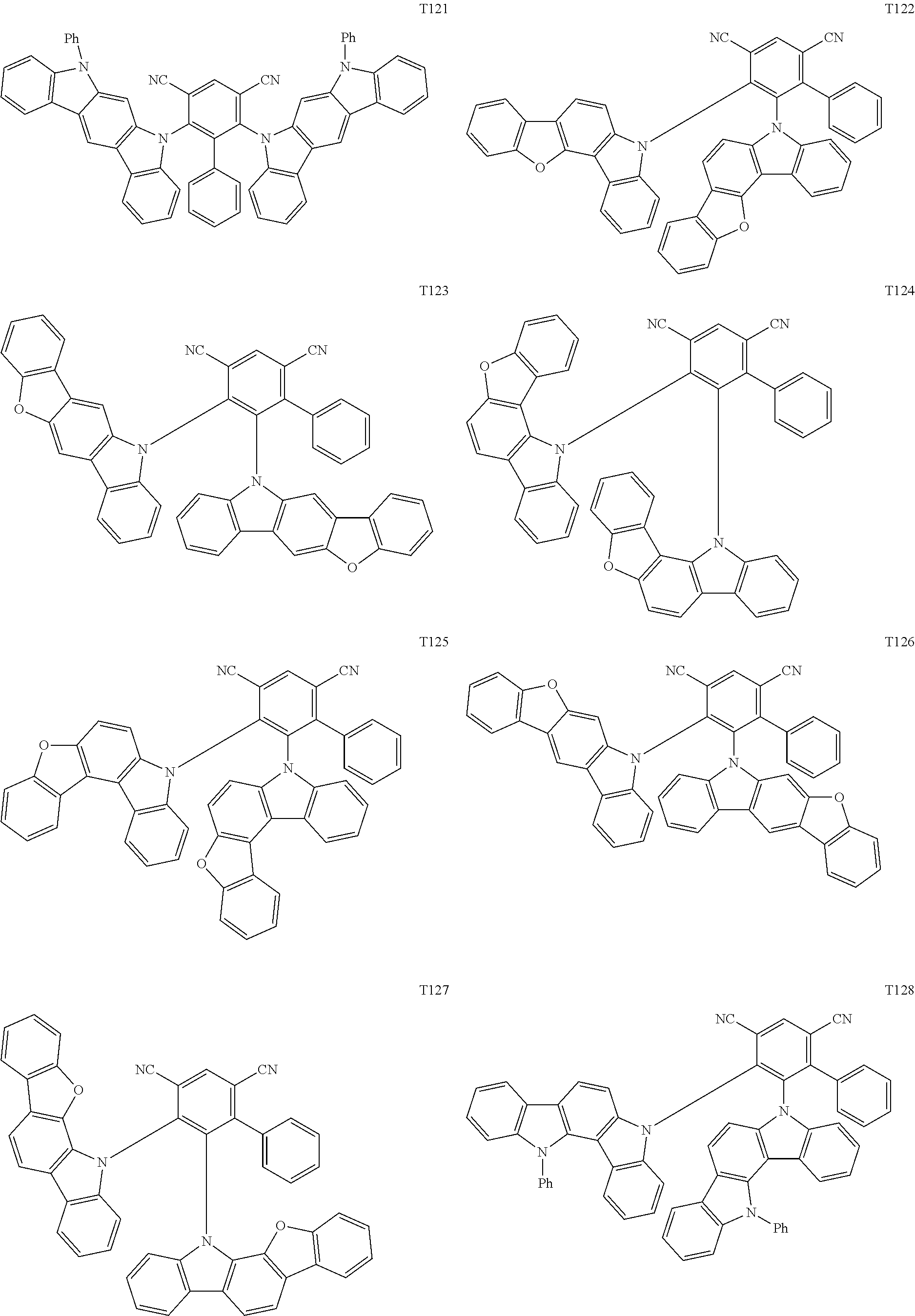

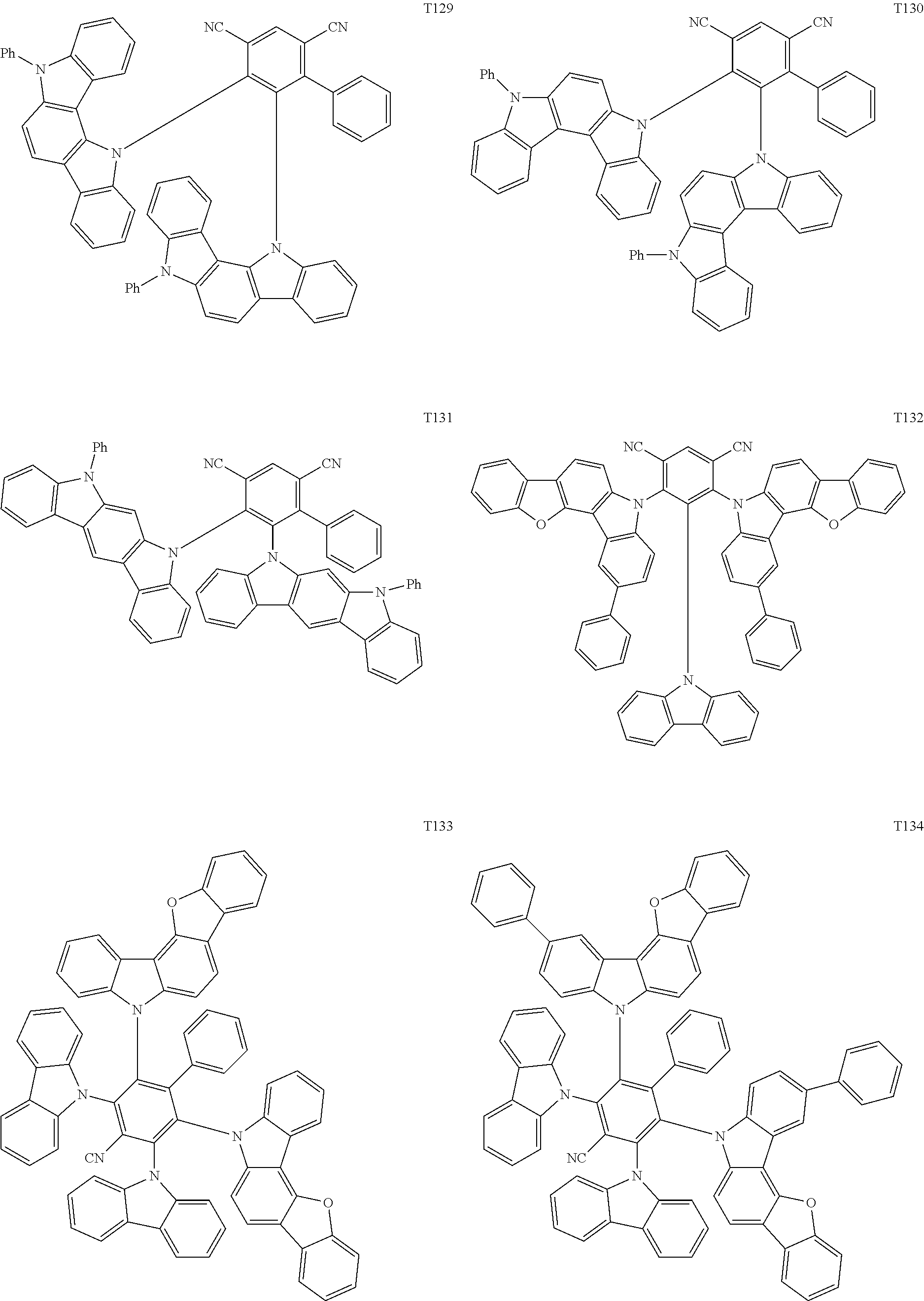

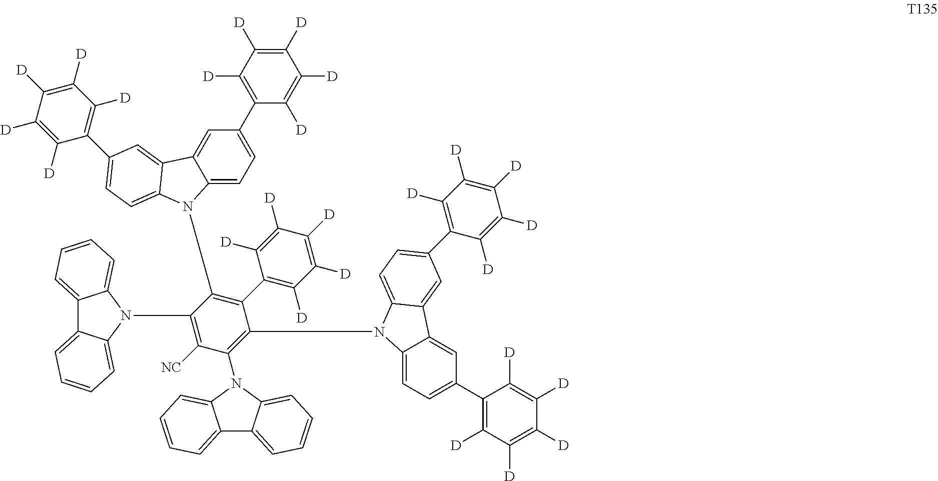 [SMILES: [2H]c1c([2H])c([2H])c(-c2ccc3c(c2)c2cc(-c4c([2H])c([2H])c([2H])c([2H])c4[2H])ccc2n3-c2c(-c3c([2H])c([2H])c([2H])c([2H])c3[2H])c(-n3c4ccc(-c5c([2H])c([2H])c([2H])c([2H])c5[2H])cc4c4cc(-c5c([2H])c([2H])c([2H])c([2H])c5[2H])ccc43)c(-n3c4ccccc4c4ccccc43)c(C#N)c2-n2c3ccccc3c3ccccc32)c([2H])c1[2H]]

The known delayed fluorescent materials other than above can be appropriately combined and used as the second organic compound. An unknown delayed fluorescent material can also be used.

As preferred delayed fluorescent materials, there can be mentioned compounds included in the general formulae described in WO2013/154064, paragraphs 0008 to 0048 and 0095 to 0133; WO2013/011954, paragraphs 0007 to 0047 and 0073˜0085; WO2013/011955, paragraphs 0007 to 0033 and 0059 to 0066; WO2013/081088, paragraphs 0008 to 0071 and 0118 to 0133; JP 2013-256490 A, paragraphs 0009 to 0046 and 0093 to 0134; JP 2013-116975 A, paragraphs 0008 to 0020 and 0038 to 0040; WO2013/133359, paragraphs 0007 to 0032 and 0079 to 0084; WO2013/161437, paragraphs 0008 to 0054 and 0101˜0121; JP 2014−9352 A, paragraphs 0007 to 0041 and 0060 to 0069; and JP 2014−9224 A, paragraphs 0008 to 0048 and 0067 to 0076; JP 2017-119663 A, paragraphs 0013 to 0025: JP 2017-119664 A, paragraphs 0013 to 0026; JP 2017-222623 A, paragraphs 0012 to 0025; JP 2017-226838 A, paragraphs 0010 to 0050; JP 2018-100411 A, paragraphs 0012 to 0043; WO2018/047853, paragraphs 0016 to 0044; and especially, exemplary compounds therein capable of emitting delayed fluorescence. In addition, also preferably employable here are light emitting materials capable of emitting delayed fluorescence, as described in JP 2013−253121 A, WO2013/133359, WO2014/034535, WO2014/115743, WO2014/122895, WO2014/126200, WO2014/136758, WO2014/133121, WO2014/136860, WO2014/196585, WO2014/189122, WO2014/168101, WO2015/008580, WO2014/203840, WO2015/002213, WO2015/016200, WO2015/019725, WO2015/072470, WO2015/108049, WO2015/080182, WO2015/072537, WO2015/080183, JP 2015-129240 A, WO2015/129714, WO2015/129715, WO2015/133501, WO2015/136880, WO2015/137244, WO2015/137202, WO2015/137136, WO2015/146541 and WO2015/159541. These patent publications described in this paragraph are hereby incorporated as a part of this description by reference.

### Third Organic Compound

The third organic compound used in the light emitting layer of the organic electroluminescent device of the present invention is a fluorescent material that has lowest excited singlet energy that is smaller than the first organic compound and the second organic compound, and has energy of the HOMO and LUMO that is larger than the second organic compound. The organic electroluminescent device of the present invention emits fluorescent light derived from the third organic compound. The light emission from the third organic compound generally includes delayed fluorescent light. The largest component of the light emission from the organic electroluminescent device of the present invention is the light emission from the third organic compound. Therefore, the light emission amount from the third organic compound is the largest in the light emission from the organic electroluminescent device of the present invention. In the light emission from the organic electroluminescent device of the present invention, 70% or more thereof may be the light emission from the third organic compound, 90% or more thereof may be the light emission from the third organic compound, or 99% or more thereof may be the light emission from the third organic compound. The third organic compound transitions to the excited singlet state through reception of energy from the first organic compound in the excited singlet state, the second organic compound in the excited singlet state, and the second organic compound that transitions from the excited triplet state to the excited singlet state through reverse intersystem crossing. In a preferred embodiment of the present invention, the third organic compound transitions to the excited singlet state through reception of energy from the second organic compound in the excited singlet state and the second organic compound that transitions from the excited triplet state to the excited singlet state through reverse intersystem crossing. Thereafter, fluorescent light is emitted in returning the excited singlet state of the third organic compound to the ground state.

The fluorescent material used as the third organic compound is not particularly limited, as far as being capable of emitting light through reception of energy from the first organic compound and the second organic compound, and the light emission may include any of fluorescent light, delayed fluorescent light, and phosphorescent light. It is preferred that the light emission includes fluorescent light and delayed fluorescent light, and it is more preferred that the largest component of the light emission from the third organic compound is fluorescent light. In one embodiment of the present invention, the organic electroluminescent device does not emit phosphorescent light, or the radiation amount of phosphorescent light thereof is 1% or less.

Two or more kinds of the third organic compounds may be used, as far as satisfying the conditions of the present invention. For example, the combination use of two or more kinds of the third organic compounds different in light emission color from each other enables light emission with intended color. One kind of the third organic compound may also be used to achieve monochromatic light emission from the third organic compound.

In the present invention, the maximum light emission wavelength of the compound that can be used as the third organic compound is not particularly limited. Accordingly, a light emitting material having a maximum light emission wavelength in the visible region (380 to 780 nm), a light emitting material having a maximum light emission wavelength in the infrared region (780 nm to 1 mm), a light emitting material having a maximum light emission wavelength in the ultraviolet region (for example, 280 to 380 nm), and the like can be appropriately selected and used. A fluorescent material having a maximum light emission wavelength in the visible region is preferably used. For example, within a range of 380 to 780 nm, a light emitting material having a maximum light emission wavelength in a range of 380 to 570 nm can be selected and used, a light emitting material having a maximum light emission wavelength in a range of 570 to 650 nm can be selected and used, a light emitting material having a maximum light emission wavelength in a range of 650 to 700 nm can be selected and used, and a light emitting material having a maximum light emission wavelength in a range of 700 to 780 nm can be selected and used.

In a preferred embodiment of the present invention, the second organic compound and the third organic compound are selected and combined so that the light emission wavelength region of the second organic compound and the absorption wavelength region of the third organic compound overlap each other. It is particularly preferred that the edge on the short wavelength side of the light emission spectrum of the second organic compound overlaps the edge on the long wavelength side of the absorption spectrum of the third organic compound.

The third organic compound preferably contains no other metal atom than a boron atom. For example, the third organic compound may be a compound that contains both a boron atom and a fluorine atom, may be a compound that contains a boron atom but no fluorine atom, or may be a compound that contains no metal atom. For example, the third organic compound selected may be a compound containing atoms selected from the group consisting of a carbon atom, a hydrogen atom, a deuterium atom, a nitrogen atom, an oxygen atom, a sulfur atom, a fluorine atom, and a boron atom. For example, the third organic compound selected may be a compound containing atoms selected from the group consisting of a carbon atom, a hydrogen atom, a deuterium atom, a nitrogen atom, an oxygen atom, a fluorine atom, and a boron atom. For example, the third organic compound selected may be a compound containing atoms selected from the group consisting of a carbon atom, a hydrogen atom, a deuterium atom, a nitrogen atom, an oxygen atom, a sulfur atom, and a boron atom. For example, the third organic compound selected may be a compound containing atoms selected from the group consisting of a carbon atom, a hydrogen atom, a deuterium atom, a nitrogen atom, and a boron atom. For example, the third organic compound selected may be a compound containing atoms selected from the group consisting of a carbon atom, a hydrogen atom, a deuterium atom, a nitrogen atom, an oxygen atom, and a sulfur atom. For example, the third organic compound selected may be a compound containing atoms selected from the group consisting of a carbon atom, a hydrogen atom, a deuterium atom, a nitrogen atom, and an oxygen atom. For example, the third organic compound selected may be a compound containing atoms selected from the group consisting of a carbon atom and a hydrogen atom.

Examples of the third organic compound include a compound having a multiple resonance effect of a boron atom and a nitrogen atom, and a compound including a condensed aromatic cyclic structure, such as anthracene, pyrene, and perylene.

In one preferred embodiment of the present invention, a compound represented by the following general formula (15) is used as the third organic compound. General Formula (15)

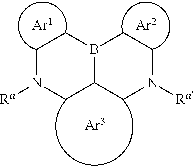

In the general formula (15), Ar¹ to Ar³ each independently represent an aryl ring or a heteroaryl ring, in which at least one hydrogen atom in the ring may be substituted, and a ring may be condensed thereto. In the case where the hydrogen atom is substituted, the hydrogen atom is preferably substituted by one group or a group combining two or more groups selected from the group consisting of a deuterium atom, an aryl group, a heteroaryl group, and an alkyl group. In the case where a ring is condensed thereto, a benzene ring or a heteroaromatic ring (such as a furan ring, a thiophene ring, and a pyrrole ring) is preferably condensed. R^{a} and R^{a′} each independently represent a substituent, and preferably represent one group or a group combining two or more groups selected from the group consisting of a deuterium atom, an aryl group, a heteroaryl group, and an alkyl group. R^{a} and Ar¹, Ar¹ and Ar², Ar² and R^{a′}, R^{a′} and Ar³, and Ar³ and R^{a} each may be bonded to each other to form a cyclic structure.

The compound represented by the general formula (15) preferably includes at least one carbazole structure. For example, one of the benzene rings constituting the carbazole structure may be the ring represented by Ar¹, one of the benzene rings constituting the carbazole structure may be the ring represented by Ar², and one of the benzene rings constituting the carbazole structure may be the ring represented by Ar³. The carbazolyl group may be bonded to one or more of Ar¹ to Ar³. For example, a substituted or unsubstituted carbazol-9-yl group may be bonded to the ring represented by Ar³.

A condensed aromatic cyclic structure, such as anthracene, pyrene, and perylene, may be bonded to Ar to Ar³. Ar¹ to Ar³ may be one ring constituting a condensed aromatic cyclic structure. At least one of R^{a} and R^{a′} may be a group having a condensed aromatic cyclic structure.

The compound may have multiple skeletons each represented by the general formula (15) existing therein. For example, the compound may have a structure including skeletons each represented by the general formula (15) bonded via a single bond or a linking group. The skeleton represented by the general formula (15) may have added thereto a structure showing a multiple resonance effect including benzene rings bonded via a boron atom, a nitrogen atom, an oxygen atom, or a sulfur atom.

In one preferred embodiment of the present invention, a compound including a BODIPY (4,4-difluoro-4-bora-3a,4a-diaza-s-indacene) structure is used as the third organic compound. For example, a compound represented by the following general formula (16) is used.

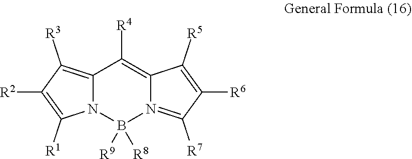

In the general formula (16), R¹ to R⁷ each independently represent a hydrogen atom, a deuterium atom, or a substituent. At least one of R¹ to R⁷ preferably represents a group represented by the following general formula (17).

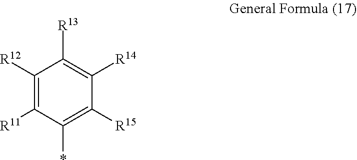

In the general formula (17), R¹¹ to R¹⁵ each independently represent a hydrogen atom, a deuterium atom, or a substituent, and * indicates the bonding position.

The group represented by the general formula (17) may be one of R¹ to R⁷ in the general formula (16), two thereof, or three thereof, and may be at least four thereof, for example, four or five thereof. In one preferred embodiment of the present invention, one of R¹ to R⁷ is the group represented by the general formula (17). In one preferred embodiment of the present invention, at least R¹, R³, R⁵, and R⁷ are the groups represented by the general formula (17). In one preferred embodiment of the present invention, only R¹, R³, R⁴, R⁵, and R⁷ are the groups represented by the general formula (17). In one preferred embodiment of the present invention, R¹, R³, R⁴, R⁵, and R⁷ are the groups represented by the general formula (17), and R² and R⁴ are a hydrogen atom, a deuterium atom, an unsubstituted alkyl group (for example, having 1 to 10 carbon atoms), or an unsubstituted aryl group (for example, having 6 to 14 carbon atoms). In one embodiment of the present invention, all R¹ to R⁷ are the groups represented by the general formula (17).

In one preferred embodiment of the present invention, R¹ and R⁷ are the same as each other. In one preferred embodiment of the present invention, R³ and R⁵ are the same as each other. In one preferred embodiment of the present invention, R² and R⁶ are the same as each other. In one preferred embodiment of the present invention, R¹ and R⁷ are the same as each other, R³ and R⁵ are the same as each other, and R¹ and R³ are different from each other. In one preferred embodiment of the present invention, R¹, R³, R⁵, and R⁷ are the same as each other. In one preferred embodiment of the present invention, R¹, R⁴, and R⁷ are the same as each other, which are different from R³ and R⁵. In one preferred embodiment of the present invention, R³, R⁴, and R⁵ are the same as each other, which are different from R¹ and R⁷. In one preferred embodiment of the present invention, R¹, R³, R⁵, and R⁷ are different from R⁴.

Examples of the substituent that R¹¹ to R¹⁵ in the general formula (17) each can represent include the groups of the substituent group A. The substituent that R¹¹ to R¹⁵ each can represent is preferably one group or a group combining two or more groups selected from the group consisting of a substituted or unsubstituted alkyl group (for example, having 1 to 40 carbon atoms), a substituted or unsubstituted alkoxy group (for example, having 1 to 40 carbon atoms), a substituted or unsubstituted aryl group (for example, having 6 to 30 carbon atoms), a substituted or unsubstituted aryloxy group (for example, having 6 to 30 carbon atoms), and a substituted or unsubstituted amino group (for example, having 0) to 20 carbon atoms) (which are hereinafter referred to as “groups of the substituent group C”). In the substituent group C, an unsubstituted alkyl group having 1 to 20 carbon atoms, an unsubstituted alkoxy group having 1 to 20 carbon atoms, an unsubstituted aryl group having 6 to 14 carbon atoms, an aryloxy group having 6 to 14 carbon atoms, and an unsubstituted diarylamino group having 5 to 20 ring skeleton-forming atoms are preferably selected (which are hereinafter referred to as “groups of the substituent group D”). The substituted amino group herein is preferably a di-substituted amino group, in which two substituent on the amino group each independently are preferably a substituted or unsubstituted aryl group, a substituted or unsubstituted heteroaryl group, or a substituted or unsubstituted alkyl group, and particularly preferably a substituted or unsubstituted aryl group (i.e., forming a diarylamino group). Examples of the substituent that the two aryl groups of the diarylamino group can have include the groups of the substituent group A, the groups of the substituent group B, and the groups of the substituent group C. The two aryl groups of the diarylamino group may be bonded via a single bond or a linking group, and for the description of the linking group herein, reference may be made to the description for the linking group represented by R³³ and R³⁴. Specific examples of the diarylamino group include a substituted or unsubstituted carbazol-9-yl group. Examples of the substituted or unsubstituted carbazol-9-yl group include a group represented by the general formula (5), wherein L¹³ represents a single bond.

In one preferred embodiment of the present invention, in the general formula (17), only R¹³ is a substituent, and R¹¹, R¹², R¹⁴, and R¹⁵ are hydrogen atoms. In one preferred embodiment of the present invention, in the general formula (17), only R¹¹ is a substituent, and R¹², R¹³, R¹⁴, and R¹⁵ are hydrogen atoms. In one preferred embodiment of the present invention, in the general formula (17), only R¹¹ and R¹³ are substituents, and R¹², R¹⁴, and R¹⁵ are hydrogen atoms.

R¹ to R⁷ in the general formula (16) each may include a group represented by the general formula (17), wherein all R¹¹ to R¹⁵ are hydrogen atoms (i.e., a phenyl group). For example, R², R⁴, and R⁶ each may be a phenyl group.

In the general formula (16), R⁸ and R⁹ each independently preferably represent one group or a group combining two or more groups selected from the group consisting of a hydrogen atom, a deuterium atom, a halogen atom, an alkyl group (for example, having 1 to 40 carbon atoms), an alkoxy group (for example, having 1 to 40 carbon atoms), an aryloxy group (for example, having 6 to 30 carbon atoms), and a cyano group. In a preferred embodiment of the present invention, R⁸ and R⁹ are the same as each other. In a preferred embodiment of the present invention, R⁸ and R⁹ each represent a halogen atom, and particularly preferably a fluorine atom.

In one embodiment of the present invention, the total number of the substituted or unsubstituted alkoxy group, the substituted or unsubstituted aryloxy group, and the substituted or unsubstituted amino group existing in R¹ to R⁹ in the general formula (16) is preferably 3 or more, and for example, a compound having the number of 3 or a compound having the number of 4 may be used. In one more preferred embodiment, the total number of the substituted or unsubstituted alkoxy group, the substituted or unsubstituted aryloxy group, and the substituted or unsubstituted amino group existing in R¹ to R⁷ in the general formula (16) is preferably 3 or more, and for example, a compound having the number of 3 or a compound having the number of 4 may be used. In this case, an alkoxy group, an aryloxy group, and an amino group may not exist in R⁸ and R⁹. In one further preferred embodiment, the total number of the substituted or unsubstituted alkoxy group, the substituted or unsubstituted aryloxy group, and the substituted or unsubstituted amino group existing in R¹, R³, R⁴, R⁵, and R⁷ in the general formula (16) is preferably 3 or more, and for example, a compound having the number of 3 or a compound having the number of 4 may be used. In this case, an alkoxy group, an aryloxy group, and an amino group may not exist in R², R⁶, R⁸, and R⁹. In one preferred embodiment of the present invention, 3 or more substituted or unsubstituted alkoxy groups exist. In one preferred embodiment of the present invention, 4 or more substituted or unsubstituted alkoxy groups exist. In one preferred embodiment of the present invention, 1 or more substituted or unsubstituted alkoxy group and two or more substituted or unsubstituted aryloxy groups exist. In one preferred embodiment of the present invention, 2 or more substituted or unsubstituted alkoxy groups and one or more substituted or unsubstituted amino group exist. In one preferred embodiment of the present invention, a substituted or unsubstituted alkoxy group or a substituted or unsubstituted aryloxy group exists in each of R¹, R⁴, and R⁷. In one preferred embodiment of the present invention, a substituted or unsubstituted alkoxy group exists in each of R¹, R⁴, and R⁷.

In one embodiment of the present invention, the total number of the substituent that has a Hammett's σₚ value of less than −0.2 existing in R¹ to R⁹ in the general formula (16) is 3 or more. Examples of the substituent that has a Hammett's σₚ value of less than −0.2 include a methoxy group (−0.27), an ethoxy group (−0.24), a n-propoxy group (−0.25), an isopropoxy group (−0.45), and an n-butoxy group (−0.32). A fluorine atom (0.06), a methyl group (−0.17), an ethyl group (−0.15), a tert-butyl group (−0.20), a n-hexyl group (−0.15), a cyclohexyl group (−0.15), and the like are not the substituent that has a Hammett's σₚ value of less than −0.2.

In one embodiment of the present invention, a compound having 3 of substituents that have a Hammett's σₚ value of less than −0.2 existing in R¹ to R⁹ in the general formula (16) may be used, or a compound having 4 thereof may be used. In one more preferred embodiment, the total number of the substituent that has a Hammett's σₚ value of less than −0.2 existing in R¹ to R⁷ in the general formula (16) is 3 or more, and for example, a compound having 3 thereof may be used, or a compound having 4 thereof may be used. In this case, the substituent that has a Hammett's σₚ value of less than −0.2 may not exist in R⁸ and R⁹. In one further preferred embodiment, the total number of the substituent that has a Hammett's σₚ value of less than −0.2 existing in R¹, R³, R⁴, R⁵, and R⁷ in the general formula (16) is 3 or more, and for example, a compound having 3 thereof may be used, or a compound having 4 thereof may be used. In this case, the substituent that has a Hammett's σₚ value of less than −0.2 may not exist in R², R⁶, R⁸, and R⁹. In a preferred embodiment of the present invention, the substituent that has a Hammett's σₚ value of less than −0.2 exists in each of R¹, R⁴, and R⁷.

Preferred examples of the compound that can be used as the third organic compound are shown below. In the following structural formulae of the example compounds, t-Bu represents a tert-butyl group.

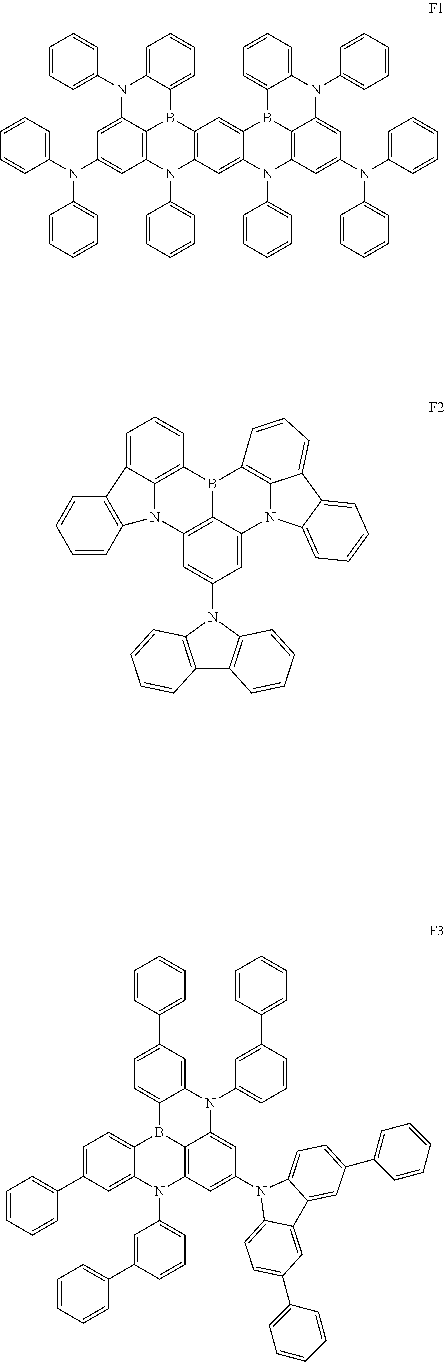 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1 ; c1ccc2c(c1)c1ccccc1n2-c1cc2c3c(c1)-n1c4ccccc4c4cccc(c41)B3c1cccc3c4ccccc4n-2c13 ; c1ccc(-c2cccc(N3c4cc(-c5ccccc5)ccc4B4c5ccc(-c6ccccc6)cc5N(c5cccc(-c6ccccc6)c5)c5cc(-n6c7ccc(-c8ccccc8)cc7c7cc(-c8ccccc8)ccc76)cc3c54)c2)cc1]

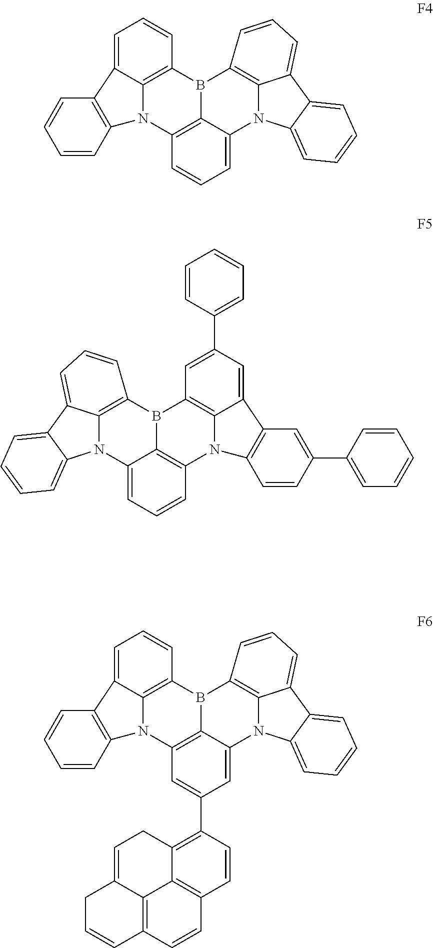 [SMILES: c1cc2c3c(c1)-n1c4ccccc4c4cccc(c41)B3c1cccc3c4ccccc4n-2c13 ; c1ccc(-c2ccc3c(c2)c2cc(-c4ccccc4)cc4c2n3-c2cccc3c2B4c2cccc4c5ccccc5n-3c24)cc1 ; C1=Cc2ccc3ccc(-c4cc5c6c(c4)-n4c7ccccc7c7cccc(c74)B6c4cccc6c7ccccc7n-5c46)c4c3c2C(=CC4)C1]

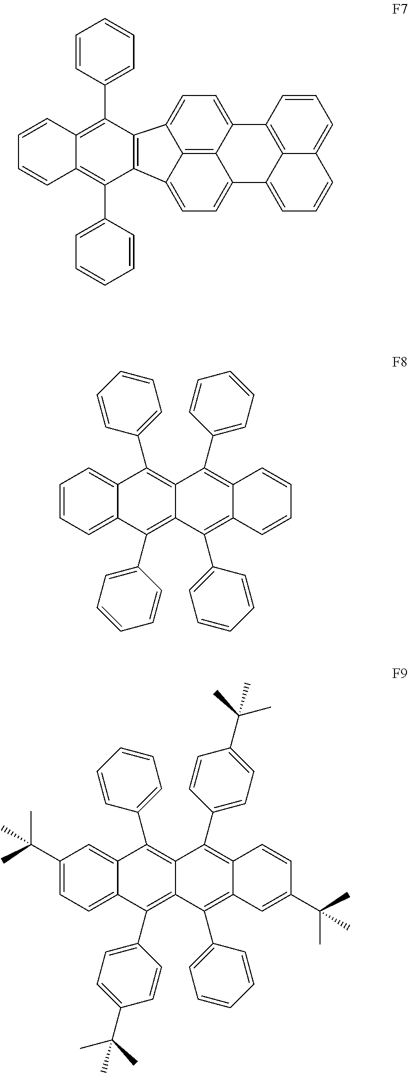

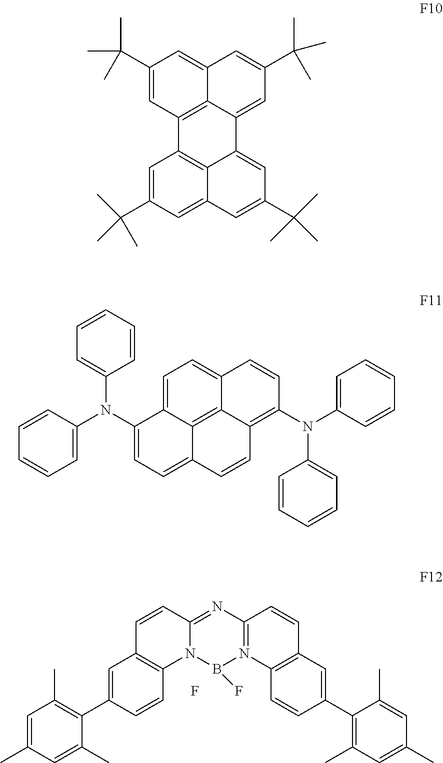

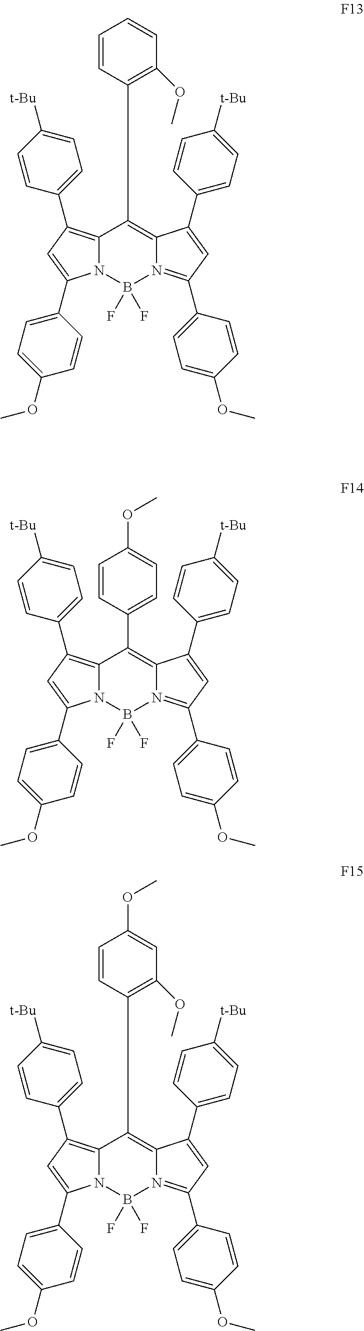

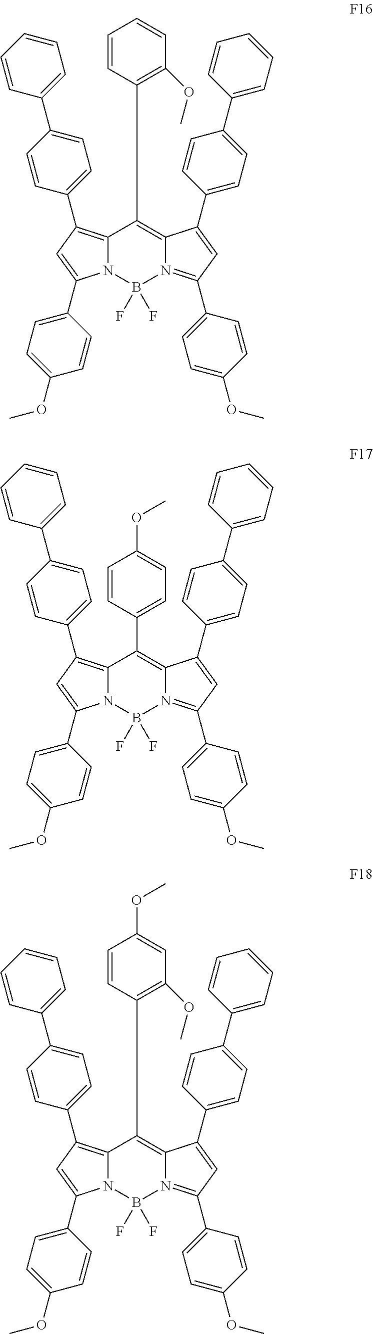

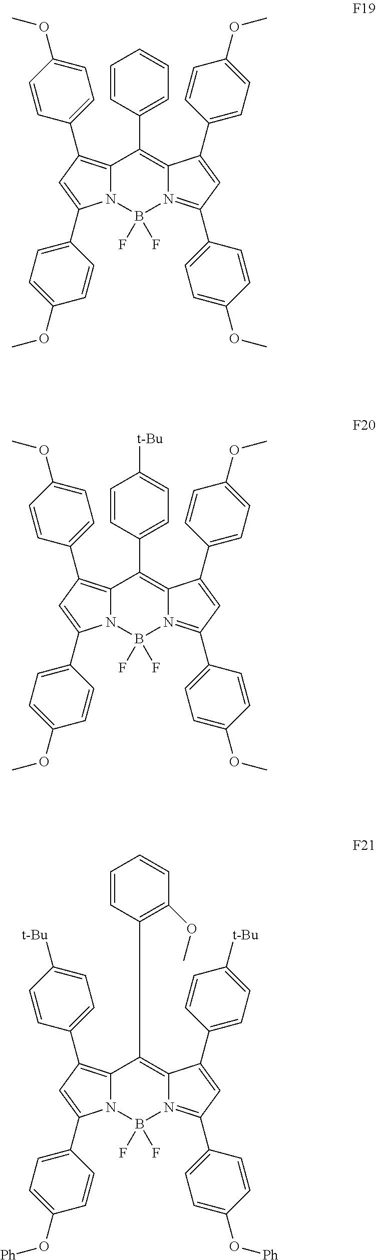

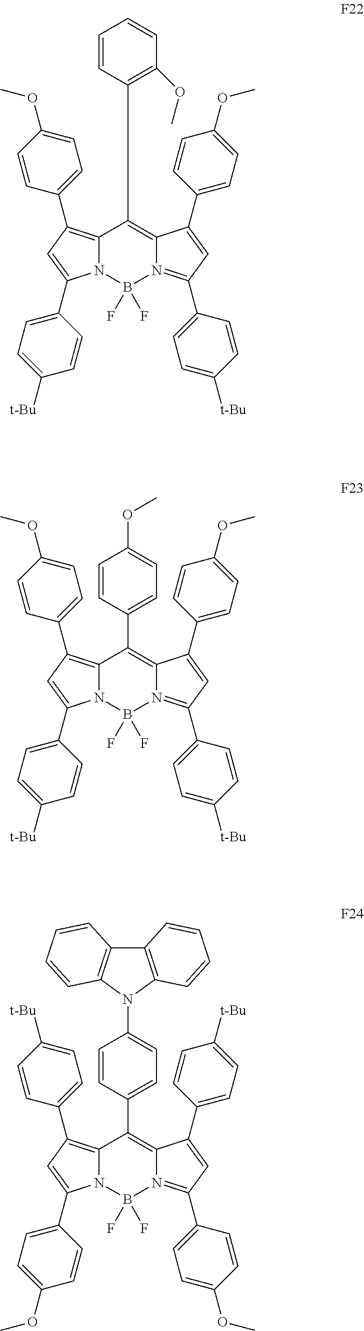

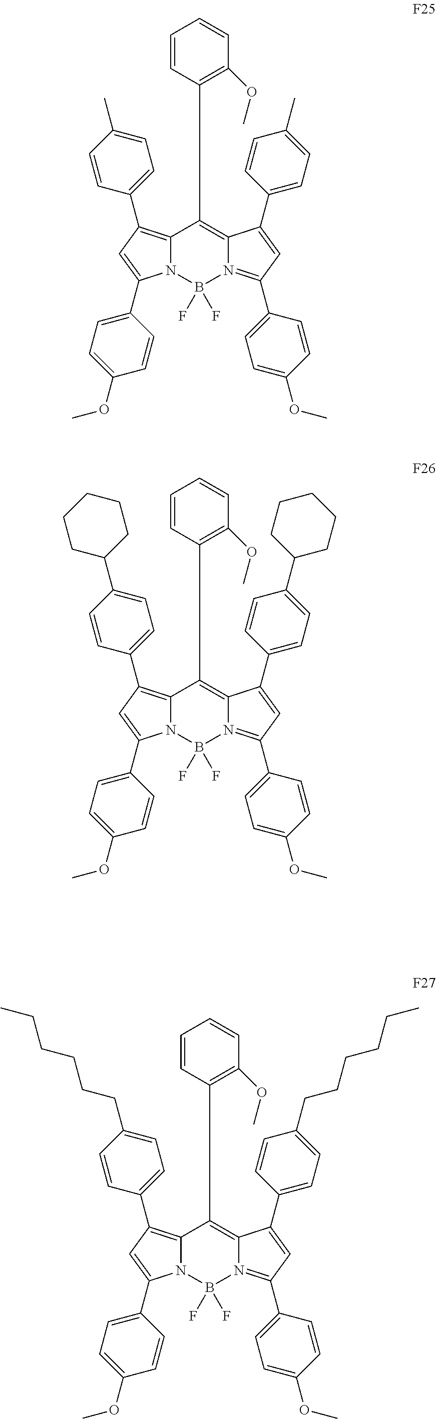

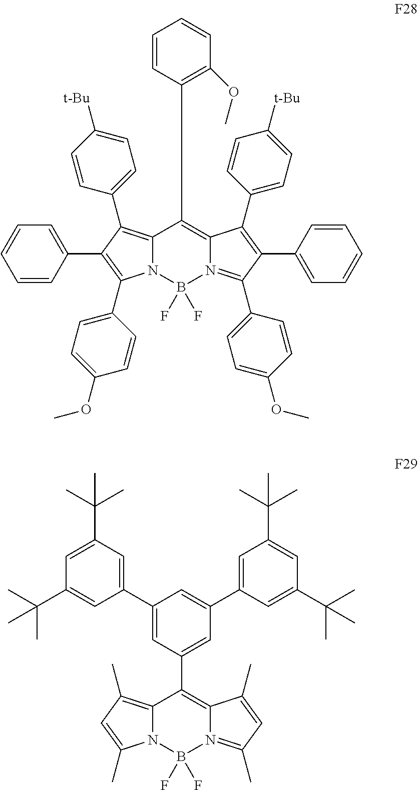

Examples of derivatives of the example compounds include compounds obtained by substituting at least one hydrogen atom by a deuterium atom, an alkyl group, an aryl group, a heteroaryl group, or a diarylamino group.

The compounds described in WO 2015/022974, paragraphs 0220 to 0239 can also particularly preferably used as the third organic compound in the present invention.

### Light Emitting Layer

The light emitting layer of the organic electroluminescent device of the present invention contains the first organic compound, the second organic compound, and the third organic compound that satisfy the conditions (a) to (c). The light emitting layer may have a configuration that does not contain a compound donating or receiving charge or energy or a metal element other than boron, in addition to the first organic compound, the second organic compound, and the third organic compound. The light emitting layer may be constituted only by a compound containing atoms selected from the group consisting of a carbon atom, a hydrogen atom, a deuterium atom, a nitrogen atom, a boron atom, an oxygen atom, and a sulfur atom. For example, the light emitting layer may be constituted only by a compound containing atoms selected from the group consisting of a carbon atom, a hydrogen atom, a deuterium atom, a nitrogen atom, a boron atom, and an oxygen atom. For example, the light emitting layer may be constituted only by a compound containing atoms selected from the group consisting of a carbon atom, a hydrogen atom, a deuterium atom, a nitrogen atom, a boron atom, and a sulfur atom. For example, the light emitting layer may be constituted only by a compound containing atoms selected from the group consisting of a carbon atom, a hydrogen atom, a deuterium atom, a nitrogen atom, and a boron atom. For example, the light emitting layer may be constituted only by a compound containing atoms selected from the group consisting of a carbon atom, a hydrogen atom, a deuterium atom, a nitrogen atom, an oxygen atom, and a sulfur atom. For example, the light emitting layer may be constituted only by a compound containing atoms selected from the group consisting of a carbon atom, a hydrogen atom, a deuterium atom, and a nitrogen atom. The light emitting layer may include the first organic compound constituted by atoms selected from the group consisting of a carbon atom, a hydrogen atom, a nitrogen atom, and an oxygen atom, the second organic compound constituted by atoms selected from the group consisting of a carbon atom, a hydrogen atom, a deuterium atom, a nitrogen atom, and an oxygen atom, and the third organic compound constituted by atoms selected from the group consisting of a carbon atom, a hydrogen atom, a deuterium atom, a nitrogen atom, a boron atom, an oxygen atom, and a sulfur atom. The light emitting layer may include the first organic compound constituted by atoms selected from the group consisting of a carbon atom, a hydrogen atom, a nitrogen atom, and an oxygen atom, the second organic compound constituted by atoms selected from the group consisting of a carbon atom, a hydrogen atom, a deuterium atom, and a nitrogen atom, and the third organic compound constituted by atoms selected from the group consisting of a carbon atom, a hydrogen atom, a deuterium atom, a nitrogen atom, and a boron atom.

The light emitting layer may be formed through vapor co-deposition of the first organic compound, the second organic compound, and the third organic compound, or may be formed by a coating method using a solution having the first organic compound, the second organic compound, and the third organic compound dissolved therein. In the formation of the light emitting layer through vapor co-deposition, it is possible that two or more of the first organic compound, the second organic compound, and the third organic compound are mixed in advance and the placed as a vapor deposition source in a crucible, and the light emitting layer is formed through vapor co-deposition with the vapor deposition source. For example, it is possible that the first organic compound and the second organic compound are mixed in advance to form a single vapor deposition source, and the light emitting layer is formed through vapor co-deposition using the vapor deposition source and the third organic compound as another vapor deposition source.

### Layer Configuration of Top Emission Type Organic Electroluminescent Device

The layer configuration of the organic electroluminescent device of the present invention will be described below.

The organic electroluminescent device of the present invention is a top emission type organic electroluminescent device including a lamination structure including at least a substrate, a first electrode, a light emitting layer, and a second electrode in this order, emitting light from the side opposite to the substrate (i.e., the side of the second electrode). The top emission type is also referred to as a “film surface emission type”, and for the configuration thereof, for example, reference may be made to Appl. Phys. Lett., 65, pp. 2636-2638 (1994). In following description, the layer configuration will be described with “/” as a symbol showing the boundary between layers. For example, a configuration including a substrate, a first electrode, a light emitting layer, and a second electrode in this order is shown by substrate/first electrode/light emitting layer/second electrode. The second electrode herein is transparent, and the first electrode may be either transparent or opaque. One of the first electrode and the second electrode functions as an anode, and the other thereof functions as a cathode. In the case where both the first electrode and the second electrode are transparent, and the substrate is also transparent, the organic electroluminescent device emits light from both the side of the substrate and the side opposite to the substrate. The top emission type organic electroluminescent device of the present invention encompasses this double side light emission type organic electroluminescent device, in addition to a single side light emission type organic electroluminescent device emitting light only from the side opposite to the substrate. The double side light emission type organic electroluminescent device may transmit external light in the thickness direction. In this case, an observer on the side opposite to the substrate of the organic electroluminescent device can view the scenery on the side of the substrate through the organic electroluminescent device.

One or more layers of a functional layer may be provided between the first electrode and the second electrode, in addition to the light emitting layer. Examples of the functional layer include a hole injection layer, a hole transporting layer, an electron barrier layer, a hole barrier layer, an electron transporting layer, and an electron injection layer.

Specific examples of the structure of the organic electroluminescent device will be described below. In the following description, the layer between the first electrode and the second electrode will be referred to as an “intermediate layer”

### <1> First Embodiment of Organic Electroluminescent Device

The organic electroluminescent device of the first embodiment has the first electrode that functions as an anode and the second electrode that functions as a cathode. Preferred specific examples (a-i) to (a-viii) of the organic electroluminescent device are shown below. In the specific examples, the layers are formed on the substrate in the order from the anode so that the anode is on the side of the substrate, and the cathode is the uppermost layer. The hole transporting layer may also has the function of an electron barrier layer. An electron barrier layer may also be provided between the hole transporting layer and the light emitting layer, in addition to the hole transporting layer.
(a-i) anode/light emitting layer/electron transporting layer/electron injection layer/cathode
(a-ii) anode/hole transporting layer/light emitting layer/electron transporting layer/electron injection layer/cathode
(a-iii) anode/hole transporting layer/light emitting layer/hole barrier layer/electron transporting layer/electron injection layer/cathode
(a-iv) anode/hole injection layer/hole transporting layer/light emitting layer/electron transporting layer/electron injection layer/cathode
(a-v) anode/light emitting layer/electron transporting layer/electron injection layer/transparent protective layer/cathode
(a-vi) anode/hole transporting layer/light emitting layer/electron transporting layer/electron injection layer/transparent protective layer/cathode
(a-vii) anode/hole transporting layer/light emitting layer/hole barrier layer/electron transporting layer/electron injection layer/transparent protective layer/cathode
(a-viii) anode/hole injection layer/hole transporting layer/light emitting layer/electron layer/electron injection layer/transparent protective layer/cathode

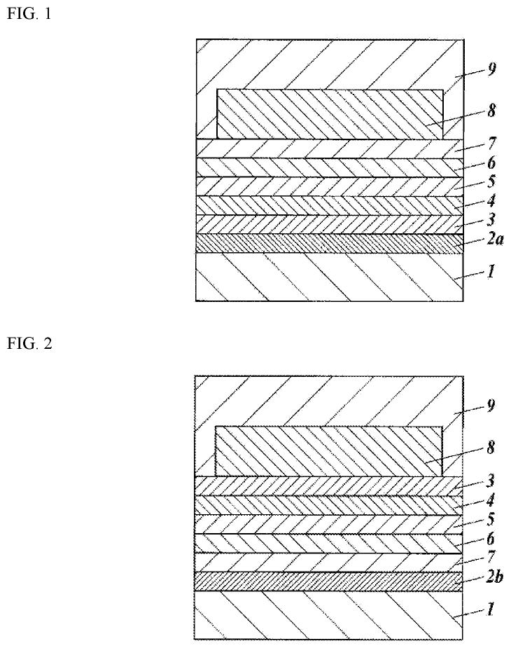

As a representative example, the organic electroluminescent device having the layer configuration (a-vii) is shown in FIG. 1. In FIG. 1, numeral 1 denotes the substrate, 2a denotes the anode, 3 denotes the hole injection layer, 4 denotes the hole transporting layer, 5 denotes the light emitting layer, 6 denotes the electron transporting layer, 7 denotes the electron injection layer, 8 denotes the transparent protective layer, and 9 denotes the transparent conductive layer (cathode).

The layers other than the light emitting layer constituting the organic electroluminescent device will be described below.

### Cathode

The material used as the cathode may be a transparent conductive material, such as indium tin oxide (ITO), indium zinc oxide (IZO), SnO₂, ZnO, and In₂O₃. A material capable of forming an amorphous transparent conductive film, such as IDIXO (In₂O₃—ZnO) may also be used. The sheet resistance of the transparent conductive layer used as the cathode is preferably several hundred Ω/square or less. The thickness of the cathode is generally 10 to 1,000 nm, preferably 50 to 200 nm, and particularly preferably 100 nm, while varying depending on the material.

### Anode

The material used as the anode may be, for example, a metal, such as Ag, Mg, Al, Pt, Pd, Au, Ni, Nd, Ir, Cr, Li, Ca, LiF/Ca, and LiF/Al, and an alloy thereof. The anode can be formed by thinly vapor-depositing the metal or alloy. The transparent conductive materials exemplified for the cathode may also be used as the material of the anode. The thickness of the anode is generally 10 to 1,000 nm, and preferably 10 to 200 nm, while varying depending on the material.

### Injection Layer

An injection layer is a layer between the electrode and the organic layer. In some embodiments, the injection layer decreases the driving voltage and enhances the light emission luminance. In some embodiments the injection layer includes a hole injection layer and an electron injection layer. The injection layer can be positioned between the anode and the light-emitting layer or the hole transporting layer, and between the cathode and the light-emitting layer or the electron transporting layer. In some embodiments, an injection layer is present. In some embodiments, no injection layer is present.

Preferred compound examples for use as a hole injection material are shown below.

### MoO₃

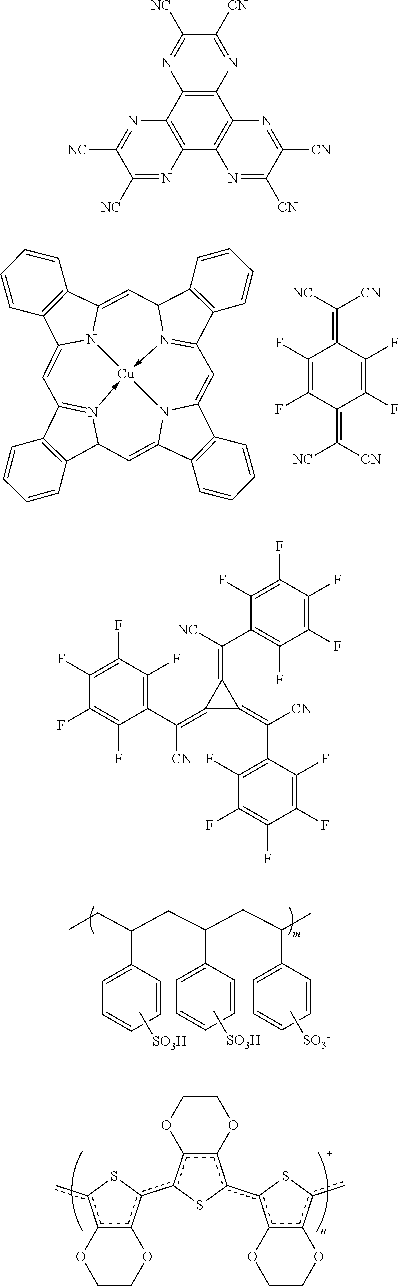

Next, preferred compound examples for use as an electron injection material are shown below.

### LiF, CsF

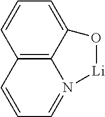

### Barrier Layer

A barrier layer is a layer capable of inhibiting charges (electrons or holes) and/or excitons present in the light-emitting layer from being diffused outside the light-emitting layer. In some embodiments, the electron barrier layer is between the light-emitting layer and the hole transporting layer, and inhibits electrons from passing through the light-emitting layer toward the hole transporting layer. In some embodiments, the hole barrier layer is between the light-emitting layer and the electron transporting layer, and inhibits holes from passing through the light-emitting layer toward the electron transporting layer. In some embodiments, the barrier layer inhibits excitons from being diffused outside the light-emitting layer. In some embodiments, the electron barrier layer and the hole barrier layer are exciton barrier layers. As used herein, the term “electron barrier layer” or “exciton barrier layer” includes a layer that has the functions of both electron barrier layer and of an exciton barrier layer.

### Hole Barrier Layer

A hole barrier layer acts as an electron transporting layer. In some embodiments, the hole barrier layer inhibits holes from reaching the electron transporting layer while transporting electrons. In some embodiments, the hole barrier layer enhances the recombination probability of electrons and holes in the light-emitting layer. The material for the hole barrier layer may be the same materials as the ones described for the electron transporting layer.

Preferred compound examples for use for the hole barrier layer are shown below.

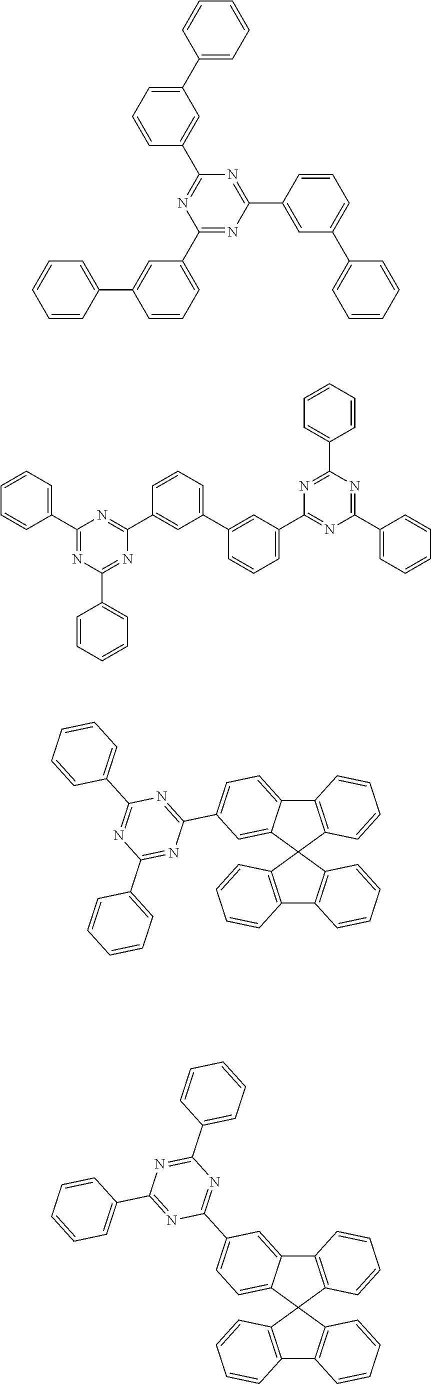 [SMILES: c1ccc(-c2cccc(-c3nc(-c4cccc(-c5ccccc5)c4)nc(-c4cccc(-c5ccccc5)c4)n3)c2)cc1 ; c1ccc(-c2nc(-c3ccccc3)nc(-c3cccc(-c4cccc(-c5nc(-c6ccccc6)nc(-c6ccccc6)n5)c4)c3)n2)cc1 ; c1ccc(-c2nc(-c3ccccc3)nc(-c3ccc4c(c3)C3(c5ccccc5-c5ccccc53)c3ccccc3-4)n2)cc1 ; c1ccc(-c2nc(-c3ccccc3)nc(-c3ccc4c(c3)-c3ccccc3C43c4ccccc4-c4ccccc43)n2)cc1]

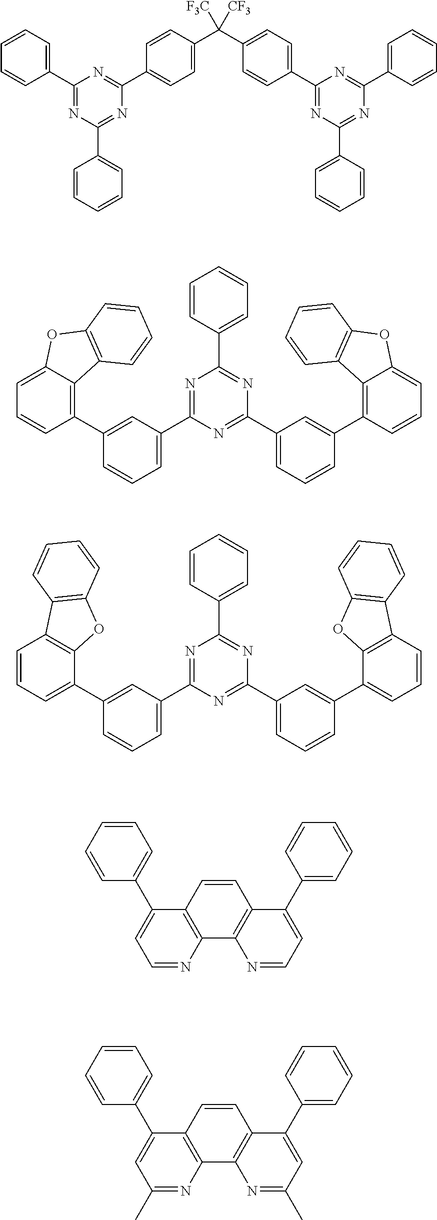 [SMILES: FC(F)(F)C(c1ccc(-c2nc(-c3ccccc3)nc(-c3ccccc3)n2)cc1)(c1ccc(-c2nc(-c3ccccc3)nc(-c3ccccc3)n2)cc1)C(F)(F)F ; c1ccc(-c2nc(-c3cccc(-c4cccc5oc6ccccc6c45)c3)nc(-c3cccc(-c4cccc5oc6ccccc6c45)c3)n2)cc1 ; c1ccc(-c2nc(-c3cccc(-c4cccc5c4oc4ccccc45)c3)nc(-c3cccc(-c4cccc5c4oc4ccccc45)c3)n2)cc1 ; c1ccc(-c2ccnc3c2ccc2c(-c4ccccc4)ccnc23)cc1 ; Cc1cc(-c2ccccc2)c2ccc3c(-c4ccccc4)cc(C)nc3c2n1]

### Electron Barrier Layer

As electron barrier layer transports holes. In some embodiments, the electron barrier layer inhibits electrons from reaching the hole transporting layer while transporting holes. In some embodiments, the electron barrier layer enhances the recombination probability of electrons and holes in the light-emitting layer. The material used for the electron barrier layer may be the same materials as the ones mentioned above for the hole transporting layer.

Preferred compound examples for use as the electron barrier material are shown below.

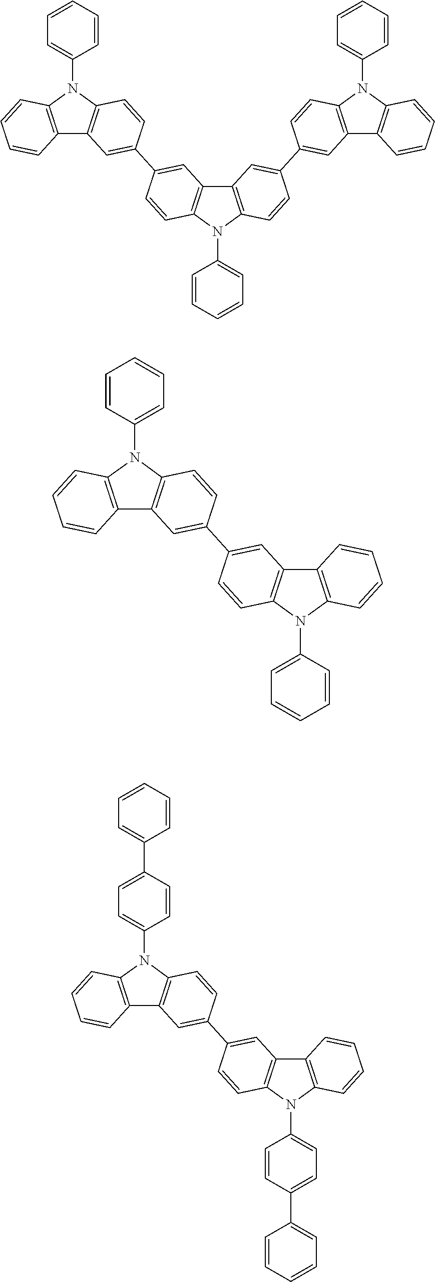 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1ccc(-n2c3ccccc3c3cc(-c4ccc5c(c4)c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

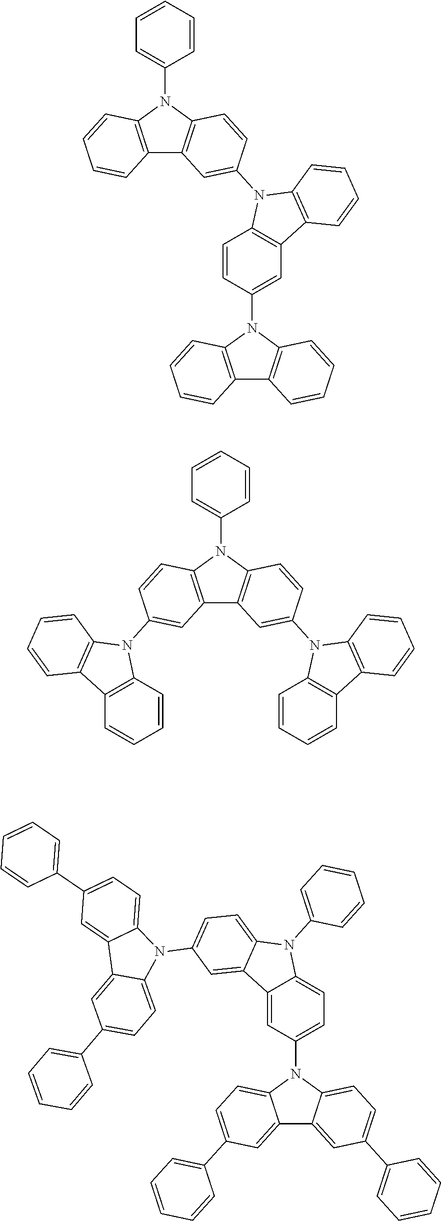 [SMILES: c1ccc(-n2c3ccccc3c3cc(-n4c5ccccc5c5cc(-n6c7ccccc7c7ccccc76)ccc54)ccc32)cc1 ; c1ccc(-n2c3ccc(-n4c5ccccc5c5ccccc54)cc3c3cc(-n4c5ccccc5c5ccccc54)ccc32)cc1 ; c1ccc(-c2ccc3c(c2)c2cc(-c4ccccc4)ccc2n3-c2ccc3c(c2)c2cc(-n4c5ccc(-c6ccccc6)cc5c5cc(-c6ccccc6)ccc54)ccc2n3-c2ccccc2)cc1]

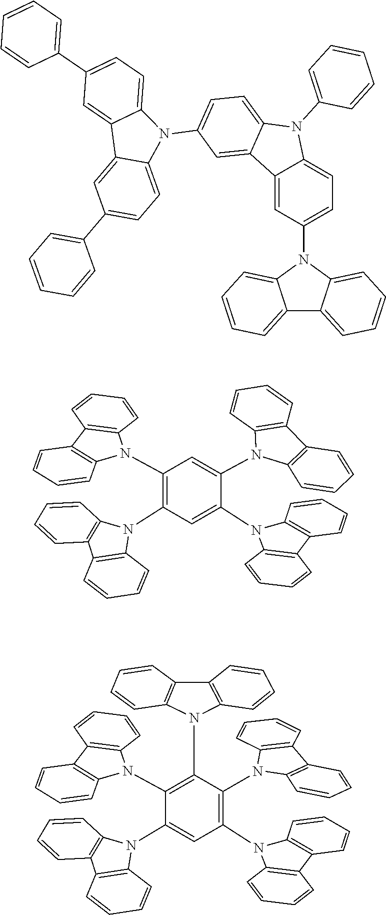 [SMILES: c1ccc(-c2ccc3c(c2)c2cc(-c4ccccc4)ccc2n3-c2ccc3c(c2)c2cc(-n4c5ccccc5c5ccccc54)ccc2n3-c2ccccc2)cc1 ; c1ccc2c(c1)c1ccccc1n2-c1cc(-n2c3ccccc3c3ccccc32)c(-n2c3ccccc3c3ccccc32)cc1-n1c2ccccc2c2ccccc21 ; c1ccc2c(c1)c1ccccc1n2-c1cc(-n2c3ccccc3c3ccccc32)c(-n2c3ccccc3c3ccccc32)c(-n2c3ccccc3c3ccccc32)c1-n1c2ccccc2c2ccccc21]

### Exciton Barrier Layer

An exciton barrier layer inhibits excitons generated through recombination of holes and electrons in the light-emitting layer from being diffused to the charge transporting layer. In some embodiments, the exciton barrier layer enables effective confinement of excitons in the light-emitting layer. In some embodiments, the light emission efficiency of the device is enhanced. In some embodiments, the exciton barrier layer is adjacent to the light-emitting layer on any of the side of the anode and the side of the cathode, and on both the sides. In some embodiments, where the exciton barrier layer is on the side of the anode, the layer can be between the hole transporting layer and the light-emitting layer and adjacent to the light-emitting layer. In some embodiments, where the exciton barrier layer is on the side of the cathode, the layer can be between the light-emitting layer and the cathode and adjacent to the light-emitting layer. In some embodiments, a hole injection layer, an electron barrier layer, or a similar layer is between the anode and the exciton barrier layer that is adjacent to the light-emitting layer on the side of the anode. In some embodiments, a hole injection layer, an electron barrier layer, a hole barrier layer, or a similar layer is between the cathode and the exciton barrier layer that is adjacent to the light-emitting layer on the side of the cathode. In some embodiments, the exciton barrier layer comprises excited singlet energy and excited triplet energy, at least one of which is higher than the excited singlet energy and the excited triplet energy of the light-emitting material, respectively.

### Hole Transporting Layer

The hole transporting layer comprises a hole transporting material. In some embodiments, the hole transporting layer is a single layer. In some embodiments, the hole transporting layer comprises a plurality layers.

In some embodiments, the hole transporting material has one of injection or transporting property of holes and barrier property of electrons. In some embodiments, the hole transporting material is an organic material. In some embodiments, the hole transporting material is an inorganic material. Examples of known bole transporting materials that may be used herein include but are not limited to a triazole derivative, an oxadiazole derivative, an imidazole derivative, a carbazole derivative, an indolocarbazole derivative, a polyarylalkane derivative, a pyrazoline derivative, a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, an aniline copolymer and an electroconductive polymer oligomer, particularly a thiophene oligomer, or a combination thereof. In some embodiments, the hole transporting material is selected from a porphyrin compound, an aromatic tertiary amine compound, and a styrylamine compound. In some embodiments, the hole transporting material is an aromatic tertiary amine compound. Preferred compound examples for use as the hole transporting material are shown below.

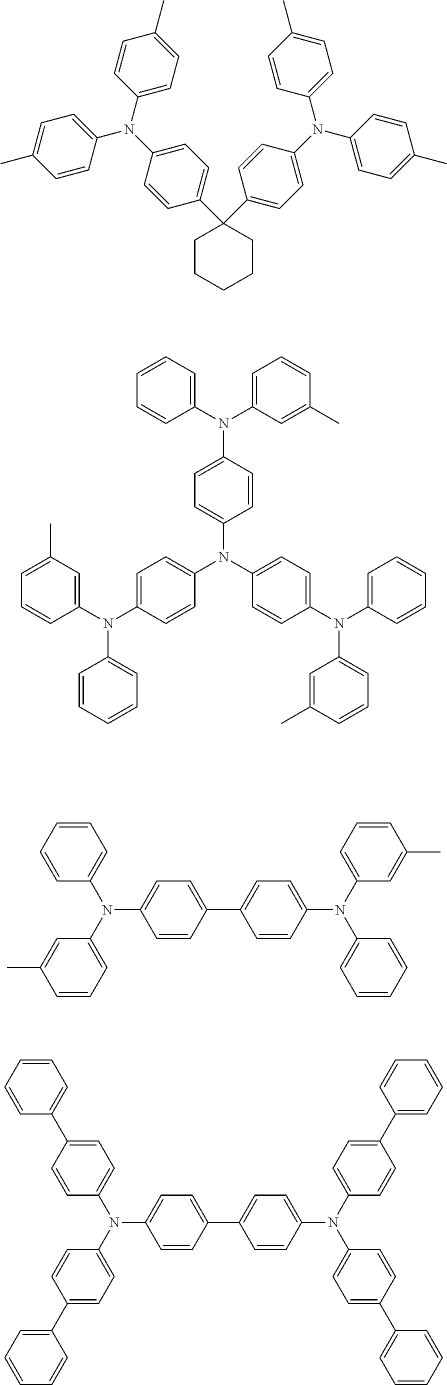

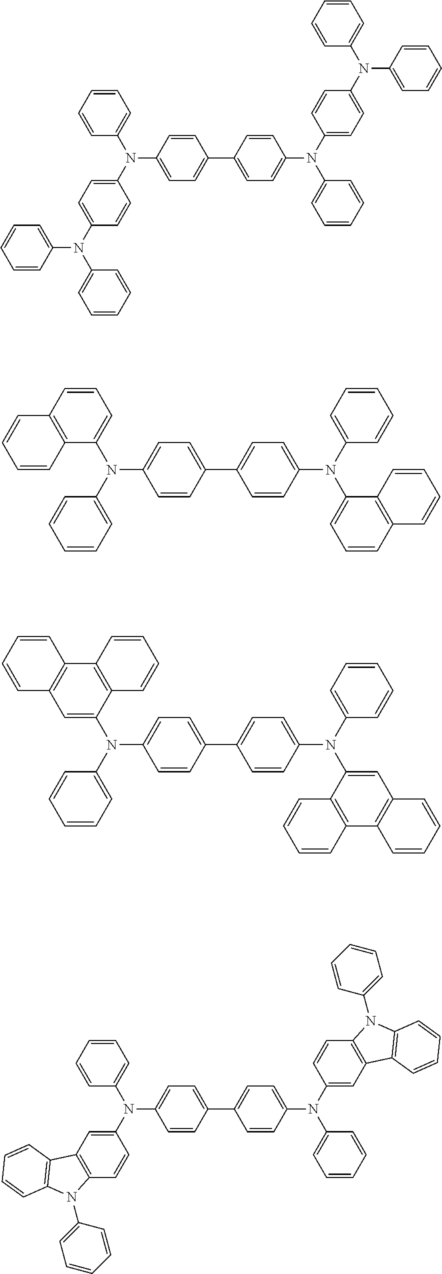 [SMILES: c1ccc(N(c2ccccc2)c2ccc(N(c3ccccc3)c3ccc(-c4ccc(N(c5ccccc5)c5ccc(N(c6ccccc6)c6ccccc6)cc5)cc4)cc3)cc2)cc1 ; c1ccc(N(c2ccc(-c3ccc(N(c4ccccc4)c4cccc5ccccc45)cc3)cc2)c2cccc3ccccc23)cc1 ; c1ccc(N(c2ccc(-c3ccc(N(c4ccccc4)c4cc5ccccc5c5ccccc45)cc3)cc2)c2cc3ccccc3c3ccccc23)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

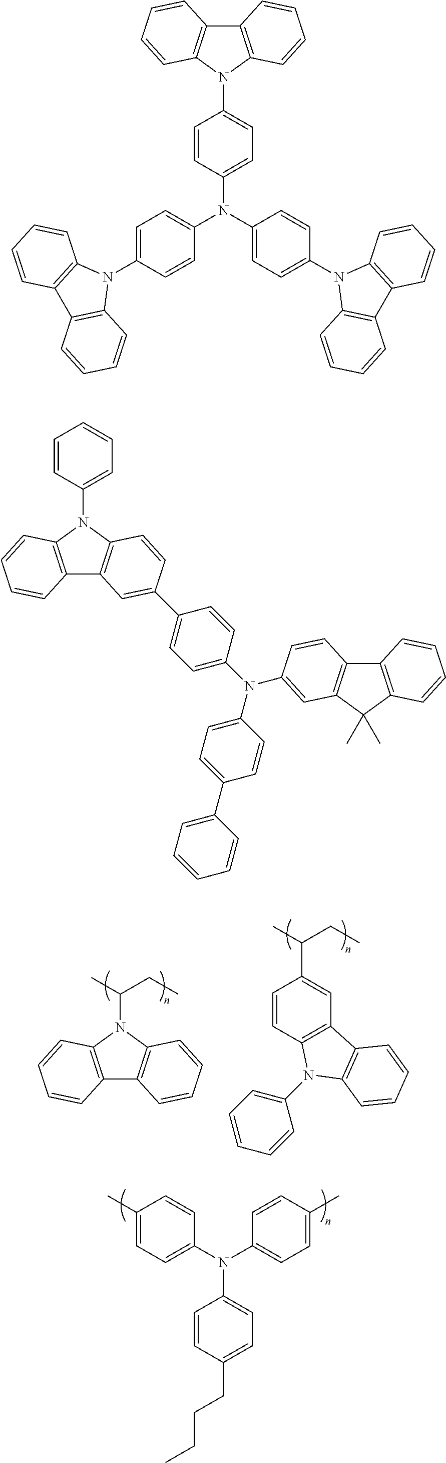

### Electron Transporting Layer

The electron transporting layer comprises an electron transporting material. In some embodiments, the electron transporting layer is a single layer. In some embodiments, the electron transporting layer comprises a plurality of layer.

In some embodiments, the electron transporting material needs only to have a function of transporting electrons, which are injected from the cathode, to the light-emitting layer. In some embodiments, the electron transporting material also function as a hole barrier material. Examples of the electron transporting layer that may be used herein include but are not limited to a nitro-substituted fluorene derivative, a diphenylquinone derivative, a thiopyran dioxide derivative, carbodiimide, a fluorenylidene methane derivative, anthraquinodimethane, an anthrone derivatives, an azole derivative, an azine derivative, an oxadiazole derivative, or a combination thereof, or a polymer thereof. In some embodiments, the electron transporting material is a thiadiazole derivative, or a quinoxaline derivative. In some embodiments, the electron transporting material is a polymer material. Preferred compound examples for use as the electron transporting material are shown below.

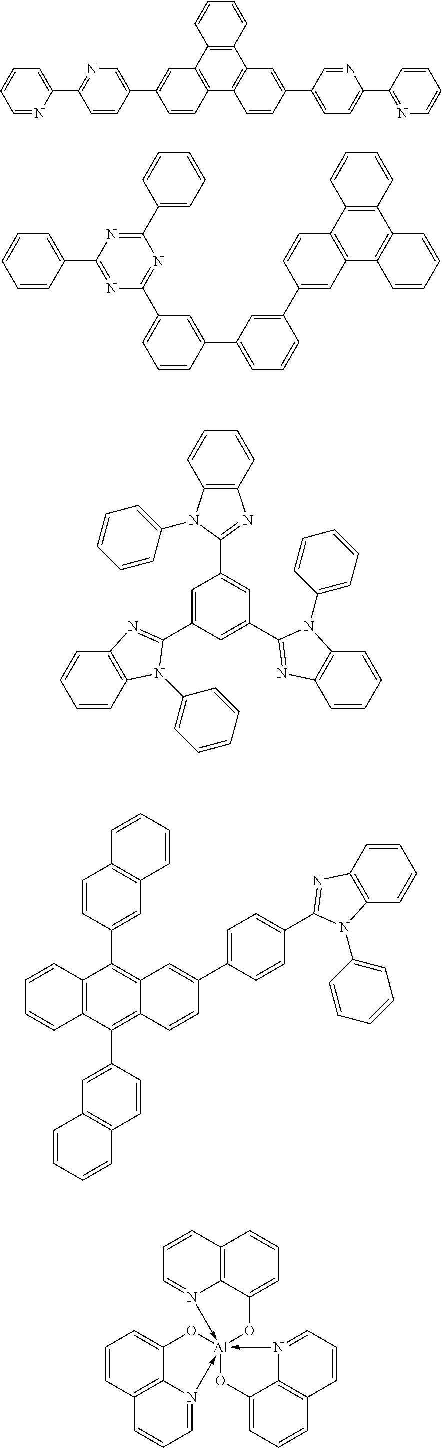

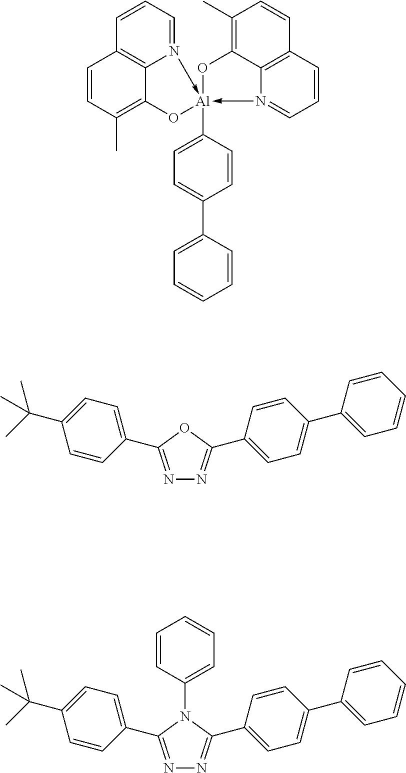

Hereinunder compound examples preferred as a material that can be added to the organic layers are shown. For example, these can be added as a stabilization material.

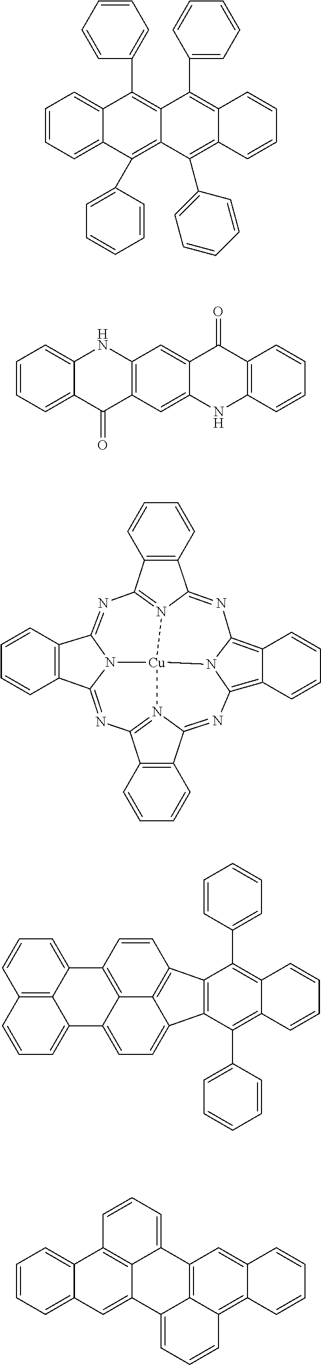

### Transparent Protective Layer

The organic electroluminescent device of the first embodiment may have a transparent protective layer that is provided between the cathode and the organic light emitting layer. The transparent protective layer is provide, for example, between the cathode and the electron injection layer. According to the configuration, after forming the transparent protective layer, the light emitting layer and the electron injection layer are protected with the transparent protective layer, and therefore the light emitting layer and the electron injection layer can be prevented from being deteriorated in the subsequent process. The transparent protective layer may be patterned. According to the configuration, the cathode and the electron injection layer can be allowed to be electrically in contact with each other, and thereby the driving voltage of the device can be reduced. Examples of the pattern of the transparent protective layer include a stripe pattern and a lattice pattern, and the distance between lines thereof is preferably 500 to 5,000 μm. Examples of the patterning method of the transparent protective layer include the shadow mask method, the laser thermal transfer method, the laser vapor deposition method, the laser ablation method, the ink-jet method, and the printing method.

Examples of the material of the transparent protective layer include a metal complex, such as tris(8-quinolilato)aluminum, and a metal oxide, such as molybdenum oxide and vanadium oxide. The thickness of the transparent protective layer is not particularly limited, and is preferably 50 to 200 nm.

### Auxiliary Electrode

The organic electroluminescent device of the first embodiment may have an auxiliary electrode provided on the cathode. According to the configuration, the electric resistance of the device can be reduced to reduce the driving voltage.

The material used for the auxiliary electrode may be a low resistance metal, such as Au, Pt, Pd, Ag, Cu, and Al. The auxiliary electrode preferably has a line width of 1 to 50 μm. According to the configuration, the auxiliary electrode can exert the sufficient function thereof while securing the aperture ratio of the light emitting surface. In the case where the organic electroluminescent device has the transparent protective layer, the auxiliary electrode is preferably formed in the area having no transparent protective layer formed therein.

On applying an electric field between the cathode and the anode of the organic electroluminescent device of the first embodiment constituted as described above, holes and electrons injected from the electrodes are recombined in the organic light emitting layer, and the light emitting material is allowed to be the excited state. Light emitted from the light emitting material in the excited state is emitted outside, and thereby the organic electroluminescent device emits light. In the organic electroluminescent device of the first embodiment herein, the light emitted from the light emitting material is emitted from the side of the cathode (i.e., the side opposite to the substrate) since the cathode disposed on the opposite side to the substrate is transparent. The cathode side has a high aperture ratio since neither wiring nor driving element is formed on the substrate, achieving a high light extraction efficiency.

### <2> Second Embodiment of Organic Electroluminescent Device

The organic electroluminescent device of the second embodiment has the first electrode that functions as a cathode and the second electrode that functions as an anode. Preferred specific examples (b-i) to (b-viii) of the organic electroluminescent device are shown below. In the specific examples, the layers are formed on the substrate in the order from the cathode so that the cathode is on the side of the substrate, and the anode is the uppermost layer. The hole transporting layer may also has the function of an electron barrier layer. An electron barrier layer may also be provided between the hole transporting layer and the organic light emitting layer, in addition to the hole transporting layer.
(b-i) anode/organic light emitting layer/electron transporting layer/electron injection layer/cathode
(b-ji) anode/hole transporting layer/organic light emitting layer/electron transporting layer/electron injection layer/cathode
(b-iii) anode/hole transporting layer/organic light emitting layer/hole barrier layer/electron transporting layer/electron injection layer/cathode
(b-iv) anode/hole injection layer/hole transporting layer/organic light emitting layer/electron transporting layer/electron injection layer/cathode
(b-v) anode/transparent protective layer/organic light emitting layer/electron transporting layer/electron injection layer/cathode
(b-vi) anode/transparent protective layer/hole transporting layer/organic light emitting layer/electron transporting layer/electron injection layer/cathode
(b-vii) anode/transparent protective layer/hole transporting layer/organic light emitting layer/hole barrier layer/electron transporting layer/electron injection layer/cathode
(b-viii) anode/transparent protective layer/hole injection layer/hole transporting layer/organic light emitting layer/electron transporting layer/electron injection layer/cathode

As a representative example, the organic electroluminescent device having the layer configuration (b-viii) is shown in FIG. 2. In FIG. 2, numeral 1 denotes the substrate, 2b denotes the cathode, 3 denotes the hole injection layer, 4 denotes the hole transporting layer, 5 denotes the organic light emitting layer, 6 denotes the electron transporting layer, 7 denotes the electron injection layer, 8 denotes the transparent protective layer, and 9 denotes the transparent conductive layer (anode).

For the descriptions and the preferred ranges of the cathode, the organic light emitting layer, the electron injection layer, the hole injection layer, the electron transporting layer, and the hole transporting layer, reference may be made to the section “First Embodiment of Organic Electroluminescent Device”. The material used for the cathode may be the transparent conductive material used in the first embodiment, and may also be a metal or alloy having a relatively small work function, such as aluminum.

The anode is constituted by a transparent material. Examples of the transparent conductive material that can be used as the anode include indium tin oxide (ITO), indium zinc oxide (IZO), ZnO, In₂O₃, and DIXO (In₂O₃—ZnO). The anode may have a three-layer structure including an auxiliary layer, a conductive layer, and an insulating layer in this order from the side of the organic light emitting layer.

The auxiliary layer has a function assisting the injection of boles from the anode to the intermediate layer. The material that can be used in the auxiliary layer may be a material capable of regulating the energy barrier between the conductive layer and the intermediate layer, for example, a material having a lower HOMO (highest occupied molecular orbital) level than the layer as the intermediate layer that is in contact with the auxiliary layer (such as the hole injection layer) or a material having a dipole. The auxiliary layer may be constituted by two layers including a material layer formed of a material having a lower HOMO level than the layer as the intermediate layer that is in contact with the auxiliary layer and a material layer formed of a material having a dipole. Specific examples of the material of the auxiliary layer include tungsten oxide, fullerene, copper phthalocyanine, tetracyanoquinodimethane (TCNQ), triphenyltetrazolium chloride (TTC), naphthalenetetracarboxylic dianhydride (NTCDA), perylenetetracarboxylic dianhydride (PTCDA), and copper hexadecafluorophthalocyanine (F16CuPc).

The conductive layer used may be a good conductor, such as silver, aluminum, chromium, samarium, and alloys thereof. According to the configuration, the electric resistance of the anode can be reduced.

The insulating layer has a function regulating the transmittance of the light emitted from the organic electroluminescent device. Examples of the insulating layer used include an inorganic material, such as silicon oxide, silicon nitride, molybdenum oxide, tungsten oxide, and an organic material, such as tris(8-quinolinolato) aluminum (Alq3). Among these, in particular, tungsten oxide has a high light transmittance, and therefore the use thereof can enhance the transparency of the anode.

The thickness of the auxiliary layer is preferably 5 to 40 nm, and more preferably 5 to 10 nm. The thickness of the conductive layer is preferably 8 to 24 nm, and more preferably 16 to 24 nm, provided that in the case where the light transmittance is important, the thickness of the conductive layer is preferably 8 to 16 nm. The thickness of the insulating layer is preferably 30 to 80 nm.

The organic electroluminescent device of the second embodiment may have a transparent protective layer that is provided between the anode and the organic light emitting layer. The transparent protective layer is provide, for example, between the anode and the hole injection layer or the hole transporting layer. According to the configuration, after forming the transparent protective layer, the organic light emitting layer and the like are protected with the transparent protective layer, and therefore the organic light emitting layer and the like can be prevented from being deteriorated in the subsequent process. The material used for the transparent protective layer may be a metal oxide, and a metal oxide in an oxygen defect state, such as hexavalent molybdenum oxide, hexavalent rhenium oxide, and divalent nickel oxide, is preferably used. The transparent protective layer may be patterned. For the pattern, the dimension, and the patterning method in the case where the transparent protective layer is patterned, reference may be made to the section “Transparent Protective Layer” in the organic electroluminescent device of the first embodiment.

The organic electroluminescent device of the second embodiment may have an auxiliary electrode provided on the anode. According to the configuration, the electric resistance of the device can be reduced to reduce the driving voltage. For the description, the preferred ranges, and the specific examples of the auxiliary electrode, reference may be made to the section “Auxiliary Electrode” in the organic electroluminescent device of the first embodiment.

On applying an electric field between the cathode and the anode of the organic electroluminescent device of the second embodiment constituted, holes and electrons injected from the electrodes are recombined in the organic light emitting layer, and the light emitting material is allowed to be the excited state. Light emitted from the light emitting material in the excited state is emitted outside, and thereby the organic electroluminescent device emits light. In the organic electroluminescent device of the second embodiment herein, the light emitted from the light emitting material is emitted from the side of the anode (i.e., the side opposite to the substrate) since the anode disposed on the opposite side to the substrate is transparent. The anode side has a high aperture ratio since neither wiring nor driving element is formed on the substrate, achieving a high light extraction efficiency.

The layers constituting the organic electroluminescent devices of the first embodiment and the second embodiment each can be formed by forming the material thereof into a film. The film forming method is not particularly limited, and may be any of a dry process and a wet process. Specific examples thereof include the vapor-deposition method, the sputtering method, the spin coating method, the printing method, the ink-jet method, and the acrosol jet method.

### Devices

In some embodiments, a light emitting layer is incorporated into a device. For example, the device includes, but is not limited to an OLED bulb, an OLED lamp, a television screen, a computer monitor, a mobile phone, and a tablet.

In some embodiments, an electronic device comprises an OLED comprising an anode, a cathode, and at least one organic layer comprising a light emitting layer between the anode and the cathode.

In some embodiments, compositions described herein may be incorporated into various light-sensitive or light-activated devices, such as a OLEDs or photovoltaic devices. In some embodiments, the composition may be useful in facilitating charge transfer or energy transfer within a device and/or as a hole-transport material. The device may be, for example, an organic light-emitting diode (OLED), an organic integrated circuit (O-IC), an organic field-effect transistor (O-FET), an organic thin-film transistor (O-TFT), an organic light-emitting transistor (O-LET), an organic solar cell (O-SC), an organic optical detector, an organic photoreceptor, an organic field-quench device (O-FQD), a light-emitting electrochemical cell (LEC) or an organic laser diode (O-laser).

### Bulbs or Lamps

In some embodiments, an electronic device comprises an OLED comprising an anode, a cathode, and at least one organic layer comprising a light emitting layer between the anode and the cathode.

In some embodiments, a device comprises OLEDs that differ in color. In some embodiments, a device comprises an array comprising a combination of OLEDs. In some embodiments, the combination of OLEDs is a combination of three colors (e.g., RGB). In some embodiments, the combination of OLEDs is a combination of colors that are not red, green, or blue (for example, orange and yellow green). In some embodiments, the combination of OLEDs is a combination of two, four, or more colors.

In some embodiments, a device is an OLED light comprising:
a circuit board having a first side with a mounting surface and an opposing second side, and defining at least one aperture;
at least one OLED on the mounting surface, the at least one OLED configured to emanate light, comprising:
   an anode, a cathode, and at least one organic layer comprising a light emitting layer between the anode and the cathode;
a housing for the circuit board; and
at least one connector arranged at an end of the housing, the housing and the connector defining a package adapted for installation in a light fixture.

In some embodiments, the OLED light comprises a plurality of OLEDs mounted on a circuit board such that light emanates in a plurality of directions. In some embodiments, a portion of the light emanated in a first direction is deflected to emanate in a second direction. In some embodiments, a reflector is used to deflect the light emanated in a first direction.

### Displays or Screens

In some embodiments, the compounds of the invention can be used in a screen or a display. In some embodiments, the compounds of the invention are deposited onto a substrate using a process including, but not limited to, vacuum evaporation, deposition, vapor deposition, or chemical vapor deposition (CVD). In some embodiments, the substrate is a photoplate structure useful in a two-sided etch provides a unique aspect ratio pixel. The screen (which may also be referred to as a mask) is used in a process in the manufacturing of OLED displays. The corresponding artwork pattern design facilitates a very steep and narrow tie-bar between the pixels in the vertical direction and a large, sweeping bevel opening in the horizontal direction. This allows the close patterning of pixels needed for high definition displays while optimizing the chemical deposition onto a TFT backplane.

The internal patterning of the pixel allows the construction of a 3-dimensional pixel opening with varying aspect ratios in the horizontal and vertical directions. Additionally, the use of imaged “stripes” or halftone circles within the pixel area inhibits etching in specific areas until these specific patterns are undercut and fall off the substrate. At that point the entire pixel area is subjected to a similar etch rate but the depths are varying depending on the halftone pattern. Varying the size and spacing of the halftone pattern allows etching to be inhibited at different protection rates within the pixel allowing for a localized deeper etch needed to create steep vertical bevels.

A preferred material for the deposition mask is invar. Invar is a metal alloy that is cold rolled into long thin sheet in a steel mill. Invar cannot be electrodeposited onto a rotating mandrel as the nickel mask. A preferred and more cost feasible method for forming the open areas in the mask used for deposition is through a wet chemical etching.

In some embodiments, a screen or display pattern is a pixel matrix on a substrate. In some embodiments, a screen or display pattern is fabricated using lithography (e.g., photolithography and e-beam lithography). In some embodiments, a screen or display pattern is fabricated using a wet chemical etch. In further embodiments, a screen or display pattern is fabricated using plasma etching.

### Methods of Manufacturing Devices Using the Disclosed Compounds

An OLED display is generally manufactured by forming a large mother panel and then cutting the mother panel in units of cell panels. In general, each of the cell panels on the mother panel is formed by forming a thin film transistor (TFT) including an active layer and a source/drain electrode on a base substrate, applying a planarization film to the TFT, and sequentially forming a pixel electrode, a light-emitting layer, a counter electrode, and an encapsulation layer, and then is cut from the mother panel.

An OLED display is generally manufactured by forming a large mother panel and then cutting the mother panel in units of cell panels. In general, each of the cell panels on the mother panel is formed by forming a thin film transistor (TFT) including an active layer and a source/drain electrode on a base substrate, applying a planarization film to the TFT, and sequentially forming a pixel electrode, a light-emitting layer, a counter electrode, and an encapsulation layer, and then is cut from the mother panel.

In another aspect, provided herein is a method of manufacturing an organic light-emitting diode (OLED) display, the method comprising:
forming a barrier layer on a base substrate of a mother panel;
forming a plurality of display units in units of cell panels on the barrier layer;
forming an encapsulation layer on each of the display units of the cell panels;
applying an organic film to an interface portion between the cell panels.

In some embodiments, the barrier layer is an inorganic film formed of, for example, SiNx, and an edge portion of the barrier layer is covered with an organic film formed of polyimide or acryl. In some embodiments, the organic film helps the mother panel to be softly cut in units of the cell panel.

In some embodiments, the thin film transistor (TFT) layer includes a light-emitting layer, a gate electrode, and a source/drain electrode. Each of the plurality of display units may include a thin film transistor (TFT) layer, a planarization film formed on the TFT layer, and a light-emitting unit formed on the planarization film, wherein the organic film applied to the interface portion is formed of a same material as a material of the planarization film and is formed at a same time as the planarization film is formed. In some embodiments, a light-emitting unit is connected to the TFT layer with a passivation layer and a planarization film therebetween and an encapsulation layer that covers and protects the light-emitting unit. In some embodiments of the method of manufacturing, the organic film contacts neither the display units nor the encapsulation layer.

Each of the organic film and the planarization film may include any one of polyimide and acryl. In some embodiments, the barrier layer may be an inorganic film. In some embodiments, the base substrate may be formed of polyimide. The method may further include, before the forming of the barrier layer on one surface of the base substrate formed of polyimide, attaching a carrier substrate formed of a glass material to another surface of the base substrate, and before the cutting along the interface portion, separating the carrier substrate from the base substrate. In some embodiments, the OLED display is a flexible display.

In some embodiments, the passivation layer is an organic film disposed on the TFT layer to cover the TFT layer. In some embodiments, the planarization film is an organic film formed on the passivation layer. In some embodiments, the planarization film is formed of polyimide or acryl, like the organic film formed on the edge portion of the barrier layer. In some embodiments, the planarization film and the organic film are simultaneously formed when the OLED display is manufactured. In some embodiments, the organic film may be formed on the edge portion of the barrier layer such that a portion of the organic film directly contacts the base substrate and a remaining portion of the organic film contacts the barrier layer while surrounding the edge portion of the barrier layer.

In some embodiments, the light-emitting layer includes a pixel electrode, a counter electrode, and an organic light-emitting layer disposed between the pixel electrode and the counter electrode. In some embodiments, the pixel electrode is connected to the source/drain electrode of the TFT layer.

In some embodiments, when a voltage is applied to the pixel electrode through the TFT layer, an appropriate voltage is formed between the pixel electrode and the counter electrode, and thus the organic light-emitting layer emits light, thereby forming an image. Hereinafter, an image forming unit including the TFT layer and the light-emitting unit is referred to as a display unit.

In some embodiments, the encapsulation layer that covers the display unit and prevents penetration of external moisture may be formed to have a thin film encapsulation structure in which an organic film and an inorganic film are alternately stacked. In some embodiments, the encapsulation layer has a thin film encapsulation structure in which a plurality of thin films are stacked. In some embodiments, the organic film applied to the interface portion is spaced apart from each of the plurality of display units. In some embodiments, the organic film is formed such that a portion of the organic film directly contacts the base substrate and a remaining portion of the organic film contacts the barrier layer while surrounding an edge portion of the barrier layer.

In one embodiment, the OLED display is flexible and uses the soft base substrate formed of polyimide. In some embodiments, the base substrate is formed on a carrier substrate formed of a glass material, and then the carrier substrate is separated.

In some embodiments, the barrier layer is formed on a surface of the base substrate opposite to the carrier substrate. In one embodiment, the barrier layer is patterned according to a size of each of the cell panels. For example, while the base substrate is formed over the entire surface of a mother panel, the barrier layer is formed according to a size of each of the cell panels, and thus a groove is formed at an interface portion between the barrier layers of the cell panels. Each of the cell panels can be cut along the groove.

In some embodiments, the method of manufacture further comprises cutting along the interface portion, wherein a groove is formed in the barrier layer, wherein at least a portion of the organic film is formed in the groove, and wherein the groove does not penetrate into the base substrate. In some embodiments, the TFT layer of each of the cell panels is formed, and the passivation layer which is an inorganic film and the planarization film which is an organic film are disposed on the TFT layer to cover the TFT layer. At the same time as the planarization film formed of, for example, polyimide or acryl is formed, the groove at the interface portion is covered with the organic film formed of, for example, polyimide or acryl. This is to prevent cracks from occurring by allowing the organic film to absorb an impact generated when each of the cell panels is cut along the groove at the interface portion. That is, if the entire barrier layer is entirely exposed without the organic film, an impact generated when each of the cell panels is cut along the groove at the interface portion is transferred to the barrier layer, thereby increasing the risk of cracks. However, in one embodiment, since the groove at the interface portion between the barrier layers is covered with the organic film and the organic film absorbs an impact that would otherwise be transferred to the barrier layer, each of the cell panels may be softly cut and cracks may be prevented from occurring in the barrier layer. In one embodiment, the organic film covering the groove at the interface portion and the planarization film are spaced apart from each other. For example, if the organic film and the planarization film are connected to each other as one layer, since external moisture may penetrate into the display unit through the planarization film and a portion where the organic film remains, the organic film and the planarization film are spaced apart from each other such that the organic film is spaced apart from the display unit.

In some embodiments, the display unit is formed by forming the light-emitting unit, and the encapsulation layer is disposed on the display unit to cover the display unit. As such, once the mother panel is completely manufactured, the carrier substrate that supports the base substrate is separated from the base substrate. In some embodiments, when a laser beam is emitted toward the carrier substrate, the carrier substrate is separated from the base substrate due to a difference in a thermal expansion coefficient between the carrier substrate and the base substrate.

In some embodiments, the mother panel is cut in units of the cell panels. In some embodiments, the mother panel is cut along an interface portion between the cell panels by using a cutter. In some embodiments, since the groove at the interface portion along which the mother panel is cut is covered with the organic film, the organic film absorbs an impact during the cutting. In some embodiments, cracks may be prevented from occurring in the barrier layer during the cutting.

In some embodiments, the methods reduce a defect rate of a product and stabilize its quality.

Another aspect is an OLED display including: a barrier layer that is formed on a base substrate; a display unit that is formed on the barrier layer; an encapsulation layer that is formed on the display unit; and an organic film that is applied to an edge portion of the barrier layer.

### Method for Evaluating Light Emission Capability of Film

The present invention also provides a method for evaluating the light emission capability of a film containing an organic compound.

The film as the evaluation target of the evaluation method of the present invention is a film containing the first organic compound, the second organic compound, the third organic compound that satisfy the expressions (a) to (c) above. In the evaluation, the S value of the third organic compound in the film and the full width at half maximum of the light emission spectrum of the third organic compound are considered. The full width at half maximum of the light emission spectrum herein is the full width at half maximum of the light emission peak that is intended to be used as light emission. In general, the full width at half maximum is the full width at half maximum of the light emission peak having the maximum light emission intensity, and is preferably the full width at half maximum of the light emission peak having the maximum light emission intensity within the visible region. The S value and the full width at half maximum each may be a value that has been measured prior to the evaluation or a value that is obtained through calculation. In the evaluation, a film having an S value that is as small as possible and a full width at half maximum that is as narrow as possible can be evaluated as having a high light emission capability. For example, a film having an S value of −0.38 or less and a full width at half maximum of 31 nm or less can be judged as having a good light emission capability, a film having an S value of −0.39 or less and a full width at half maximum of 30 nm or less can be judged as having a good light emission capability, a film having an S value of −0.40 or less and a full width at half maximum of 30 nm or less can be judged as having a good light emission capability, a film having an S value of −0.41 or less and a full width at half maximum of 23 nm or less can be judged as having a better light emission capability, a film having an S value of −0.42 or less and a full width at half maximum of 23 nm or less can be judged as having a further better light emission capability, and a film having an S value of −0.42 or less and a full width at half maximum of 20 nm or less can be judged as having a still further better light emission capability. In the evaluation method of the present invention, the evaluation may be performed in consideration of a third index in addition to the S value and the full width at half maximum. In one embodiment of the present invention, the light emission capability is evaluated only with the S value and the full width at half maximum as indices. The evaluation method of the present invention performed can evaluate the usefulness (particularly the light emission capability) of an organic electroluminescent device as a light emitting layer, and particularly can evaluate the usefulness (particularly the light emission capability) of a top emission type organic electroluminescent device as a light emitting layer. In this case, a numerical value relating to the light emission capability, such as an external quantum efficiency, may be specifically predicted. In the prediction, the relationships between the predicted values and the actual measured values may be accumulated, with which the calculation method for the predicted value is appropriately compensated, and thereby the accuracy of the prediction can be enhanced. The evaluation method of the present invention can be used for evaluating capabilities of multiple films.

The use of the film evaluation method of the present invention enables the preliminary evaluation of the light emission capability in the state of films before producing devices. Accordingly, before performing tests taking costs and time for actually mounting on top emission type organic electroluminescent device, films that have high preliminary evaluation results can be screened out, and the number of the actual mounting tests can be reduced. The evaluation method of the present invention can also be applied to a film having been actually mounted. In the case where a good evaluation result is obtained as a result of the evaluation of the mounted film by the evaluation method of the present invention, a device having a higher light emission capability can be obtained by mounting the same film on a top emission type organic electroluminescent device. Accordingly, the evaluation method of the present invention has a wide range of use.

### Method for Determining Condition Suitable for Film Formation

The present invention also provides a method for determining a condition suitable for film formation, particularly provides a method for determining a condition suitable for formation of a light emitting layer of an organic electroluminescent device, and especially provides a method for determining a condition suitable for formation of a light emitting layer of a top emission type organic electroluminescent device.

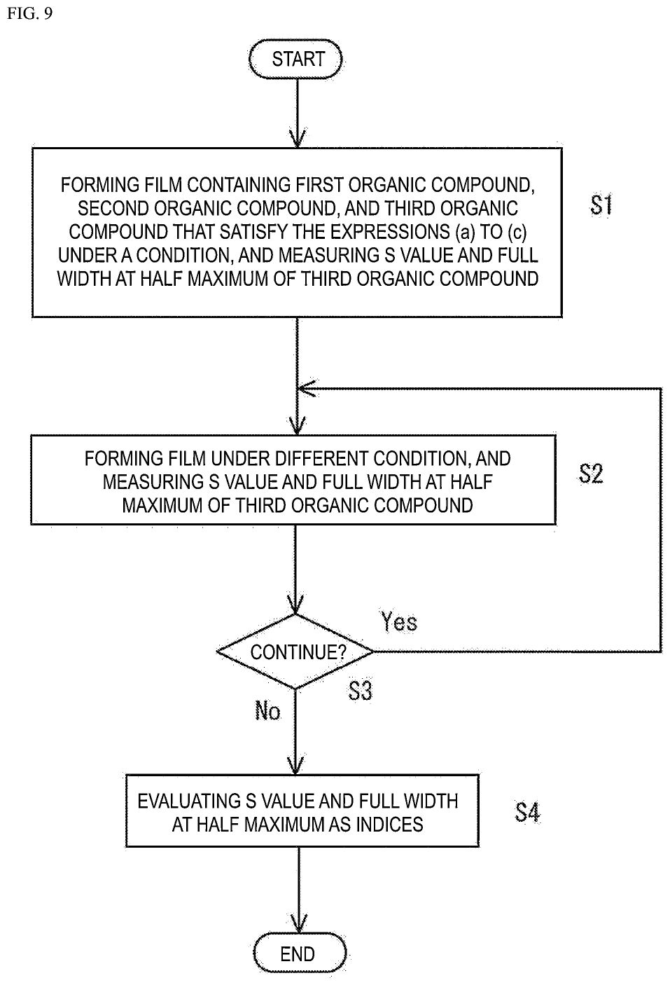

The method for determining a condition suitable for film formation of the present invention will be described with reference to FIG. 9 showing a typical example thereof. In the method of the present invention, a film containing the first organic compound, the second organic compound, and the third organic compound that satisfy the expressions (a) to (c) is formed under one condition, and the S value and the full width at half maximum of the light emission spectrum of the third organic compound in the formed film are measured (S1). A film containing the first organic compound, the second organic compound, and the third organic compound is then formed under a condition different from the previous condition, and the S value and the full width at half maximum of the light emission spectrum of the third organic compound in the formed film are measured (S2). The condition to be differentiated is not particularly limited, as far as relating to the production condition. For example, the conditions of temperature, film formation rate, and the like may be changed, or the condition of time-based environmental control may also be changed. The condition to be differentiated is preferably a condition that influences the S value and the full width at half maximum. After performing the step S2, it is decided whether or not to repeat the step S2 (S3). In the case where it is decided to repeat the step, a film is formed under a condition different from the previous conditions, and the S value and the full width at half maximum are measured (S2). At this time, however, the material species of the first organic compound, the second organic compound, and the third organic compound are not changed. After repeating the step S2 as many times as necessary, the conditions are evaluated with the S values and the full widths at half maximum measured as indices, and thereby the condition suitable for film formation is determined (S4). The condition suitable for film formation may be determined by selecting from the conditions having been evaluated, or may be determined to be a condition that is newly designed through the evaluation.

The method for determining a condition suitable for film formation of the present invention enables preliminarily narrowing down the desirable production condition before actually producing devices. The method of the present invention also enables establishing the formation condition of the film having a good light emission capability. The present invention also provides a method for designing an organic electroluminescent device, including using the condition determined by the method of the present invention.

The present invention provides a program including instructions for performing the method for determining a condition suitable for film formation of the present invention, and a program including instructions for designing an organic electroluminescent device by using the method of the present invention. The program can be stored in a recording medium, and can be sent and received through electronic means. The data of the film forming conditions, the S values, and the full widths at half maximum accumulated by the method of the present invention can be stored and used as a database. The database may also include the actually measured values obtained by measuring the actual films and organic electroluminescent devices, and can be used for enhancing the accuracy of the evaluation method.

The methods and the programs can be appropriately subjected to modifications that are apparent to a skilled person in the art.

### EXAMPLES

The present invention will be described more specifically with reference to examples below. The materials, the contents of the process, the procedures of the process, and the like shown below can be appropriately modified unless deviating from the substance of the present invention. Therefore, the scope of the present invention should not be interpreted as being limited by the specific examples shown below. The light emission capabilities were evaluated by using a source meter (2400 Series, available from Keithley, Tektronix, Inc.), a semiconductor parameter analyzer (E5273A, available from Agilent Technologies, Inc.), an optical power meter (1930C, available from Newport Corporation), an optical spectrometer (USB2000, available from Ocean Optics, Inc.), a spectroradiometer (SR-3, available from Topcon Corporation), and a streak camera (Model C4334, available from Hamamatsu Photonics K.K.). The lowest excited singlet energy E_{S1}, the lowest excited triplet energy E_{T1}, the energy E_{HOMO} of the HOMO, and the energy E_{LUMO} of the LUMO of the compounds used below are shown in the following table.

TABLE 1

| | | E_{S1} | E_{T1} | E_{LUMO} | E_{HOMO} |
|---|---|---|---|---|---|
| First organic compound | Compound H1 | 3.69 | 2.83 | —2.63 | —6.13 |
| Second organic compound | Compound T1 | 2.93 | 2.75 | —3.05 | —5.83 |
| | Compound T2 | 2.89 | 2.77 | —3.17 | —5.95 |
| | Compound T3 | 2.83 | 2.70 | —3.28 | —6.01 |
| Third organic compound | Compound F1 | 2.75 | 2.59 | —2.76 | —5.36 |
| | Compound F2 | 2.66 | 2.40 | —3.00 | —5.61 |
| | Compound F3 | 2.75 | 2.48 | —3.04 | —5.68 |

(Unit: eV)

### Production of Bottom Emission Type Organic Electroluminescent Device

Thin films each were laminated by the vacuum vapor deposition method at a vacuum degree of 1×10⁻⁶ Pa on a glass substrate having a thickness of 2 mm having formed thereon an anode formed of indium tin oxide (ITO) having a thickness of 50 nm. HI01 was formed to a thickness of 10 nm on ITO, and EB1 was formed to a thickness of 10 nm thereon. The first organic compound, the second organic compound, and the third organic compound were then vapor-co-deposited from separate vapor deposition sources to form a light emitting layer having a thickness of 40 nm. HB1 was then formed to a thickness of 10 nm, and subsequently ET1 and Liq (weight ratio: 70/30) were formed to a thickness of 30 nm. Furthermore, Liq was formed to a thickness of 2 nm, and then aluminum (Al) was vapor-deposited to a thickness of 100 nm to form a cathode. According to the procedure, a bottom emission type organic electroluminescent device was produced.

### Production of Top Emission Type Organic Electroluminescent Device

Separately, thin films each were laminated by the vacuum vapor deposition method at a vacuum degree of 1×10⁻⁶ Pa on a glass substrate having a thickness of 2 mm having formed thereon a multilayer transparent anode including indium tin oxide (ITO) having a thickness of 10 nm and a silver-palladium-copper alloy (APC) having a thickness of 150 nm. HI01 was formed to a thickness of 10 nm on ITO, and EB1 was formed to a thickness of 10 nm thereon. The first organic compound, the second organic compound, and the third organic compound were then vapor-co-deposited from separate vapor deposition sources to form a light emitting layer having a thickness of 40 nm. HB1 was then formed to a thickness of 10 nm, and subsequently ET1 and Liq (having the same weight ratio as in the bottom emission type) were formed to a thickness of 30 nm. Furthermore, Liq was formed to a thickness of 2 nm. Subsequently, Mg and Ag (weight ratio: 1/10) were vapor-deposited to a thickness of 15 nm to form a cathode, and furthermore NPD was vapor-deposited to a thickness of 105 nm to form a cap layer. According to the procedure, a top emission type organic electroluminescent device was produced.

### Materials

In the production procedure of the bottom emission type organic electroluminescent device, light emitting layers 1 to 6 having the compositions shown in Table 2 below each were formed to produce bottom emission type organic electroluminescent devices BE1 to BE6.

In the production procedure of the top emission type organic electroluminescent device, light emitting layers 1 to 6 having the compositions shown in Table 2 below each were formed to produce top emission type organic electroluminescent devices TE1 to TE6. All the devices produced satisfied the expressions (a) to (c).

TABLE 2

| | First organic | | Second organic | | Third organic | |
|---|---|---|---|---|---|---|
| | compound | | compound | | compound | |
| | | Content | | Content | | Content |
| Light emitting layer No. | Compound | (wt %) | Compound | (wt %) | Compound | (wt %) |
| Light emitting layer 1 | H1 | 69.5 | T3 | 30.0 | F1 | 0.5 |
| Light emitting layer 2 | H1 | 69.0 | T3 | 30.0 | F1 | 1.0 |
| Light emitting layer 3 | H1 | 69.0 | T2 | 30.0 | F1 | 1.0 |
| Light emitting layer 4 | H1 | 68.0 | T3 | 30.0 | F3 | 2.0 |
| Light emitting layer 5 | H1 | 68.0 | T3 | 30.0 | F2 | 2.0 |
| Light emitting layer 6 | H1 | 69.0 | T1 | 30.0 | F1 | 1.0 |

### Evaluation Results

The devices produced each were measured for the S value and the full width at half maximum (FWHM) of the spectrum of the third organic compound in the light emitting layer. The devices produced each were also measured for the external quantum efficiency (EQE) and the light emission peak intensity. The external quantum efficiency and the light emission peak intensity were calculated for the ratio (top emission type device)/(bottom emission type device) (TE/BE) of the devices using the same light emitting layer formed therein.

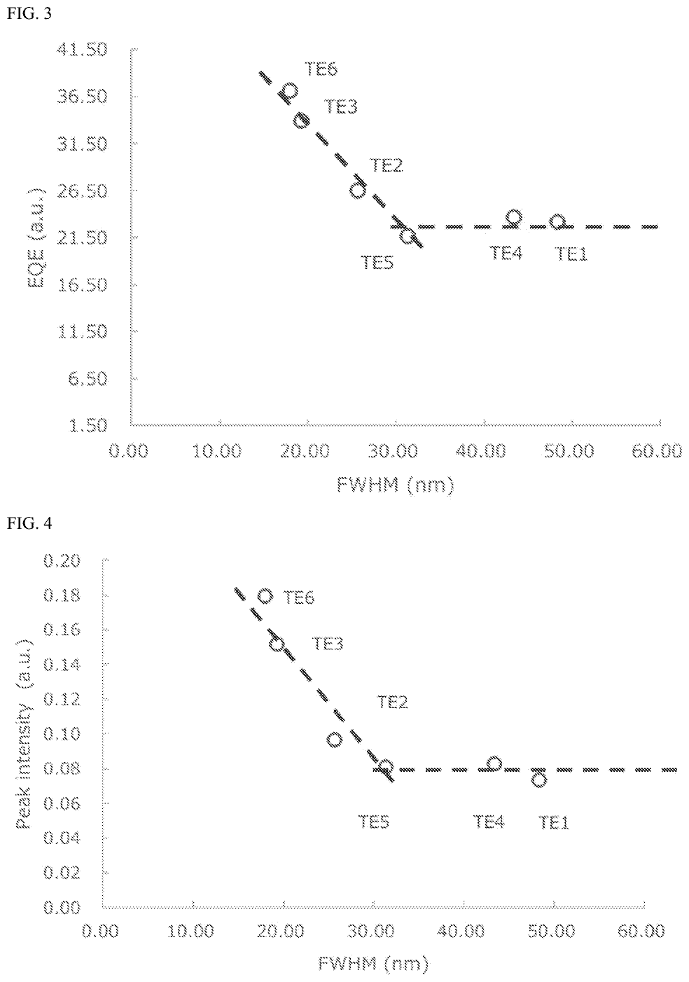

FIG. 3 shows the relationship between the external quantum efficiency (EQE) and the full width at half maximum (FWHM) of the third organic compound of the top emission type devices TE1 to TE6. FIG. 4 shows the relationship between the light emission peak intensity (PI) and the full width at half maximum (FWHM) of the third organic compound of the top emission type devices TE1 to TE6. It is suggested from FIGS. 3 and 4 that the graphs bend at a full width at half maximum (FWHM) of 31 nm. Accordingly, it is confirmed that the external quantum efficiency (EQE) and the light emission peak intensity (PI) of the top emission type organic electroluminescent device are significantly enhanced in the case where the full width at half maximum (FWHM) is 31 nm or less.

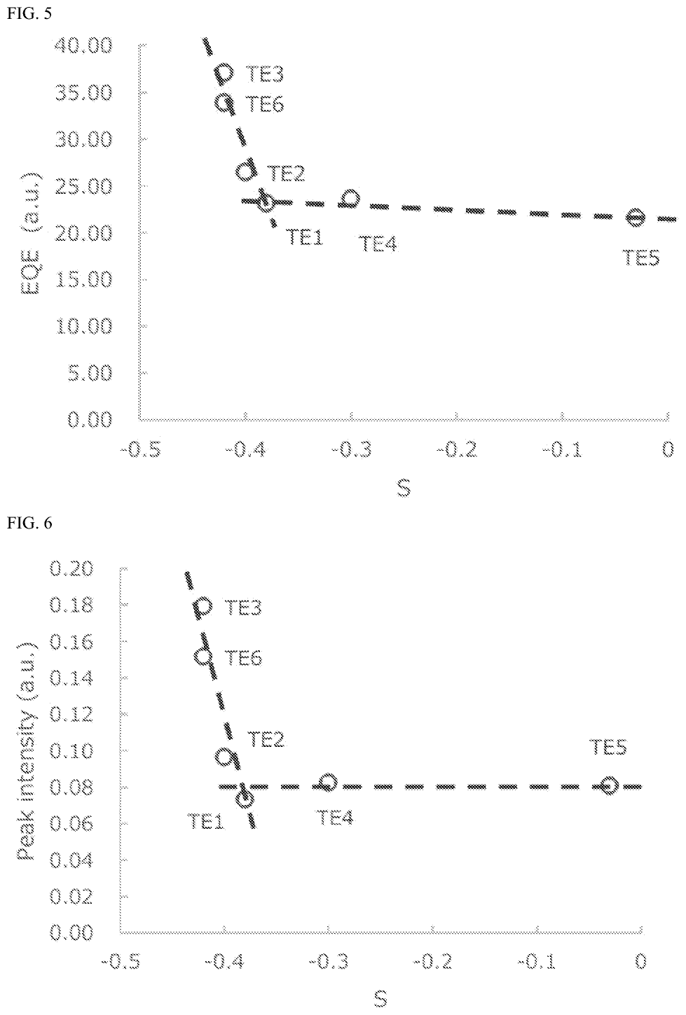

FIG. 5 shows the relationship between the external quantum efficiency (EQE) and the S value of the third organic compound in the light emitting layer of the top emission type devices TE1 to TE6. FIG. 6 shows the relationship between the light emission peak intensity (PI) and the S value of the third organic compound in the light emitting layer of the top emission type devices TE1 to TE6. It is suggested from FIGS. 5 and 6 that the graphs bend at an S value of −0.38. Accordingly, it is confirmed that the external quantum efficiency (EQE) and the light emission peak intensity (PI) of the top emission type device are significantly enhanced in the case where the S value is −0.38 or less.

Focusing on the light emission peak intensities, the ratios (top emission type device)/(bottom emission type device) are all higher values of 1.84 to 2.03, and it is confirmed that the top emission type devices result in larger light emission peak intensities. Focusing on the external quantum efficiency, the ratios (top emission type device)/(bottom emission type device) are higher values exceeding 1 for the devices having the light emitting layer 3 and the light emitting layer 6, which have an S value of −0.38 or less and a full width at half maximum of 31 nm or less (TE3/BE3=1.10, TE6/BE6=1.24). On the other hand, the ratios are less than 1 for the devices having the light emitting layer that does not satisfy the condition of an S value of −0.38 or less and a full width at half maximum of 31 nm or less (TE1/BE1=0.77, TE4/BE4=0.82, TE5/BE5=0.94).

It is confirmed from the above that both the light emission peak intensity and the light emission efficiency can be enhanced by forming the light emitting layer having an S value of the third organic compound of −0.38 or less and a full width at half maximum of the light emission spectrum of 31 nm or less, particularly as the light emitting layer in the top emission type organic electroluminescent device.

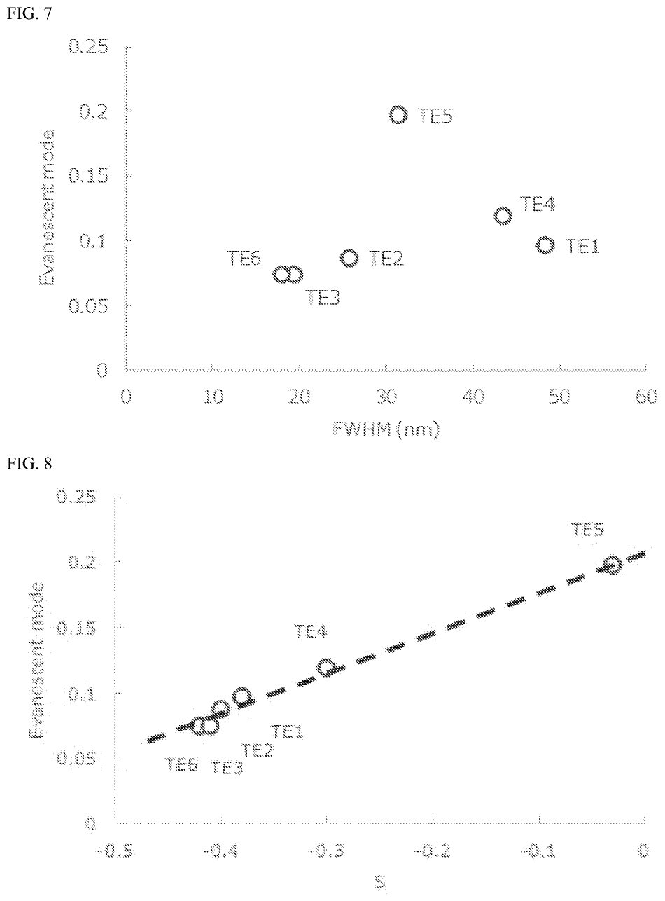

For elucidating the mechanism causing the advantageous effects of the present invention, the evanescent modes of the top emission type devices TE1 to TE6 were obtained through calculation. The evanescent mode was calculated by performing mode analysis from the thickness information and the optical constant using an analysis software, Setfos (available from Cybernet Systems Co., Ltd.). FIG. 7 shows the relationship between the evanescent mode and the full width at half maximum (FWHM) of the third organic compound of the top emission type devices TE1 to TE6. FIG. 8 shows the relationship between the evanescent mode and the S value of the third organic compound in the light emitting layer of the top emission type devices TE1 to TE6. There was no correlative relationship found between the evanescent mode and the full width at half maximum (FWHM), but there was a tendency that the evanescent mode was increased as the S value was decreased. It is considered that the tendency occurs since when the molecules of the third organic compound are horizontally oriented in the light emitting layer to reduce the S value, the plasmon is prevented from generating, and the metal loss is suppressed thereby. The suppression of the metal loss increases accordingly the proportion of excitons capable of being extracted. It is also considered that the horizontal orientation of the third organic compound also reduces the total reflection angle, and thereby the light extraction efficiency is enhanced by decreasing the S value. On the other hand, the full width at half maximum (FWHM) does not involve the suppression of the metal loss, but with the same number of light emission photons assumed, the number density of photons existing in the peak wavelength region is increased by decreasing the full width at half maximum. Accordingly, the decrease of the full width at half maximum increases the number of photons in the wavelength region allowed by the cavity thickness, which leads the enhancement of the light emission luminance. In the present invention, it is considered that the effect obtained by narrowing the full width at half maximum and the effect obtained by decreasing the S value (i.e., increasing the orientation) are synergistically enhanced in the region with a full width at half maximum of the light emission spectrum of 31 nm or less and an S value of −0.38 or less, which results in the significant improvement of the light emission efficiency.

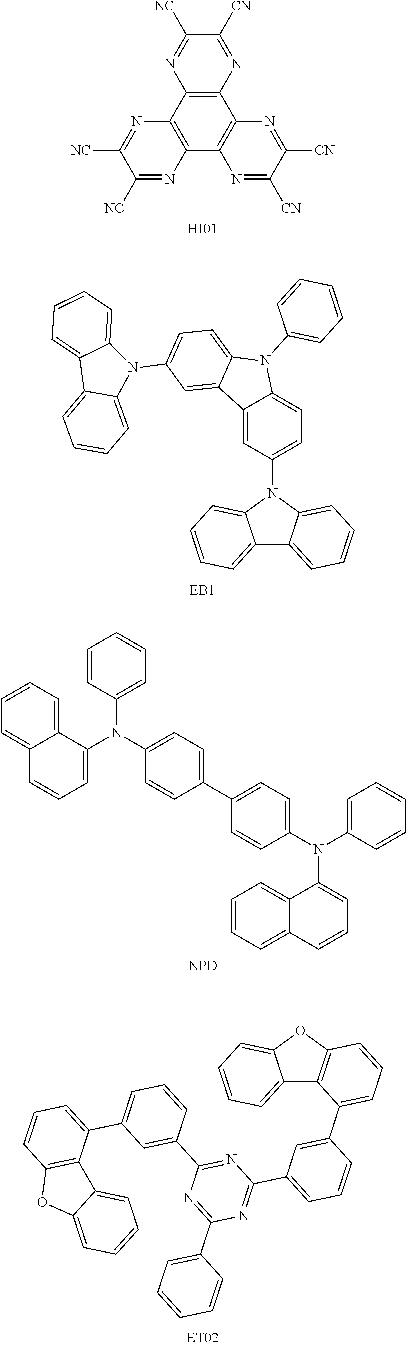 [SMILES: N#Cc1nc2c3nc(C#N)c(C#N)nc3c3nc(C#N)c(C#N)nc3c2nc1C#N ; "HI01" ; c1ccc(-n2c3ccc(-n4c5ccccc5c5ccccc54)cc3c3cc(-n4c5ccccc5c5ccccc54)ccc32)cc1 ; c1ccc(N(c2ccc(-c3ccc(N(c4ccccc4)c4cccc5ccccc45)cc3)cc2)c2cccc3ccccc23)cc1 ; "NPD" ; c1ccc(-c2nc(-c3cccc(-c4cccc5oc6ccccc6c45)c3)nc(-c3cccc(-c4cccc5oc6ccccc6c45)c3)n2)cc1]

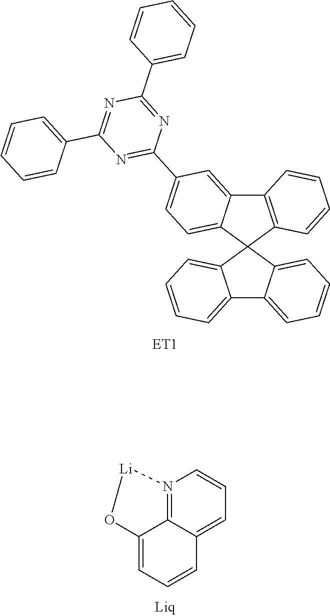

### INDUSTRIAL APPLICABILITY

The top emission type organic electroluminescent device of the present invention has a high light emission efficiency. According to the methods of the present invention, the light emission capability of the film can be easily evaluated, the formation condition of the light emitting layer having a good light emission capability can be found with high accuracy, and an excellent organic electroluminescent device can be designed. Furthermore, the use of the program and the database of the present invention enables the evaluation and the designing with high efficiency. Consequently, the present invention has practical usefulness and high industrial applicability.

### Reference Sign List

1: Substrate
2a: Anode (first electrode)
2b: Cathode (first electrode)
3: Hole injection layer
4: Hole transporting layer
5: Organic light emitting layer
6: Electron transporting layer
7: Electron injection layer
8: Transparent protective layer
9: Transparent conductive layer (second electrode)

1. A top emission type organic electroluminescent device comprising a lamination structure including a substrate, a first electrode, a light emitting layer, and a transparent second electrode in this order,
the light emitting layer containing a first organic compound, a second organic compound, and a third organic compound that satisfy the following expressions (a) to (c),
the second organic compound being a delayed fluorescent material,
the third organic compound having an S value of −0.38 or less in the light emitting layer,
the third organic compound having a full width at half maximum of a light emission spectrum of 31 nm or less:
$${E}_{S 1} ( 1 ) > {E}_{S 1} ( 2 ) > {E}_{S 1} ( 3 ) \qquad ( a )$$
$${E}_{LUMO} ( 2 ) \leq {E}_{LUMO} ( 3 ) \qquad ( b )$$
$${E}_{HOMO} ( 2 ) \leq {E}_{HOMO} ( 3 ) \qquad ( c )$$
wherein
E_{S1}(1) represents lowest excited singlet energy of the first organic compound,
E_{S1}(2) represents lowest excited singlet energy of the second organic compound,
E_{S1}(3) represents lowest excited singlet energy of the third organic compound,
E_{LUMO}(2) represents energy of a LUMO of the second organic compound,
E_{LUMO}(3) represents energy of a LUMO of the third organic compound,
E_{HOMO}(2) represents energy of a HOMO of the second organic compound, and
E_{HOMO}(3) represents energy of a HOMO of the third organic compound.

2. The organic electroluminescent device according to claim 1, wherein recombination of a hole and an electron occurs in the light emitting layer.

3. The organic electroluminescent device according to claim 1, wherein the second organic compound includes a structure including a benzene ring having bonded thereto one or two cyano groups and at least one donor group.

4. The organic electroluminescent device according to claim 3, wherein the donor group is a substituted or unsubstituted carbazol-9-yl group.

5. The organic electroluminescent device according to claim 3, wherein the benzene ring has bonded thereto 3 or more substituted or unsubstituted carbazol-9-yl groups.

6. The organic electroluminescent device according to claim 1, wherein the third organic compound is a compound having a multiple resonance effect of a boron atom and a nitrogen atom, or a compound including a condensed aromatic cyclic structure.

7. A method for evaluating a light emission capability of a film containing the first organic compound, the second organic compound, and the third organic compound that satisfy the expressions (a) to (c),
the method comprising evaluating the light emission capability of the film with an S value of the third organic compound and a full width at half maximum of a light emission spectrum of the third organic compound as indices:
$${E}_{S 1} ( 1 ) > {E}_{S 1} ( 2 ) > {E}_{S 1} ( 3 ) \qquad ( a )$$
$${E}_{LUMO} ( 2 ) \leq {E}_{LUMO} ( 3 ) \qquad ( b )$$
$${E}_{HOMO} ( 2 ) \leq {E}_{HOMO} ( 3 ) \qquad ( c )$$
wherein
E_{S1}(1) represents lowest excited singlet energy of the first organic compound,
E_{S1}(2) represents lowest excited singlet energy of the second organic compound,
E_{S1}(3) represents lowest excited singlet energy of the third organic compound,
E_{LUMO}(2) represents energy of a LUMO of the second organic compound,
E_{LUMO}(3) represents energy of a LUMO of the third organic compound,
E_{HOMO}(2) represents energy of a HOMO of the second organic compound, and
E_{HOMO}(3) represents energy of a HOMO of the third organic compound.

8. The method according to claim 7, wherein the method comprises evaluating based on the full width at half maximum of 31 nm or less and the S value of −0.38 or less.

9. The method according to claim 7, wherein the method comprises evaluating usefulness as a light emitting layer of a top emission type organic electroluminescent device.

10. The method according to claim 9, wherein the method comprises predicting a light emission efficiency of the device.

11. The method according claim 7, wherein the method comprises evaluating capabilities of multiple films.

12. A method for determining a condition suitable for film formation, comprising
forming a film containing the first organic compound, the second organic compound, and the third organic compound that satisfy the expressions (a) to (c) under one condition,
measuring an S value and a full width at half maximum of a light emission spectrum of the third organic compound in the formed film,
repeating once or more an operation including forming a film containing the first organic compound, the second organic compound, and the third organic compound under a condition different from the previous condition, and measuring an S value and a full width at half maximum of a light emission spectrum of the third organic compound in the formed film, and
evaluating the S value and the full width at half maximum as indices:
$${E}_{S 1} ( 1 ) > {E}_{S 1} ( 2 ) > {E}_{S 1} ( 3 ) \qquad ( a )$$
$${E}_{LUMO} ( 2 ) \leq {E}_{LUMO} ( 3 ) \qquad ( b )$$
$${E}_{HOMO} ( 2 ) \leq {E}_{HOMO} ( 3 ) \qquad ( c )$$
wherein
E_{S1}(1) represents lowest excited singlet energy of the first organic compound,
E_{S1}(2) represents lowest excited singlet energy of the second organic compound,
E_{S1}(3) represents lowest excited singlet energy of the third organic compound,
E_{LUMO}(2) represents energy of a LUMO of the second organic compound,
E_{LUMO}(3) represents energy of a LUMO of the third organic compound,
E_{HOMO}(2) represents energy of a HOMO of the second organic compound, and
E_{HOMO}(3) represents energy of a HOMO of the third organic compound.

13. The method according to claim 12, wherein the method further comprises newly designing a condition suitable for film formation based on the evaluation, and then determining the condition.

14. A method for designing an organic electroluminescent device, comprising forming a light emitting layer under a condition determined by the method according to claim 12.

15. A computer-readable recording medium which records a program for making a computer perform the method according to claim 12.

16. A database comprising data of the conditions, the S values, and the full widths at half maximum in claim 12.
